(19) United States
(12) Patent Application Publication
(10) Pub. No.: US 2016/0197282 A1
(43) Pub. Date: Jul. 7, 2016

(54) ORGANIC ELECTROLUMINESCENT ELEMENT, LIGHT EMITTING DEVICE, LIGHTING DEVICE, DISPLAY DEVICE AND ELECTRONIC DEVICE

(71) Applicant: KONICA MINOLTA, INC., Tokyo (JP)

(72) Inventors: Shuho TANIMOTO, Fukuoka-shi, Fukuoka (JP); Dai IKEMIZU, Hachioji, Tokyo (JP); Tatsuo TANAKA, Fuchu-shi, Tokyo (JP); Hideo TAKA, Inagi-shi, Tokyo (JP); Hiroshi KITA, Hachioji-shi, Tokyo (JP)

(21) Appl. No.: 14/911,941

(22) PCT Filed: Aug. 14, 2014
(86) PCT No.: PCT/JP2014/071433

§ 371 Date: Feb. 12, 2016

(30) Foreign Application Priority Data
Aug. 16, 2013 (JP) 2013-169078

(51) Int. Cl. H01L 51/00; C09K 11/02; C09K 11/06

(52) U.S. Cl. CPC H01L 51/0058; C09K 11/06; C09K 11/025; H01L 51/0072; H01L 51/0094; H01L 51/0057; H01L 51/0054; H01L 51/0074; H01L 51/0073; H01L 51/5012

(57) ABSTRACT

An organic electroluminescent element contains at least one organic layer that is interposed between an anode and a cathode. The organic layer includes a light emitting layer. The light emitting layer contains a light emitting compound that has a stokes shift within the range of 0-0.24 eV and a lowest excited singlet energy (S₁) of 2.64 eV or more.

### TECHNICAL FIELD

The present invention relates to an organic electroluminescent element. The present invention also relates to a light-emitting device, a lighting device, a display device, and an electronic device, each of the devices including the organic electroluminescent element. In particular, the present invention relates to, for example, an organic electroluminescent element exhibiting improved light emission efficiency.

### BACKGROUND ART

Organic electroluminescent (hereinafter referred to as “EL”) elements, which are based on electroluminescence of organic materials, have already been put into practice as a new generation of light-emitting systems capable of planar light emission. Organic EL elements have recently been applied to electronic displays and also to lighting devices. Thus, a demand has arisen for further development of organic EL elements.

Organic EL elements are based on two light emission modes; i.e., “phosphorescence,” which occurs during transfer of excitons from the triplet excitation state to the ground state, and “fluorescence,” which occurs during transfer of excitons from the singlet excitation state to the ground state.

Under an electric field applied to such an organic EL element, holes and electrons are respectively injected from an anode and a cathode into a light-emitting layer, and the injected hole and electrons are recombined in the light-emitting layer, to generate excitons. In this case, singlet excitons and triplet excitons are generated at a ratio of 25%:75%; i.e., a phosphorescent mode, which is based on triplet excitons, theoretically provides internal quantum efficiency higher than that of a fluorescent mode.

Unfortunately, achievement of high quantum efficiency in a phosphorescent mode requires the use of a complex of iridium or platinum (i.e., a rare metal) as a central metal, which may cause future problems in the industry in terms of the reserves and price of rare metals.

In recent years, new techniques have been proposed for development of various fluorescent elements having improved light emission efficiency.

For example, PTL 1 discloses a technique focused on a phenomenon in which singlet excitons are generated by collision of two triplet excitons (hereinafter also called “triplet-triplet annihilation (TTA)” or “triplet-triplet fusion (TTF)”). This technique prompts the TTA phenomenon to occur effectively and thus improves the light emission efficiency of a fluorescent element. Although this technique can increase the power efficiency of the fluorescent material to two to three times that of a conventional fluorescent material, the light emission efficiency is not as high as that of a phosphorescent material, because singlet excitons are theoretically generated at an efficiency of only about 40% by the TTA phenomenon.

Adachi, et al. have recently reported fluorescent materials based on a thermally activated delayed fluorescence (hereinafter may be referred to as “TADF”) mechanism and applicability of the materials to organic EL elements (see, for example, NPLs 1 to 7).

As illustrated in FIG. 1A, the TADF mechanism of a fluorescent material involves a phenomenon wherein excitons undergo reverse intersystem crossing from the triplet excitation state to the singlet excitation state if the difference between excited singlet energy level and excited triplet energy level (ΔEst) in the fluorescent material is smaller than that in a common fluorescent material (i.e., ΔEst (TADF) is smaller than ΔEst (F) in FIG. 1A). This small difference in energy level allows fluorescence to occur. Specifically, triplet excitons generated at a probability of 75% through electrical excitation, which would otherwise fail to contribute to fluorescence, are transferred to the singlet excitation state by heat energy during operation of the organic EL element. Fluorescence occurs by radiative deactivation (also referred to as “radiative transition”) during transfer of the excitons from the singlet excitation state to the ground state. The TADF mechanism can theoretically achieve 100% internal quantum efficiency even in a fluorescent material.

A known technique effective for achieving high light emission efficiency involves incorporation of a TADF compound (also referred to as “light emission auxiliary material” or “assist dopant”) into a light-emitting layer containing a host compound and a light-emitting compound, the TADF compound serving as a third component (see, for example, NPL 8). When singlet excitons (25%) and triplet excitons (75%) are generated on the compound serving as an assist dopant by electrical excitation, the triplet excitons are converted into singlet excitons through reverse intersystem crossing (RISC).

The energy of the singlet excitons is transferred to the light-emitting compound (i.e., fluorescence resonance energy transfer (FRET)), and the light-emitting compound emits light by the transferred energy. Thus, the light-emitting compound emits light by the exciton energy (theoretically 100%), resulting in high light emission efficiency.

There are technical problems in terms of the color of emitted light. Various light-emitting compounds that emit light of different colors have been developed regardless of light emission mode. Among these light-emitting compounds, blue light-emitting compounds encounter many technical problems. Specifically, emission of blue light (i.e., light of short wavelength) requires high excited singlet or triplet energy level. In general, a material exhibiting high excited energy level is unstable in the excited state. Thus, an organic EL element containing such a material exhibits unsatisfactorily short service life and low light emission efficiency. Although the use of a structure having a large conjugated π-electron system is generally advantageous in view of carrier transportability and heat resistance, the structure having a large conjugated π-electron system exhibits low excited energy level and is barely applicable to a light-emitting compound that emits blue light of short wavelength.

Regardless of the principle of emission, EL elements containing traditional blue light-emitting organic materials are still unsatisfactory in terms of external quantum efficiency, practical service life, and emission of blue light with high chromaticity. In particular, blue light-emitting organic EL elements encounter difficulty in maintaining the light emission efficiency at the initial level over a long period of time.

Appropriate molecular design is required for a light-emitting material, and a host compound used in combination with the light-emitting material should be appropriately selected. The interaction between compounds greatly affects the emission properties of the light-emitting material in a thin film of an organic EL element. Thus, combination of the light-emitting material with an appropriate host compound may improve optical and practical properties (e.g., light emission efficiency, chromaticity, and service life) of the organic EL element. In order to solve the aforementioned problems, extensive studies are required for careful molecular design of a blue light-emitting material and combination of the material with a host compound.

### CITATION LIST

### Patent Literature

PTL 1: WO2012/133188

### Non-Patent Literature

NPL 1: “Shomei ni Muketa Rinko Yuki EL Gijutsu no Kaihatsu (Development of phosphorescent OLED (organic light emitting diode) technology for lighting)” Oyo Butsuri (Applied Physics), Vol. 80, No. 4, 2011
NPL 2: H. Uoyama, et al., Nature, 2012, 492, 234-238
NPL 3: S. Y. Lee, et al., Applied Physics Letters, 2012, 101, 093306-093309
NPL 4: Q. Zhang, et al., J. Am. Chem. Soc., 2012, 134, 14706-14709
NPL 5: T. Nakagawa, et al., Chem. Commun., 2012, 48, 9580-9582
NPL 6: A. Endo, et al., Adv. Mater., 2009, 21, 4802-4806
NPL 7: Yuki EL Toronkai Dai-10-Kai Reikai Yokoshu (Proceedings of Organic EL Symposium of Japan 10th Meeting), pp. 11-12, 2010
NPL 8: H. Nakanotani, et al., Nature Communication, 2014, 5, 4016-4022.

### SUMMARY OF INVENTION

### Problems to be Solved by Invention

The present invention has been attained in consideration of the problems and circumstances described above. An object of the present invention is to provide an organic electroluminescent element which emits blue light with high chromaticity and which exhibits high light emission efficiency over a long period of time. Another object of the present invention is to provide a light-emitting device, a lighting device, a display device, and an electronic device, each of the devices including the organic electroluminescent element.

### Means for Solving Problems

The present inventors, who have conducted studies to solve the problems described above, have found that an organic electroluminescent element containing a light-emitting compound having a small Stokes shift and a lowest excited singlet energy level S₁ of 2.64 eV or more exhibits high light emission efficiency, emits blue light with high chromaticity, and achieves a practical service life. The present invention has been accomplished on the basis of this finding.

As used herein, “emission of blue light with high chromaticity” refers to fluorescence having a peak of the shortest wavelength region at 470 nm or less (i.e., blue light is not pure at a wavelength region longer than 470 nm). A wavelength of 470 nm corresponds to about 2.64 eV. Thus, the lowest excited singlet energy level S₁ is defined as 2.64 eV or more in the present invention.

The present inventors have also found that a light-emitting compound having a non-planar electronic conjugated structure has favorable properties suitable for light-emitting material.

The present invention to solve the problems described above is characterized by the following aspects:

1. An organic electroluminescent element including:

an anode;

a cathode; and

at least one organic layer disposed between the anode and the cathode, the organic layer including a light-emitting layer,

wherein the light-emitting layer contains a light-emitting compound having a Stokes shift of 0 to 0.24 eV and a lowest excited singlet energy level S₁ of 2.64 eV or more.

2. The organic electroluminescent element according to item 1, wherein the light-emitting compound has a structure represented by Formula (1):

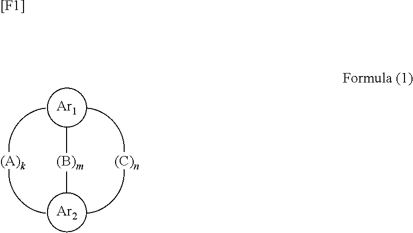

wherein A, B, and C each independently represent a single bond or a linking group containing a carbon, silicon, or oxygen atom; Ar₁ and Ar₂ each independently represent an aromatic hydrocarbon or heterocyclic group optionally having a condensed ring structure; Ar₁ and Ar₂ are optionally identical to each other; k represents a natural number and if k is 2 or more, the groups A are optionally different from one another; m is 0 or a natural number and if m is 2 or more, the groups B are optionally different from one another; n is 0 or a natural number and if n is 2 or more, the groups C are optionally different from one another; and each of A, B, and C independently optionally links Ar₁ and Ar₂ with a single bond or through formation of a condensed ring.
3. The organic electroluminescent element according to item 1 or 2, wherein the light-emitting compound has a non-planar electronic conjugated structure.
4. The organic electroluminescent element according to any one of items 1 to 3, wherein the light-emitting compound has a structure represented by Formula (2):

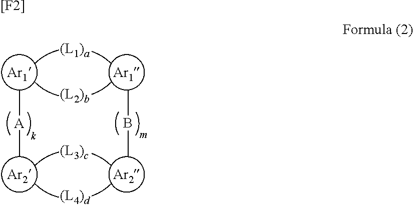

wherein Ar₁′, Ar₁″, Ar₂′, and Ar₂″ are optionally identical to or different from one another and each independently represent an aromatic hydrocarbon or heterocyclic group optionally having a condensed ring structure and a substituent; Ar₁′ and Ar₁″ optionally form a condensed ring, and Ar₂′ and Ar₂″ optionally form a condensed ring; a, b, c, and d each represent 0 or a natural number; a or b represents a natural number; c or d represents a natural number; L₁ and L₂ each represent a single bond or divalent linking group that links Ar₁′ and Ar₁″; Ar₁′ and Ar₁″ optionally form a condensed ring with L₁ and L₂; L₃ and L₄ each represent a single bond or divalent linking group that links Ar₂′ and Ar₂″; Ar₂′ and Ar₂″ optionally form a condensed ring with L₃ and L₄; if a, b, c, or d is 2 or more, the groups L₁, L₂, L₃, or L₄ are optionally identical to or different from one another; k and m each represent 0 or a natural number; k or m represents a natural number; A and B each represent a single bond or a divalent linking group; if k or m is 2 or more, the groups A or B are optionally identical to or different from one another; and Ar₁′, Ar₂′, and A optionally form a condensed ring, and Ar₁″, Ar₂″, and B optionally form a condensed ring.
5. The organic electroluminescent element according to any one of items 1 to 4, wherein the light-emitting compound has a structure represented by Formula (3):

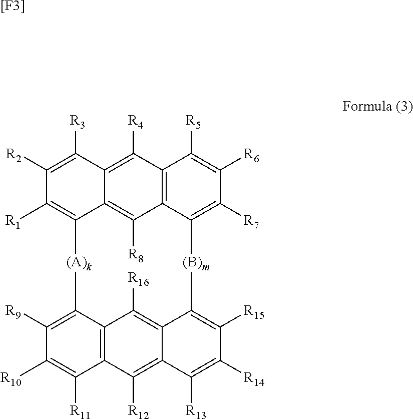

wherein A and B each independently represent a single bond or a linking group containing a carbon or silicon atom; two anthracene rings linked by A and/or B optionally form a condensed ring with R₁, R₉, and A or with R₇, R₁₅, and B; k represents a natural number and if k is 2 or more, the groups A are optionally different from one another; R₁ to R₁₆ each represent a substituted or unsubstituted aliphatic hydrocarbon group or a substituted or unsubstituted aromatic hydrocarbon group, and optionally form a ring; each of R₁ to R₁₆ is optionally a heteroaromatic hydrocarbon group containing a nitrogen, oxygen, or sulfur atom; m represents 0 or a natural number and if m is 2 or more, the groups B are optionally different from one another; and each of the two anthracene rings linked by A and/or B optionally has a non-planar electronic conjugated structure, or the two anthracene rings optionally form a single aromatic ring.
6. The organic electroluminescent element according to any one of items 1 to 4, wherein the light-emitting compound has a structure represented by Formula (4):

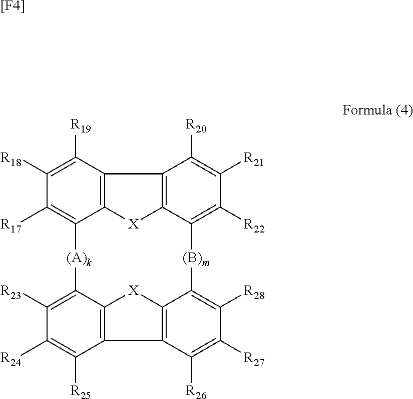

wherein X represents boron, carbon, nitrogen, oxygen, sulfur, or silicon; X optionally has a hydrogen atom or a substituent; R₁₇ to R₂₈ each independently represent a hydrogen atom or a substituent; two aromatic rings linked by A and/or B optionally form a condensed ring structure with any of R₁₇ to R₂₈, A, and B; k and m each represent 0 or a natural number; k or m represents a natural number; A and B each represent a single bond or a divalent linking group; if k or m is 2 or more, the groups A or B are optionally identical to or different from one another; and each of the two aromatic rings linked by A and/or B optionally has a non-planar electronic conjugated structure, or the two aromatic rings optionally form a single aromatic ring.
7. The organic electroluminescent element according to any one of items 1 to 4, wherein the light-emitting compound has a structure represented by Formula (5):

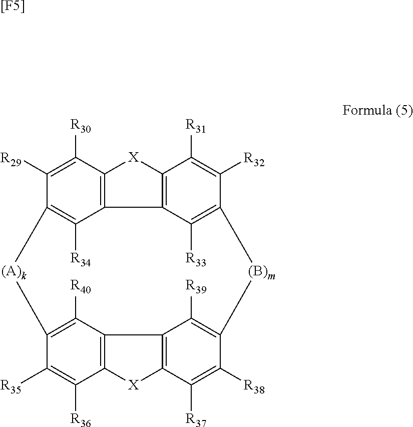

wherein X represents boron, carbon, nitrogen, oxygen, sulfur, or silicon; X optionally has a hydrogen atom or a substituent; R₂₉ to R₄₀ each represent a hydrogen atom or a substituent; two aromatic rings linked by A and/or B optionally form a condensed ring structure with any of R₂₉ to R₄₀, A, and B; k and m each represent 0 or a natural number; k or m represents a natural number; A and B each represent a single bond or a divalent linking group; if k or m is 2 or more, the groups A or B are optionally identical to or different from one another; and each of the two aromatic rings linked by A and/or B optionally has a non-planar electronic conjugated structure, or the two aromatic rings optionally form a single aromatic ring.
8. The organic electroluminescent element according to any one of items 1 to 7, wherein the light-emitting layer contains a carbazole derivative.
9. The organic electroluminescent element according to item 8, wherein the carbazole derivative is a compound having two or more conjugated structures each having 14 or more π-electrons.
10. The organic electroluminescent element according to item 8 or 9, wherein the carbazole derivative is a compound having a structure represented by Formula (SH):

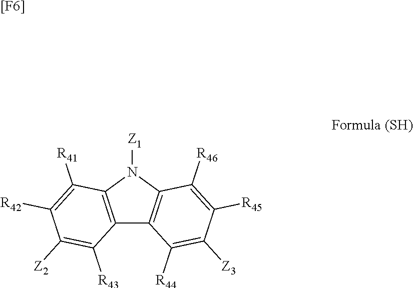

wherein Z₁ to Z₃ and R₄₁ to R₄₆ each independently represent a hydrogen atom or a substituent; at least one of Z₁ to Z₃ and R₄₁ to R₄₆ represents an aromatic cyclic group having 14 or more π-electrons; and adjacent substituents optionally form a ring structure through condensation.
11. The organic electroluminescent element according to item 10, wherein at least one of Z₁ to Z₃ in Formula (SH) is a substituted or unsubstituted benzofuran ring.
12. A light-emitting device including the organic electroluminescent element according to any one of items 1 to 11.
13. A lighting device including the organic electroluminescent element according to any one of items 1 to 11.
14. A display device including the organic electroluminescent element according to any one of items 1 to 11.
15. An electronic device including the organic electroluminescent element according to any one of items 1 to 11.

### Effects of Invention

The present invention can provide an organic electroluminescent element which emits blue light with high chromaticity and which exhibits high light emission efficiency over a long period of time. The present invention can also provide a light-emitting device, a lighting device, a display device, and an electronic device, each of the devices including the organic electroluminescent element.

As described above, an improvement in the light emission efficiency of a light-emitting material, which is a universal challenge, is in a trade-off relationship with the service life of an organic electroluminescent element, which should be prolonged for practical use. The degradation of the light emission efficiency of an organic electroluminescent element from the original level during a long-term operation indicates variations in properties of a thin charge-transporting film between electrodes under application of current and a microscopic variation occurring in the components of the film. In particular, such a variation in the light-emitting layer adversely affects the light emission efficiency of the organic EL element.

The aforementioned variation is likely to occur particularly in a blue light-emitting material in the excited state because the blue light-emitting material has an energy level higher than that of a red or green light-emitting material. Thus, formation of a light-emitting layer having high strength against electricity greatly contributes to a prolonged service life of an organic electroluminescent element that emits blue light.

The present inventors have found that the aforementioned problems can be solved by reducing a variation in structure or cohesion between excitons in a light-emitting layer through use of a light-emitting material having a small Stokes shift. A thin film containing a compound having a small Stokes shift exhibits favorable properties even after long-term application of current because molecular motion in the compound is significantly prevented in the excited state. Thus, the resultant organic EL element maintains its light emission efficiency at a high level over a long period of time.

### BRIEF DESCRIPTION OF THE DRAWINGS

FIG. 1A is a schematic illustration of an energy diagram on a common fluorescent compound and a typical TADF compound.

FIG. 1B is a schematic illustration of an energy diagram in the presence of an assist dopant.

FIG. 1C is a schematic illustration of an energy diagram in the case of a light-emitting compound according to the present invention serving as a host compound.

FIG. 2 is a schematic illustration of the energy transfer between the ground and excited states of a light-emitting material having a large Stokes shift.

FIG. 3 is a schematic illustration of the energy transfer between the ground and excited states of a light-emitting material having a small Stokes shift.

FIG. 4 is a schematic illustration of the energy levels of materials containing a host compound exhibiting a large difference in energy between HOMO and LUMO.

FIG. 5 is a schematic illustration of the energy levels of materials containing a host compound exhibiting a small difference in energy between HOMO and LUMO.

FIG. 6 is a schematic illustration of the energy levels of materials containing a host compound exhibiting a large difference between excited triplet energy level and HOMO energy level.

FIG. 7 is a schematic illustration of the energy levels of materials containing a host compound exhibiting a small difference between excited triplet energy level and HOMO energy level.

FIG. 8 is a graph showing the M-plot of electron transporting layers determined by impedance spectroscopy.

FIG. 9 is a graph showing the relationship between the ETL thickness and resistance of an organic EL element.

FIG. 10 is a schematic illustration of an equivalent circuit model of an organic EL element.

FIG. 11 is a graph showing the relationship between the resistance and voltage of layers of an initial organic EL element determined by impedance spectroscopy.

FIG. 12 is a graph showing the relationship between the resistance and voltage of layers of a degraded organic EL element determined by impedance spectroscopy.

FIG. 13 is a schematic view of a display device including an organic EL element.

FIG. 14 is a schematic view of an active matrix display device.

FIG. 15 is a schematic view of a pixel circuit.

FIG. 16 is a schematic view of a passive matrix display device.

FIG. 17 is a schematic view of a lighting device.

FIG. 18 is a schematic view of a lighting device.

### MODES FOR CARRYING OUT THE INVENTION

The organic electroluminescent element of the present invention includes an anode, a cathode, and at least one organic layer disposed between the anode and the cathode. The organic layer includes a light-emitting layer. The light-emitting layer contains a light-emitting compound having a Stokes shift of 0 to 0.24 eV and a lowest excited singlet energy level S₁ of 2.64 eV or more. This technical feature is common to Aspects 1 to 15 of the present invention.

In a preferred embodiment of the present invention, the light-emitting compound has a structure represented by Formula (1) for achieving the advantageous effects of the present invention.

The light-emitting compound preferably has a non-planar electronic conjugated structure due to weak planar intermolecular interaction (e.g., π-stacking) and low molecular cohesion of the light-emitting compound, resulting in improved light emission efficiency of the organic EL element and enhanced stability of the thin film.

The light-emitting compound preferably has a structure represented by Formula (2) for further enhancing the advantageous effects of the present invention.

In the present invention, the light-emitting compound preferably has a structure represented by Formula (3). This rigid aromatic structure increases the molecular rigidity of the compound and reduces the molecular planarity thereof, resulting in improved light emission efficiency of the organic EL element and enhanced stability of the thin film.

In the present invention, the light-emitting compound preferably has a structure represented by Formula (4). This rigid aromatic structure increases the molecular rigidity of the compound and reduces the molecular planarity thereof, resulting in improved light emission efficiency of the organic EL element and enhanced stability of the thin film.

In the present invention, the light-emitting compound preferably has a structure represented by Formula (5). This rigid aromatic structure increases the molecular rigidity of the compound and reduces the molecular planarity thereof, resulting in improved light emission efficiency of the organic EL element and enhanced stability of the thin film.

The light-emitting layer preferably contains a carbazole derivative because appropriate carrier hopping or dispersion of the light-emitting material is promoted in the light-emitting layer, resulting in improved light emission efficiency of the organic EL element and enhanced stability of the thin film.

The carbazole derivative is preferably a compound having two or more conjugated structures each having 14 or more π-electrons for further enhancing the advantageous effects of the present invention.

The carbazole derivative is preferably a compound having a structure represented by Formula (SH) for further enhancing the advantageous effects of the present invention.

In Formula (SH), at least one of Z₁ to Z₃ is preferably a substituted or unsubstituted benzofuran ring for further enhancing the advantageous effects of the present invention.

The organic electroluminescent element of the present invention is suitable for use in a light-emitting device. The light-emitting device including the organic electroluminescent element exhibits improved durability.

The organic electroluminescent element of the present invention is suitable for use in a lighting device. The lighting device including the organic electroluminescent element exhibits improved durability.

The organic electroluminescent element of the present invention is suitable for use in a display device. The display device including the organic electroluminescent element exhibits improved durability.

The organic electroluminescent element of the present invention is suitable for use in an electronic device. The electronic device including the organic electroluminescent element exhibits improved durability.

The present invention, the contexture thereof, and embodiments and aspects for implementing the present invention will now be described in detail. As used herein, the term to between two numerical values indicates that the numeric values before and after the term are inclusive as the lower limit value and the upper limit value, respectively.

Now will be described light emission modes of an organic EL element and light-emitting materials, which relate to the technical concept of the present invention.

### <Light Emission Mode of Organic EL Element>

Organic EL elements are based on two light emission modes; i.e., “phosphorescence,” which occurs during transfer of excitons from the triplet excitation state to the ground state, and “fluorescence,” which occurs during transfer of excitons from the singlet excitation state to the ground state.

Through electrical excitation of an organic EL element, triplet excitons are generated at a probability of 75%, and singlet excitons are generated at a probability of 25%. Thus, a phosphorescent mode exhibits light emission efficiency higher than that of a fluorescent mode, and is effective for reducing power consumption.

A novel fluorescent mode has been proposed which involves a triplet-triplet annihilation (TTA) mechanism (also called “triplet-triplet fusion (TTF)”) wherein light emission efficiency is improved by generating one singlet exciton from two triplet excitons of high density, which are generated at a probability of 75% and are generally thermally deactivated (i.e., non-radiative deactivation of the exciton energy).

In recent years, Adachi, et al. have reported that a reduced energy gap between the singlet excitation state and the triplet excitation state generates reverse intersystem crossing from the triplet excitation state (which has a lower energy level) to the singlet excitation state depending on the Joule heat during emission and/or the temperature around a light-emitting element, resulting in fluorescence at substantially 100% (this phenomenon may be referred to as “thermally activated delayed fluorescence (TADF)”). They have also reported a fluorescent substance that achieves this phenomenon (see, for example, NPL 1).

### <Phosphorescent Material>

As described above, phosphorescence is theoretically three times more advantageous than fluorescence in terms of light emission efficiency. Unfortunately, since energy deactivation from the triplet excitation state to the singlet ground state (i.e., phosphorescence) is a forbidden transition and the intersystem crossing from the singlet excitation state to the triplet excitation state is also a forbidden transition, the rate constant of such a transition is generally small; i.e., the transition is less likely to occur. Thus, the lifetime of excitons is on the order of milliseconds to seconds, and intended light emission is difficult to achieve.

In the case of light emission of a complex containing a heavy metal, such as iridium or platinum, the rate constant of the aforementioned forbidden transition increases by three or more orders of magnitude by the heavy atom effect of the central metal, and a phosphorescent quantum yield of 100% may be achieved depending on the ligand selected.

Unfortunately, such ideal light emission requires the use of a rare metal (noble metal), such as a platinum group metal (e.g., iridium, palladium, or platinum), and the use of large amounts of rare metals may cause industrial problems on the reserves and price of the metals.

### <Fluorescent Material>

Unlike the phosphorescent material, the fluorescent material is not necessarily a heavy metal complex, and may be an organic compound composed of combination of common elements, such as carbon, oxygen, nitrogen, and hydrogen. Alternatively, the fluorescent material may be substantially any substance; for example, a non-metal element, such as phosphorus, sulfur, or silicon, or a complex of a typical metal, such as aluminum or zinc.

The light-emitting compound (fluorescent material) used in the present invention has a Stokes shift of 0 to 0.24 eV and a lowest excited singlet energy level S₁ of 2.64 eV or more.

If the light-emitting compound having the aforementioned properties is used in the present invention, blue fluorescent light with high chromaticity can be emitted through radiative deactivation from the lowest excited singlet state to the ground state.

As used herein, the term “blue light with high chromaticity” is defined as light having an emission wavelength of 470 nm or less in the CIE chromaticity diagram. When the emission is a line spectrum, a wavelength λ of 470 nm corresponds to an emission energy E of about 2.64 eV.

The relationship between wavelength λ and energy E is represented by Expression (1):

E=hc/eλ Expression (1):

where h represents Planck constant (=6.626×10⁻³⁴ m²·kg/s), c represents light velocity (=2.998×10⁸ m/s), and e represents elementary charge (=1.602×10⁻¹⁹ C).

### <Stokes Shift>

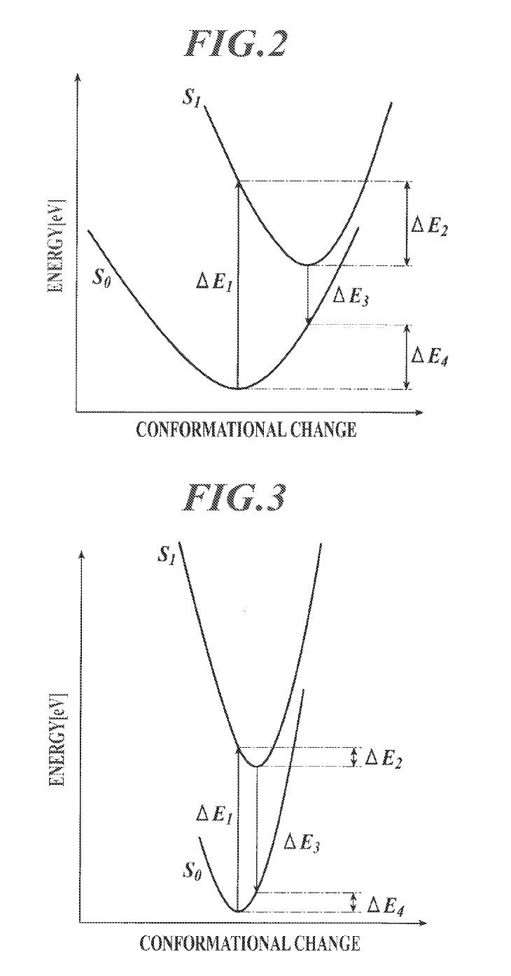

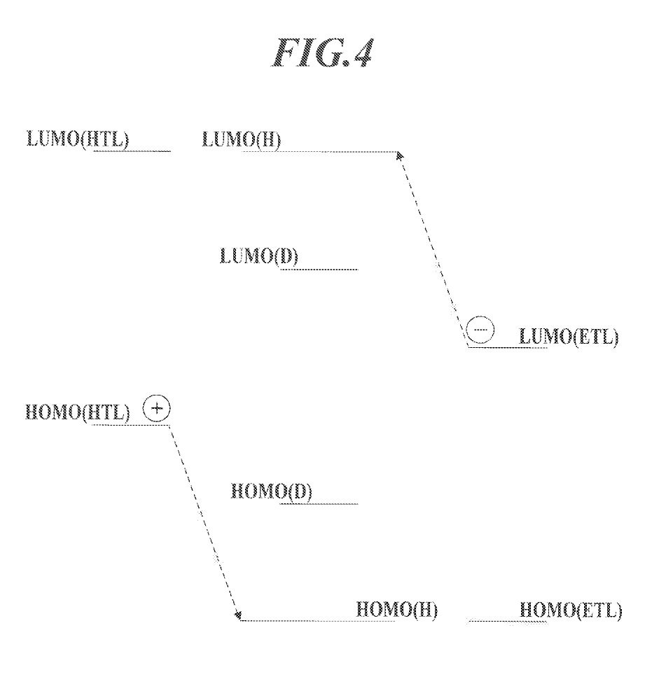

The Stokes shift is the difference between the excitation wavelength and emission wavelength of a light-emitting material during light emission of the material by photoexcitation. As used herein, the term “Stokes shift” also refers to the difference between the excitation wavelength and phosphorescence wavelength of a phosphorescent material. The Stokes shift reflects the difference between the energy absorbed by molecules during the generation of excitons and the energy consumed by light emission during the transfer of excitons to the ground state. FIGS. 2 and 3 schematically illustrate these energy relationships.

In FIGS. 2 and 3, ΔE₁ corresponds to the energy absorbed by a compound during excitation, and ΔE₃ corresponds to the energy radiated by excitons during light emission.

In FIGS. 2 and 3, the energy difference ΔE₂ or ΔE₄ corresponds to the energy consumed by a mechanism other than light emission. The consumption mechanism corresponds to, for example, thermal energy radiation due to a change in molecular conformation, and this phenomenon may occur in excitons generated by electrical excitation.

The energy lost by the consumption mechanism (i.e., the sum of ΔE₂ and ΔE₄) is called “reorientation energy.” Molecules having a small reorientation energy are advantageous for emission of light of short wavelength (large energy) because the molecules consume the energy during excitation substantially only for light emission.

In contrast, a compound having a large reorientation energy consumes the energy absorbed during excitation for thermal radiation due to a change in molecular conformation; i.e., the energy is inefficiently converted into light emission, resulting in a large Stokes shift.

The Stokes shift can be reduced by the molecular design of a light-emitting material having a small reorientation energy. In general, such a small Stokes shift is achieved by providing the light-emitting material with a rigid structure that is less likely to undergo a change in molecular conformation. A compound having a rigid structure is advantageous for efficient emission of light of short wavelength because the compound barely consumes the energy of excitons by a change in molecular conformation.

### <Energy Difference Between HOMO and LUMO>

A blue light-emitting fluorescent material is required to have an excited singlet energy level (i.e., energy difference between HOMO and LUMO) greater than that of a green or red light-emitting fluorescent material. For emission of blue light with high chromaticity, the fluorescent material should have a band gap of 2.64 eV or more even if the material exhibits a sharp light emission spectrum having a half width of about 20 nm.

For effective generation of excitons of the light-emitting material, the HOMO level of the host material is preferably lower than that of the light-emitting material, and the LUMO level of the host material is preferably higher than that of the light-emitting material.

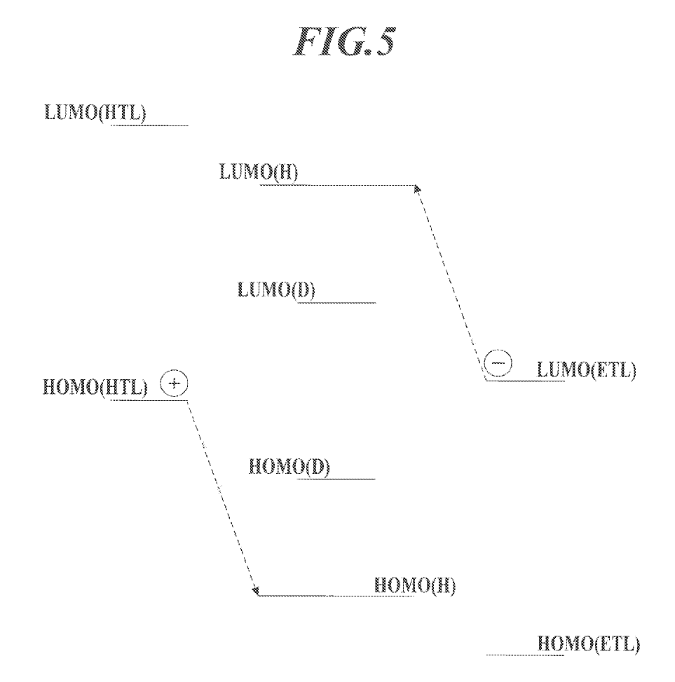

If the light-emitting material is a compound having a large Stokes shift (i.e., large energy loss or reorientation energy), a large excitation energy is necessary for a required emission wavelength, and thus the energy difference between HOMO and LUMO of the host material should be increased as shown in FIG. 4.

Specifically, in the case of a light-emitting material having a light emission energy (ΔE₃ in FIG. 2) of 2.64 eV and a Stokes shift (energy loss of excitons, the sum of ΔE₂ and ΔE₄ in FIG. 2) of 0.5 eV, the energy required for excitation (ΔE₁ in FIG. 2) should be higher by 0.5 eV than 2.64 eV.

In this case, the energy difference between HOMO and LUMO of the host material should be 3.14 eV or more for effective energy transfer from the host material to the light-emitting material. Thus, the HOMO and LUMO levels of the host material are approximate to those of an adjacent electron transporting layer or hole transporting layer.

An inappropriate difference in energy level between organic layers of the organic EL element leads to difficulty in injecting carriers into the light-emitting layer, resulting in an increase in driving voltage. Alternatively, carrier leakage is likely to occur from the light-emitting layer to an adjacent layer, resulting in a reduction in light emission efficiency of the organic EL element.

Thus, a large energy difference between HOMO and LUMO of the host material requires modification of the materials of layers other than the light-emitting layer, and the host material causes a limitation to the entire configuration of the organic EL element, which is undesirable for the design of the element.

In contrast, if the light-emitting material is a compound having a small Stokes shift, the energy difference between HOMO and LUMO required for light emission is minimized because of the small energy loss of excitons. Specifically, in the case of an ideal light-emitting material having an light emission energy (ΔE₃ in FIG. 2) of 2.64 eV and a Stokes shift (energy loss of excitons, the sum of ΔE₂ and ΔE₄ in FIG. 2) of 0.1 eV, the energy required for excitation (ΔE₁ in FIG. 2) is 2.74 eV. Thus, the energy difference between HOMO and LUMO of the host material is reduced as shown in FIG. 5, and the carrier balance is readily achieved in the entire organic EL element, resulting in an improvement in characteristics of the element. In addition, the host material is less likely to cause a limitation to the configurations of layers other than the light-emitting layer, which is preferred for the design of the element.

In the case of the phosphorescent material, light emission is attributed not to the excited singlet energy level, but to the excited triplet energy level. Thus, the excited triplet energy level should be 2.64 eV or more for emission of blue light.

For effective generation of excitons of the light-emitting material, the light-emitting material needs to be combined with a host material having an excited triplet energy level higher than that of the light-emitting material and a HOMO level lower than that of the light-emitting material.

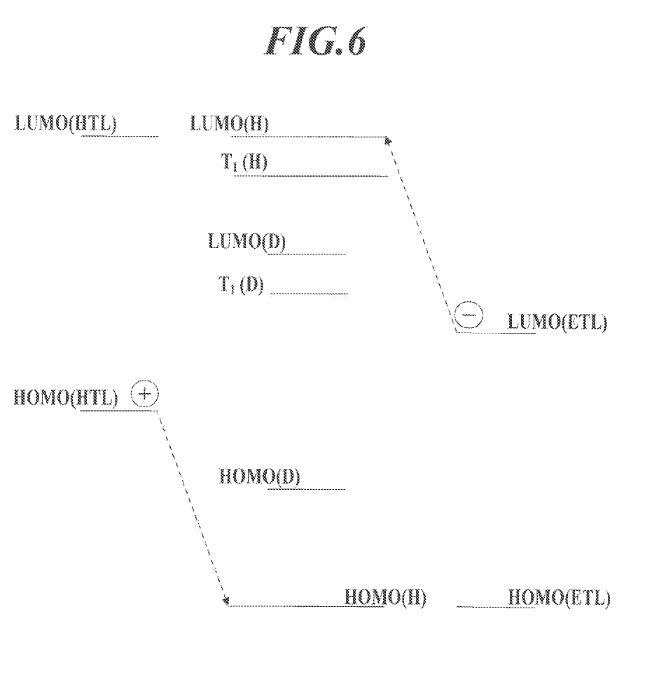

If the light-emitting material is a compound having a large Stokes shift (i.e., large energy loss or reorientation energy), a large excitation energy is necessary for a required emission wavelength, and thus the energy difference between excited triplet energy level and HOMO of the host material should be increased as shown in FIG. 6.

The LUMO energy level of molecules is generally higher than the excited triplet energy level of the molecules, and accordingly the energy difference between HOMO and LUMO of the host material needs to be increased. Thus, the HOMO and LUMO energy levels of the host material are approximate to those of an adjacent electron transporting layer or hole transporting layer.

An inappropriate difference in energy level between organic layers of the organic EL element leads to difficulty in injecting carriers into the light-emitting layer, resulting in an increase in driving voltage.

Alternatively, carrier leakage is likely to occur from the light-emitting layer to an adjacent layer, resulting in a reduction in light emission efficiency. Thus, a large energy difference between HOMO and LUMO of the host material requires modification of the materials for layers other than the light-emitting layer, and the host material causes a limitation to the entire configuration of the organic EL element, which is undesired for the design of the element.

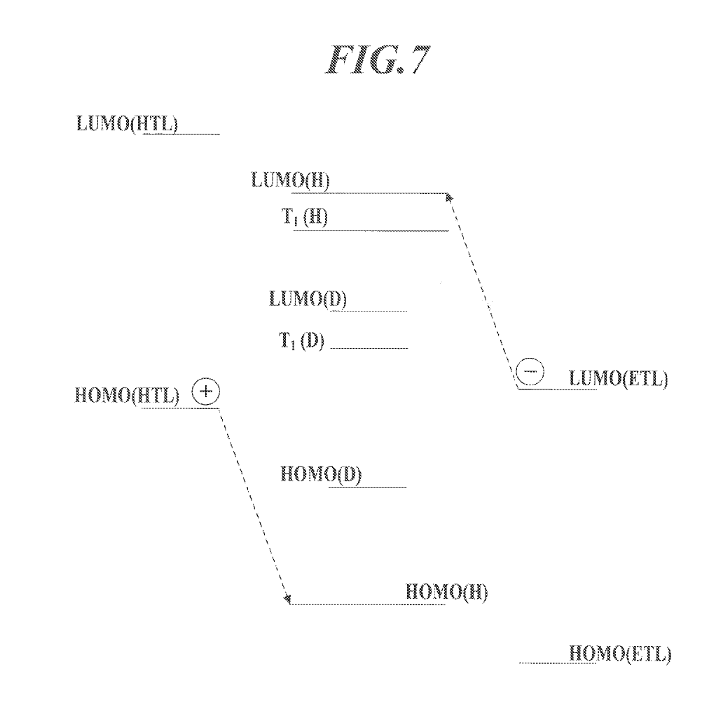

In contrast, if the light-emitting material is a compound having a small Stokes shift, the excited triplet energy level and HOMO required for emission is minimized because of the small energy loss of excitons. Thus, the energy difference between excited triplet energy level and HOMO of the host material is also reduced as shown in FIG. 7, and the carrier balance is readily achieved in the entire organic EL element, resulting in an improvement in light emission efficiency. In addition, the host material is less likely to cause a limitation to the configurations of layers other than the light-emitting layer, which is preferred for the design of the element.

In the case of a delayed fluorescent material, light emission is attributed only to the excited singlet energy level, and effective generation of excitons in the triplet excitation state is important for generation of a large number of excitons in the excited singlet state.

Thus, requirements for the host material are the same as in the case of the phosphorescent material. Specifically, if the light-emitting material is a compound having a small Stokes shift, the energy difference between excited triplet energy level and HOMO of the host material is reduced, and the carrier balance is readily achieved in the entire organic EL element, resulting in an improvement in light emission efficiency. In addition, the host material is less likely to cause a limitation to the configurations of layers other than the light-emitting layer, which is preferred for the design of the element.

As described above, a compound having a small Stokes shift has a small reorientation energy. In general, molecules having a small reorientation energy have a rigid structure and are restrained from rotation or atomic vibration.

Thus, a compound having a small Stokes shift probably exhibits high molecular stability during electrical excitation. In addition, the compound has a rigid structure, and thus molecular motion could be prevented in a thin film containing the compound even under application of voltage, resulting in an improvement in morphological stability of the thin film. Thus, a variation in state of molecules present in the thin film is reduced during application of voltage, leading to reduced variation in hole current and electron current over time. That is, a small variation in carrier recombination probability over time leads to prolonged service life of the organic EL element.

Accordingly, the present inventors have understood that a compound having a small Stokes shift can prolong the service life of the organic EL element by preventing deactivation of the exciton energy due to a change in molecular conformation, improving the carrier balance in the entire organic EL element, and improving the morphological stability of a thin film; i.e., the compound can be used as a superior blue light-emitting material.

Planar aromatic compounds have been developed as light-emitting materials having a rigid structure so far. In particular, an aromatic compound having a condensed ring structure is effective for an improvement in overall molecular rigidity. Typical examples of the compound having such a structure include anthracene, triphenylene, pyrene, and picene. In general, an increase in number of condensed rings leads to high molecular planarity and strong intermolecular interaction (e.g., π-stacking), resulting in high molecular cohesion. The molecular cohesion should be avoided in a light-emitting material for the organic EL element for the reasons described below.

### <Concentration Quenching>

In general, an organic compound exhibiting high light emission efficiency in the form of a dilute solution may cause concentration quenching; i.e., a significant reduction in light emission efficiency in the form of solid.

Concentration quenching is attributed to exciton quenching by the interaction between densely spaced organic molecules, or absorption of exciton emission by adjacent molecules.

Concentration quenching, which may cause a significant problem in the organic EL element, is generally prevented by diluting the light-emitting material with an appropriate host material.

A strong interaction between molecules of the light-emitting material leads to cohesion between the molecules, which causes local concentration quenching, resulting in a reduction in light emission efficiency of the organic EL element.

The cohesion between molecules of the light-emitting material also causes, for example, excimer fluorescence; i.e., light emission from composite excitons. In general, excimer fluorescent light has a wavelength longer than that of light emitted from a single molecule, and exhibits low light emission quantum efficiency. Thus, excimer fluorescence is not preferred for emission of blue light.

The interaction between adjacent excitons causes singlet-triplet annihilation or above-described triplet-triplet annihilation, resulting in exciton quenching.

Singlet-triplet annihilation is a phenomenon involving generation of molecules in the second triplet excitation state and molecules in the ground state through collision of molecules in the singlet excitation state and molecules in the triplet excitation state. For the reasons described above, the light-emitting material is preferably dispersed homogeneously in a host material, and the light emission properties of the organic EL element are greatly affected by the molecular design or the selection of a host material for preventing the cohesion between molecules of the light-emitting material.

As described above, the cohesion between molecules of the light-emitting material greatly affects a reduction in light emission efficiency, a variation in emission wavelength, and a decrease in service life of the organic EL element. Thus, reducing the cohesion between molecules of the light-emitting material is an important factor for developing a superior organic EL element.

In order to solve the aforementioned problems, a non-planar compound having high rigidity is preferably used as the light-emitting material.

For example, a compound having a twisted biaryl structure has no planarity and low molecular mobility.

Bifluorene, which is an aromatic compound having a spiro structure, has rigidity and low planarity. Helicene, which is composed of many helically linked aromatic rings, exhibits rigidity derived from a condensed ring structure and has a non-planar structure due to intramolecular strain.

Cyclophane, which is composed of a plurality of aromatic rings, also has a non-planar conjugated system. For example, Nakanishi, N. Hitosugi, S. Shimada, Y. Isobe, H., Chem. Asian. J., 2013, 8, 1177-1181 discloses that disilane pillared, which is composed of anthracene molecules cross-linked with two silicon atoms, has a very rigid step-terrace structure.

Disilane pillared is a unique compound having a step-terrace non-planar structure and exhibiting aromaticity due to σ-π conjugation.

Any of these compounds partially has planarity and aromaticity but has no planarity as an entire molecule. Thus, the light-emitting material containing such a compound as a basic structure is effective for preventing cohesion between molecules of the light-emitting material.

### <Carrier Hopping Properties>

In view of a prolonged service life of the organic EL element, the light-emitting material should have carrier hopping properties. For example, if the light-emitting material or the host material has poor hole transportability, holes (radical cations of the light-emitting material or the host material) accumulate at the interface between the hole transporting layer and the light-emitting layer, and emission due to carrier recombination occurs mainly at the interface.

If the light-emitting material or the host material has poor electron transportability, the aforementioned phenomenon may occur at the interface between the electron transporting layer and the light-emitting layer. In general, this phenomenon is not preferred in view of light emission efficiency and the service life of the organic EL element.

Excitons localized at the interface between the light-emitting layer and an adjacent layer lead to quenching caused by the interaction between excitons, resulting in a reduction in light emission efficiency. Examples of the quenching include singlet-triplet annihilation and triplet-triplet annihilation.

In the case of a fluorescent light-emitting material, singlet-triplet annihilation may cause a reduction in light emission efficiency, whereas in the case of a phosphorescent light-emitting material or a delayed fluorescent material, both singlet-triplet annihilation and triplet-triplet annihilation may cause a reduction in light emission efficiency. Transportation of holes or electrons by an organic material respectively corresponds to oxidation or reduction of the organic material.

Specifically, local emission at the interface between the light-emitting layer and a layer adjacent thereto indicates that electrochemical reaction of the organic material occurs only near the interface; i.e., a large load is applied only to a portion of the light-emitting layer. Thus, the organic material is readily degraded at the interface, resulting in a short service life of the organic EL element.

In a molecular design for improving the aforementioned carrier hopping properties, an organic compound used as a light-emitting material has one or more electron-accepting groups and one or more electron-donating groups. The presence of an electron-accepting group(s) and an electron-donating group(s) on a single molecule probably causes the spatial separation of the HOMO and LUMO in the molecule.

In an organic thin film, intermolecular electron transfer is caused by hopping conduction, which occurs in the presence of the HOMOs or LUMOs of adjacent two molecules.

Thus, the organic material exhibits both electron transportability and hole transportability through separation or localization of the HOMO and LUMO of the material, resulting in superior carrier transportability. That is, the light-emitting material exhibiting superior carrier transportability through separation of HOMO and LUMO can improve the morphological stability of the light-emitting layer; i.e., the light-emitting material is suitable for a prolonged service life of the organic EL element.

If a TADF compound is used as the light-emitting material, the ΔEst of the compound (i.e., the difference between excited singlet energy level and excited triplet energy level of the compound) should be sufficiently reduced for improving the TADF properties of the compound.

For a reduction in ΔEst of the compound, the HOMO and LUMO distributed over the molecule are preferably separated sufficiently.

For example, NPL 2 discloses that a TADF compound with a significant separation of HOMO and LUMO exhibits a sufficiently small ΔEst. Such a significant separation of HOMO and LUMO can be achieved by providing the light-emitting material with an electron-accepting group and an electron-donating group.

Thus, if a TADF compound is used as the light-emitting material, the presence of both electron-accepting and electron-donating moieties in the molecule is preferred for improving the carrier hopping properties and TADF properties of the compound. However, the emission principle of the light-emitting material should not be construed to limit the configuration of the present invention.

If any of the aforementioned planar and non-planar compounds is used as the light-emitting material, the planarity of the entire compound can be further reduced by appropriately selecting the structure of a substituent or a bonding moiety during introduction of electron-accepting and electron-donating groups in the molecule.

For example, the planarity of the entire compound can be reduced by introduction of a branched alkyl group or a substituent forming a twisted biaryl structure, resulting in low cohesion between molecules of the compound.

The present inventors have conducted extensive studies on the basis of the aforementioned findings and assumptions, and have found that a non-planar compound having an electronic conjugated system as a light-emitting material can produce a light-emitting element having favorable properties.

### <Delayed Fluorescent Material>

### [Excited Triplet-Triplet Annihilation (TTA) Delayed Fluorescent Material]

A light emission mode utilizing delayed fluorescence has been developed for solving the problems involved in a fluorescent material. The TTA mode, which is based on collision between triplet excitons, is described by the formula described below. Specifically, the TTA mode is advantageous in that a portion of triplet excitons, the energy of which would otherwise be converted into only heat by non-radiative deactivation, undergo reverse intersystem crossing, to generate singlet excitons that can contribute to light emission. In the organic EL element, the TTA mode can achieve an external quantum efficiency twice that obtained in a conventional fluorescent element.

T*+T*→S*+S Formula:

where T* represents a triplet exciton, S* represents a singlet exciton, and S represents a molecule in the ground state.

Unfortunately, the TTA mode fails to achieve 100% internal quantum efficiency in principle, because two triplet excitons generate only one singlet exciton that contributes to emission as illustrated in the aforementioned formula.

### [Thermally Activated Delayed Fluorescent (TADF) Material]

The TADF mode, which is another highly efficient fluorescent mode, can solve problems involved in the TTA mode.

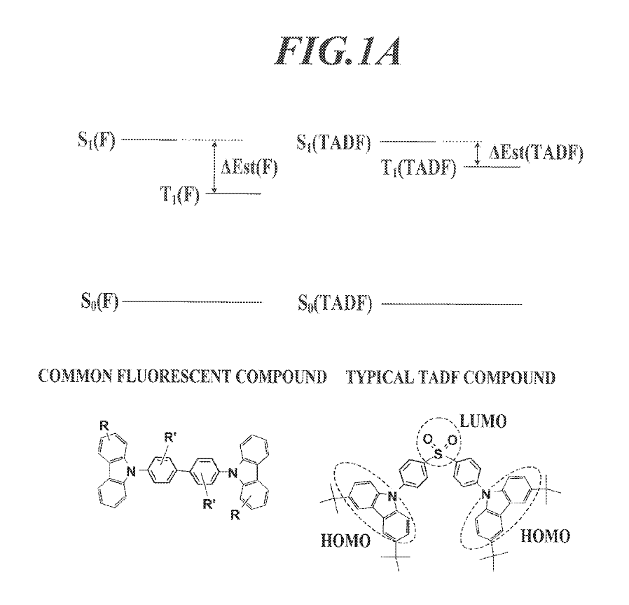

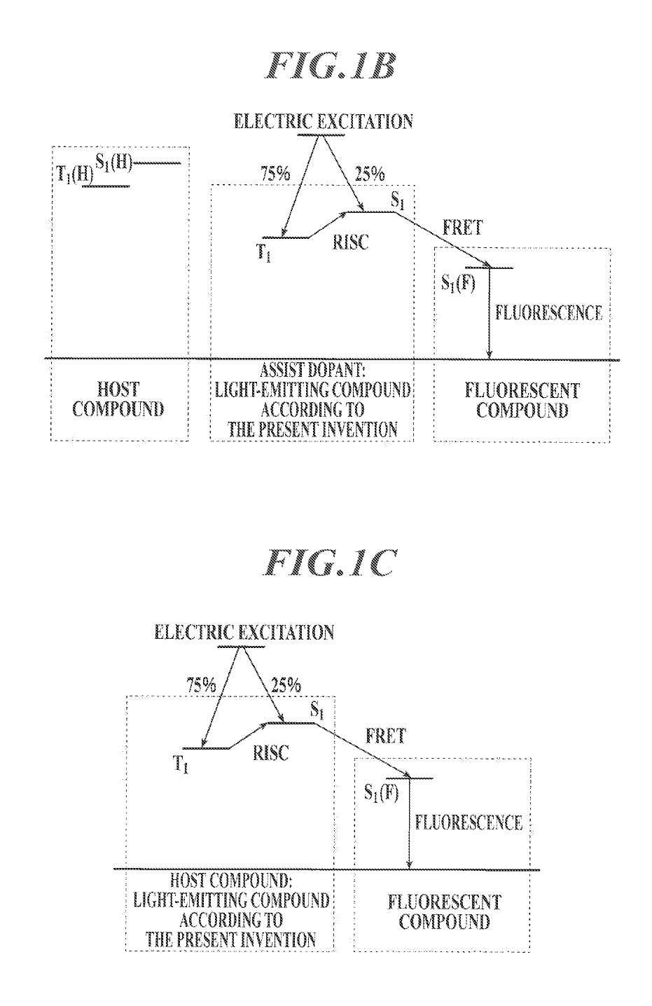

As described above, the fluorescent material has an advantage in terms of unlimited molecular design. Specifically, a molecularly designed compound exhibits a very small difference between excited triplet energy level and excited singlet energy level (hereinafter the difference will be referred to as “ΔEst”) (see FIG. 1A).

Such a compound, although having no heavy atom in the molecule, exhibits reverse intersystem crossing from the triplet excitation state to the singlet excitation state because of small ΔEst. Since the rate constant of deactivation from the singlet excitation state to the ground state (i.e., fluorescence) is very large, transfer of triplet excitons to the ground state via the singlet excitation state with emission of fluorescence is kinetically more advantageous than transfer of the triplet excitons to the ground state with thermal deactivation (non-radiative deactivation). Thus, the TADF mode can achieve 100% fluorescence in principle.

### <Molecular Design on ΔEst>

The molecular design for reducing ΔEst will now be described.

The most effective way for decreasing ΔEst in a molecule is to reduce the spatial overlap between the highest occupied molecular orbital (HOMO) and the lowest unoccupied molecular orbital (LUMO) in principle.

In general, HOMO is distributed over an electron-donating moiety, and LUMO is distributed over an electron-accepting moiety. Thus, the HOMO and LUMO in a molecule can be separated from each other through introduction of an electron donor and an electron acceptor into the molecule.

For example, NPL 1 discloses a technique in which LUMO and HOMO are separated from each other through introduction of an electron acceptor (e.g., a cyano group, a sulfonyl group, or triazine) and an electron donor (e.g., carbazole or a diphenylamino group).

Another effective way for decreasing ΔEst is to reduce a change in molecular structure of a compound between the ground state and the triplet excitation state by, for example, providing the compound with rigidity. As used herein, the term “rigidity” refers to a reduced number of freely movable portions in the molecule; for example, prevention of free rotation of the bond between rings in the molecule, or introduction of a condensed ring having a large n-conjugated surface. In particular, a change in molecular structure of a compound can be reduced in the excited state by providing a light-emitting moiety of the compound with rigidity.

<General problems of TADF material>

A TADF material poses various problems in terms of emission mechanism and molecular structure.

General problems involved in a TADF material will now be described.

In a TADF material, the HOMO moiety should be separated from the LUMO moiety for reducing ΔEst. Thus, the electronic state of a molecule is similar to a donor-acceptor intermolecular charge transfer (CT) state in which the HOMO and LUMO moieties are separated from each other.

If a plurality of such molecules is present, the molecular structure is stabilized by bringing the donor moiety of one molecule into close contact with the acceptor moiety of another molecule. Such stabilization can be achieved between two or more molecules (e.g., three molecules or five molecules). Thus, various stable states are provided, resulting broad absorption and emission spectra. Even in the case that a molecular aggregate is not formed from three or more molecules, various stable states are provided depending on the direction or angle of the interaction between the two molecules, resulting in broad absorption and emission spectra.

A broad emission spectrum poses two serious problems.

One problem is a reduction in color purity of emitted light. Reduced color purity does not cause serious problems when the organic EL element is used for lighting applications. Reduced color purity however precludes application of the organic EL element in a commercial electronic display, due to a reduction in region of color reproduction and poor color reproducibility.

The other problem is shortening of the rising wavelength (also called “fluorescent zero-zero band”) of an emission spectrum; i.e., an increase in lowest excited singlet energy level S₁.

If the fluorescent zero-zero band is shortened, the phosphorescent zero-zero band, which is derived from the energy level T₁ lower than S₁, is also shortened (i.e., an increase in T₁). Thus, the T₁ and S₁ of a host compound used should be increased for preventing reverse energy transfer from the dopant, which may result in serious problems.

The host compound, which is generally an organic compound, may be in the state of a plurality of unstable active chemical species (i.e., cationic radical state, anionic radical state, and excited state) in the organic EL element. Such chemical species can be relatively stabilized by extending an intramolecular π-conjugated system.

Unfortunately, an increase in S₁ and T₁ requires a reduction in size of the intramolecular π-conjugated system or cleavage of the π-conjugated system, which is in a trade-off relationship with the structural stability, resulting in short service life of the organic EL element.

In a TADF material containing no heavy atom, transition from the triplet excitation state to the ground state (energy deactivation) is forbidden, and thus the lifetime of excitons in the triplet excitation state is very long; i.e., on the order of several hundreds of microseconds to milliseconds. Thus, if the energy level T₁ of the host compound is higher than that of the light-emitting material, reverse energy transfer is highly likely to occur from the triplet excitation state of the light-emitting material to the host compound due to long lifetime of the excitons. Therefore, undesired reverse energy transfer to the host compound predominates over the intended reverse intersystem crossing of the TADF material from the triplet excitation state to the singlet excitation state, resulting in insufficient light emission efficiency.

In order to solve the aforementioned problems, the TADF material needs to be modified such that the material exhibits a sharp emission spectrum and a small difference between the maximum emission wavelength and the rising wavelength of the emission spectrum. This can be achieved by reducing a change in molecular structure between the singlet excitation state and the triplet excitation state.

In addition, the lifetime of excitons in the triplet excitation state of the TADF material is shortened for effectively preventing the reverse energy transfer to the host compound. This can be achieved by reducing a change in molecular structure between the ground state and the triplet excitation state, and introducing a substituent or element suitable for avoiding the forbidden transition.

As described above, the concept of the present invention includes a light-emitting material exhibiting reduced structural change in the excited state and shortened exciton lifetime in the triplet excitation state.

Now will be described methods of determining the properties of the light-emitting compound according to the present invention.

### <Electron Density Distribution>

In the light-emitting compound according to the present invention, it is preferred that the HOMO and the LUMO be substantially separated in molecules in view of a reduction in ΔEst. The distribution of the HOMO and the LUMO can be determined from the electron density distribution obtained through the structural optimization by molecular orbital calculation.

In the light-emitting compound according to the present invention, the structural optimization by molecular orbital calculation and determination of the electron density distribution can be performed with software for molecular orbital calculation using B3LYP (functional) and 6-31G(d) (basis function). The electron density distribution can be determined with any software.

The software for molecular orbital calculation used in the present invention is Gaussian 09 (Revision C.01, M. J. Frisch, et al., Gaussian, Inc., 2010).

As used herein, the expression “substantial separation of HOMO and LUMO” refers to separation of the centers of the HOMO and LUMO distributions determined by the aforementioned molecular orbital calculation, and more preferably, substantially no overlap between the HOMO and LUMO distributions.

Separation of the HOMO and the LUMO may be determined by the following expression: ΔEst=E(S₁)−E(T₁) where E(S₁) and E(T₁) are respectively the excited energy levels S₁ and T₁, which are calculated through the time-dependent density functional theory (time-dependent DFT) on the basis of the structural optimization determined using the aforementioned B3LYP (functional) and 6-31G(d) (basis function). A smaller ΔEst value indicates a larger distance between the HOMO and the LUMO. In the present invention, the ΔEst value calculated by the aforementioned method is preferably 0.5 eV or less, more preferably 0.2 eV or less, still more preferably 0.1 eV or less.

### <Lowest Excited Singlet Energy Level S₁>

In the present invention, the lowest excited singlet energy level S₁ of the light-emitting compound may be determined by a common technique. Specifically, a target compound is deposited onto a quartz substrate to prepare a sample, and an absorption spectrum of the sample is measured at ambient temperature (300 K) (vertical axis: absorbance, horizontal axis: wavelength). A tangential line is drawn at the rising point of the absorption spectrum on the longer wavelength side, and the lowest excited singlet energy level is calculated by a specific conversion expression on the basis of the wavelength at the point of intersection of the tangential line with the horizontal axis.

If the light-emitting compound used in the present invention is likely to cause molecular cohesion, a thin film prepared from the compound may cause a measurement error due to molecular cohesion. In the present invention, the lowest excited singlet energy level S₁ is determined from, as an approximation, the peak wavelength of emission of a solution of the light-emitting compound at room temperature (25° C.) in consideration of a relatively small Stokes shift of the light-emitting compound and a small change in structure of the compound between the excited state and the ground state. This determination process may use a solvent that is less likely to affect the molecular cohesion of the light-emitting compound; for example, a non-polar solvent, such as cyclohexane or toluene.

### <Determination of Stokes Shift>

The excitation (absorption) spectrum and emission spectrum of a solution of the light-emitting compound (prepared with an appropriate solvent, such as dichloromethane or chloroform) are measured with a fluorescent spectrometer (e.g., RF-5300 fluorescent spectrometer manufactured by Shimadzu Corporation, or F-4500 fluorescent spectrometer manufactured by Hitachi, Ltd.), and the “Stokes shift” can be determined as the difference between the maximum fluorescence wavelength and the maximum excitation (absorption) wavelength.

### <Evaluation of Light Emission Efficiency>

For evaluation of the light emission efficiency of the organic EL element of the present invention, the external quantum efficiency (%) of the element was determined in a certain environment (e.g., at 23° C. in an atmosphere of dry nitrogen gas) under application of a constant current (e.g., 2.5 mA/cm²). The external quantum efficiency was determined with a spectroradiometer CS-1000 (manufactured by Konica Minolta, Inc.).

### <Determination of Resistance of Thin Film by Impedance Spectroscopy>

Impedance spectroscopy is a technique for analyzing the properties of the organic EL element through conversion of a small change in properties of the element into an electric signal and amplification of the signal. This technique can determine the resistance (R) and capacitance (C) of the organic EL element at high sensitivity without causing breakage of the element.

Impedance spectroscopy typically involves analysis of electric properties with Z-plot, M-plot, and ∈-plot. The analytical process is detailed in, for example, “Hakumaku no Hyoka Handobukku (Handbook of Thin Film Characterization Technology)” (published by Technosystem Co., Ltd., pp. 423 to 425).

Now will be described a technique for impedance spectroscopic determination of the resistance of a specific layer of the organic EL element having, for example, the following configuration: ITO/(hole injecting layer (HIL))/(hole transporting layer (HTL))/(light-emitting layer (EML))/(electron transporting layer (ETL))/(electron injecting layer (EIL))/Al.

For measurement of the resistance of the electron transporting layer (ETL), for example, organic EL elements including ETLs having different thicknesses are prepared, and the M-plots of the elements are compared, to determine portions corresponding to the ETLs of the plotted curves.

FIG. 8 is a graph showing the M-plots of electron transporting layers having different thicknesses (30 nm, 45 nm, and 60 nm).

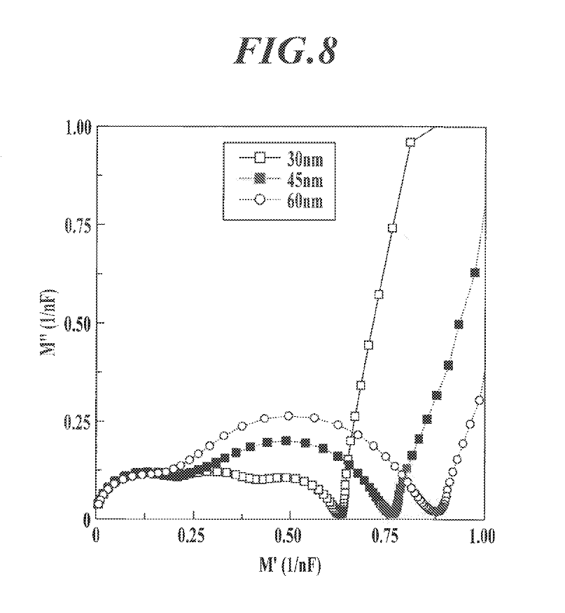

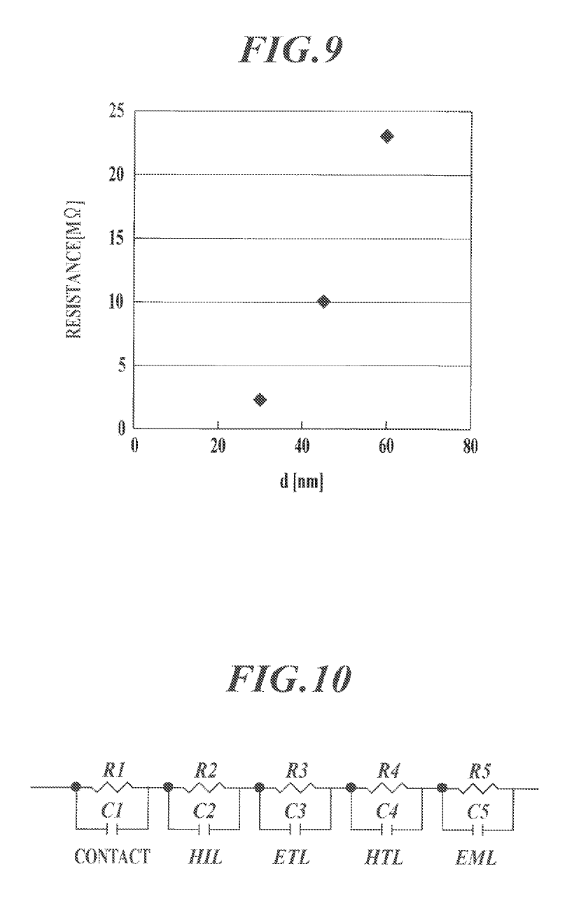

The resistances (R) determined from the M-plots are plotted against the thicknesses of the ETLs (see FIG. 9). The points are substantially on a single straight line, and thus the resistances can be determined at the corresponding thicknesses.

FIG. 9 is a graph showing the relationship between the ETL thicknesses and resistances of organic EL elements. As shown in FIG. 9 (the relationship between ETL thicknesses and resistances), the points are substantially on a single straight line, and thus the resistances can be determined at the corresponding thicknesses.

FIG. 11 shows the analytical results of the layers of an organic EL element in the form of an equivalent circuit model (FIG. 10), the organic EL element having the following configuration: ITO/HIL/HTL/EML/ETL/EIL/Al. FIG. 11 is a graph showing the relationship between voltages and the resistances of the layers.

FIG. 10 illustrates the equivalent circuit model of the organic EL element having the configuration: ITO/HIL/HTL/EML/ETL/EIL/Al.

FIG. 11 illustrates the analytical results of the organic EL element having the configuration of ITO/HIL/HTL/EML/ETL/EIL/Al.

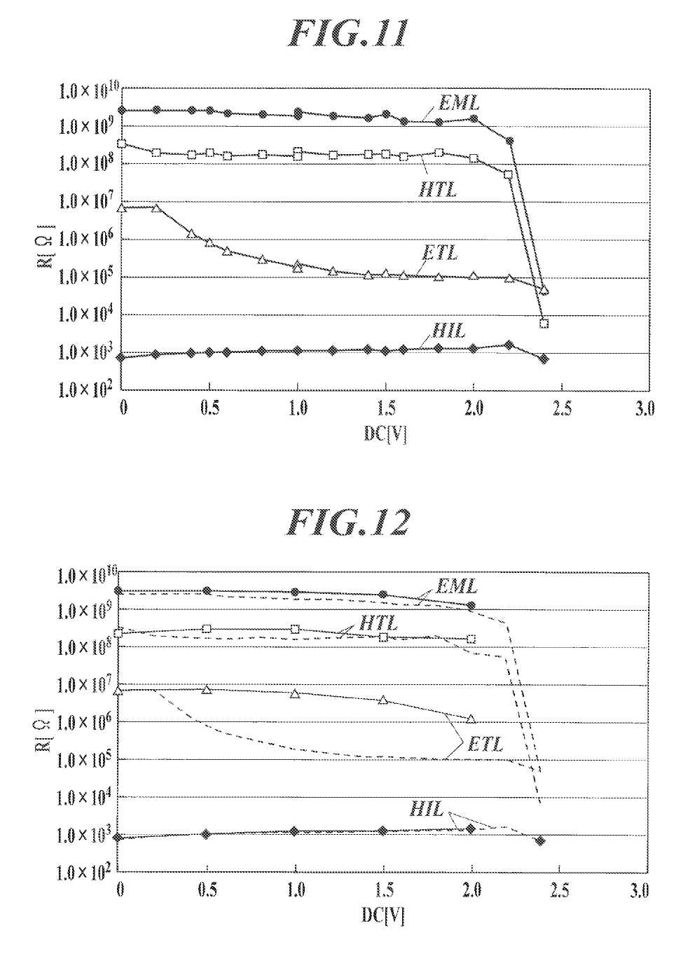

The organic EL element was caused to emit light for a long period of time, and the layers of the degraded organic EL element were analyzed under the same conditions as described above. FIG. 12 shows the analytical results before and after long-term driving. Table 1 shows the resistances of the layers at a voltage of 1V. FIG. 12 illustrates the analytical results of the degraded organic EL element.

TABLE 1

| | HIL(Ω) | ETL(Ω) | HTL(Ω) | EML(Ω) |
|---|---|---|---|---|
| Before driving | 1.1k | 0.2M | 0.2 G | 1.9 G |
| After degradation | 1.2k | 5.7M | 0.3 G | 2.9 G |

The results demonstrate that the resistance (at a DC voltage of 1 V) of only the ETL significantly increases by a factor of about 30 in the degraded organic EL element.

As described in the Examples below, a change in resistance of the organic EL element before and after application of current can be determined by the aforementioned methods.

### <<Layer Configuration of Organic EL Element>>

The organic electroluminescent (EL) element of the present invention includes an anode, a cathode, and at least one organic layer disposed between the anode and the cathode, the organic layer including a light-emitting layer, wherein the light-emitting layer contains a light-emitting compound having a Stokes shift of 0 to 0.24 eV and a lowest excited singlet energy level S₁ of 2.64 eV or more.

Now will be described the respective layers of the organic EL element, and compounds contained in the layers.

Typical examples of the configuration of the organic EL element of the present invention include, but are not limited to, the following configurations.

(1) Anode/light-emitting layer/cathode

(2) Anode/light-emitting layer/electron transporting layer/cathode

(3) Anode/hole transporting layer/light-emitting layer/cathode

(4) Anode/hole transporting layer/light-emitting layer/electron transporting layer/cathode

(5) Anode/hole transporting layer/light-emitting layer/electron transporting layer/electron injecting layer/cathode

(6) Anode/hole injecting layer/hole transporting layer/light-emitting layer/electron transporting layer/cathode

(7) Anode/hole injecting layer/hole transporting layer/(electron blocking layer)/light-emitting layer/(hole blocking layer)/electron transporting layer/electron injecting layer/cathode

Among the aforementioned configurations, configuration (7) is preferred, but any other configuration may be used.

The light-emitting layer used in the present invention is composed of a single layer or a plurality of sublayers. A light-emitting layer composed of a plurality of light-emitting sublayers may include a non-luminescent intermediate sublayer between the light-emitting sublayers.

A hole blocking layer (also referred to as “hole barrier layer”) or an electron injecting layer (also referred to as “cathode buffer layer”) may optionally be disposed between the light-emitting layer and the cathode. An electron blocking layer (also referred to as “electron barrier layer”) or a hole injecting layer (also referred to as “anode buffer layer”) may be disposed between the light-emitting layer and the anode.

The electron transporting layer used in the present invention, which has a function of transporting electrons, encompasses the electron injecting layer and the hole blocking layer in a broad sense. The electron transporting layer may be composed of a plurality of sublayers.

The hole transporting layer used in the present invention, which has a function of transporting holes, encompasses the hole injecting layer and the electron blocking layer in a broad sense. The hole transporting layer may be composed of a plurality of sublayers.

In the typical configurations described above, any of the layers other than the anode and the cathode may also be referred to as “organic layer.”

### (Tandem Structure)

The organic EL element of the present invention may have a tandem structure including a plurality of light-emitting units each including at least one light-emitting layer.

A typical tandem structure of the organic EL element is as follows:

Anode/first light-emitting unit/intermediate layer/second light-emitting unit/intermediate layer/third light-emitting unit/cathode

In this structure, the first, second, and third light-emitting units may be identical to or different from one another. Any two of the light-emitting units may be identical to each other, and may be different from the remaining one unit.

Two light-emitting units may be bonded directly to each other, or an intermediate layer may be disposed therebetween. The intermediate layer is generally also called “intermediate electrode,” “intermediate conductive layer,” “charge generating layer,” “electron extraction layer,” “connection layer,” or “intermediate insulating layer.” Any known material can be used for forming an intermediate layer capable of supplying electrons to the adjacent layer on the anode and supplying holes to the adjacent layer on the cathode.

Examples of the material used for the intermediate layer include, but are not limited to, conductive inorganic compounds, such as indium tin oxide (ITO), indium zinc oxide (IZO), ZnO₂, TiN, ZrN, HfN, TiOₓ, VOₓ, CuI, InN, GaN, CuAlO₂, CuGaO₂, SrCu₂O₂, LaB₆, RuO₂, and Al; two-layer films, such as Au/Bi₂O₃; multi-layer films, such as SnO₂/Ag/SnO₂, ZnO/Ag/ZnO, Bi₂O₃/Au/Si₂O₃, TiO₂/TiN/TiO₂, and TiO₂/ZrN/TiO₂; fullerene compounds, such as C₆₀; conductive organic substances, such as oligothiophene; and conductive organic compounds, such as metal phthalocyanines, metal-free phthalocyanines, metal porphyrins, and metal-free porphyrins.

Examples of preferred light-emitting units include, but are not limited to, the aforementioned typical device configurations (1) to (7) (exclusive of the anode and the cathode).

Specific examples of tandem organic EL elements include, but are not limited to, device configurations and constituent materials disclosed in U.S. Pat. Nos. 6,337,492, 7,420,203, 7,473,923, 6,872,472, 6,107,734, and 6,337,492, International Patent Publication WO2005/009087, Japanese Patent Application Laid-Open Publication Nos. 2006-228712, 2006-24791, 2006-49393, 2006-49394, 2006-49396, 2011-96679, and 2005-340187, Japanese Patent Nos. 4711424, 3496681, 3884564, and 4213169, Japanese Patent Application Laid-Open Publication Nos. 2010-192719, 2009-076929, 2008-078414, 2007-059848, 2003-272860, and 2003-045676, and International Patent Publication WO2005/094130.

Now will be described the respective layers forming the organic EL element of the present invention.

### <<Light-Emitting Layer>>

The light-emitting layer according to the present invention is a layer where electrons and holes injected from the electrodes or adjacent layers are recombined to emit light through excitons. A light emission portion may be located within the light-emitting layer or at the interface between the light-emitting layer and the layer adjacent thereto. The light-emitting layer may have any configuration satisfying the requirements of the present invention.

The light-emitting layer may have any total thickness. The light-emitting layer has a total thickness of preferably nm to 5 μm, more preferably 2 to 500 nm, still more preferably 5 to 200 nm, in view of the homogeneity of the layer, inhibition of application of unnecessarily high voltage upon light emission, and an improvement in stability of emission color against driving current.

Each of the sublayers forming the light-emitting layer has a thickness of preferably 2 nm to 1 μm, more preferably 2 to 200 nm, still more preferably 3 to 150 nm.

The light-emitting layer according to the present invention preferably contains the aforementioned light-emitting material as a light-emitting dopant (also referred to as “light-emitting compound”, “light-emitting dopant compound”, “dopant compound,” or “dopant”) and the aforementioned host compound (also referred to as “matrix material”, “light-emitting host compound”, or “host”).

### (1) Light-Emitting Dopant

The light-emitting dopant is preferably a fluorescent dopant (also referred to as “fluorescent compound”) or a phosphorescent dopant (also referred as “phosphorescent compound”). In the present invention, at least one light-emitting layer preferably contains any of the aforementioned light-emitting materials.

The concentration of the light-emitting dopant in the light-emitting layer may be appropriately determined depending on the type of the dopant used and the requirements for the device. The light-emitting layer may contain the light-emitting dopant at a uniform concentration across the thickness, or may have any concentration profile of the light-emitting dopant.

In the present invention, two or more light-emitting dopants may be used in combination. Specifically, dopants having different structures may be used in combination, or a fluorescent dopant may be used in combination with a phosphorescent dopant. Thus, the organic EL element can emit light of any color.

In the present invention, if the light-emitting layer contains a known light-emitting compound and a host compound, the light-emitting compound according to the present invention is preferably used as an assist dopant. If the light-emitting layer contains the light-emitting compound according to the present invention and a known light-emitting compound, but does not contain a host compound, the light-emitting compound according to the present invention is preferably used as a host compound.

In any case, the mechanism by which the advantageous effects of the present invention are expressed is based on conversion of triplet excitons generated in the light-emitting compound according to the present invention into single excitons through reverse intersystem crossing (RISC).

Accordingly, the overall exciton energy generated in the light-emitting compound according to the present invention theoretically undergoes fluorescence resonance energy transfer (FRET)), resulting in high light emission efficiency.

Thus, if the light-emitting layer contains the light-emitting compound according to the present invention, a known light-emitting compound, and a host compound, the energy levels S₁ and T₁ of the light-emitting compound according to the present invention are preferably lower than the energy levels S₁ and T₁ of the host compound and higher than the energy levels S₁ and T₁ of the known light-emitting compound.

Similarly, if the light-emitting layer contains the light-emitting compound according to the present invention and a known light-emitting compound, the energy levels S₁ and T₁ of the light-emitting compound according to the present invention are preferably higher than the energy levels S₁ and T₁ of the known light-emitting compound.

FIG. 1B schematically illustrates the case where the light-emitting compound according to the present invention serves as an assist dopant, and FIG. 1C schematically illustrates the case where the light-emitting compound serves as a host compound. Although FIGS. 1B and 1C illustrate the case where electric excitation generates triplet excitons in the light-emitting compound according to the present invention, the excitons may be generated through energy transfer or electron transfer in the light-emitting layer or from the interface between the light-emitting layer and a layer adjacent thereto.

Although FIGS. 1B and 1C illustrate the case where the light-emitting material is a fluorescent compound, the light-emitting material may be a phosphorescent compound or may be both a fluorescent compound and a phosphorescent compound.

If the light-emitting compound according to the present invention is used as an assist dopant, the light-emitting layer preferably contains a host compound in an amount of 100% or more by mass relative to the light-emitting compound, and a fluorescent compound and/or a phosphorescent compound in an amount of 0.1 to 50% by mass relative to the light-emitting compound. If the light-emitting compound according to the present invention is used as an assist dopant, incorporation of the host compound and the fluorescent compound and/or the phosphorescent compound in the aforementioned amounts results in effective fluorescence resonance energy transfer (FRET) to the fluorescent compound and/or the phosphorescent compound.

If the light-emitting compound according to the present invention is used as a host compound, the light-emitting layer preferably contains a fluorescent compound and/or a phosphorescent compound in an amount of 0.1 to 50% by mass relative to the light-emitting compound. Incorporation of the fluorescent compound and/or the phosphorescent compound in the aforementioned amount results in a preferred interaction between the light-emitting compound and the fluorescent compound and/or the phosphorescent compound.

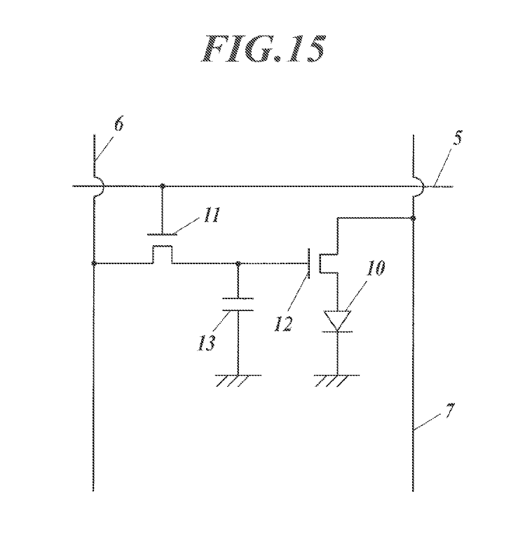

The color of light emitted from the organic EL element or compound according to the present invention is determined by applying values obtained with a spectroradiometer CS-1000 (manufactured by Konica Minolta, Inc.) to the CIE chromaticity coordinate shown in FIG. 14.16 on page 108 of “Shinpen Shikisai Kagaku Handobukku (Handbook of Color Science, New Edition)” (edited by the Color Science Association of Japan, published from University of Tokyo Press, 1985).

In the present invention, one or more light-emitting layers preferably contain a plurality of light-emitting dopants that emit light of different colors to emit white light.

The light-emitting layers may contain any combination of light-emitting dopants that emit white light; for example, a combination of blue and orange light-emitting dopants, or a combination of blue, green, and red light-emitting dopants.

For emission of white light from the organic EL element of the present invention, when 2-degree viewing angle front luminance is determined by the aforementioned process, the chromaticity in the CIE 1931 Color Specification System at 1,000 cd/m² preferably falls within a region of x=0.39±0.09 and y=0.38±0.08.

### (1.1) Light-Emitting Dopant

The light-emitting compound according to the present invention preferably has a structure represented by Formula (1). Examples of the light-emitting compound according to the present invention include fluorescent compounds, phosphorescent compounds, and delayed fluorescent compounds.

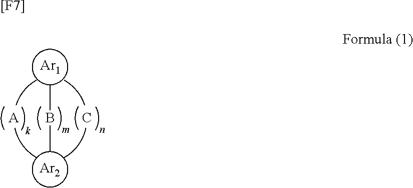

In Formula (1), A, B, and C each independently represent a single bond or a linking group containing a carbon, silicon, or oxygen atom; Ar₁ and Ar₂ each independently represent an aromatic hydrocarbon or heterocyclic group optionally having a condensed ring structure; Ar₁ and Ar₂ may be identical to each other; k represents a natural number and if k is 2 or more, the groups A may be different from one another; m is 0 or a natural number and if m is 2 or more, the groups B may be different from one another; n is 0 or a natural number and if n is 2 or more, the groups C may be different from one another; and each of A, B, and C may independently link Ar₁ and Ar₂ with a single bond or through formation of a condensed ring.

The light-emitting compound preferably has a non-planar electronic conjugated structure. This structure reduces a planar intermolecular interaction (e.g., π-stacking) and cohesion between molecules of the light-emitting compound, resulting in improved light emission efficiency of the organic EL element and enhanced stability of thin films.

The light-emitting compound according to the present invention preferably has a structure represented by Formula (2).

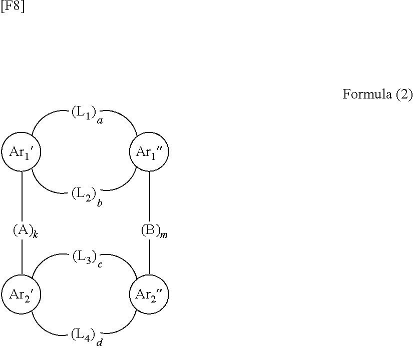

In Formula (2), Ar₁′, Ar₁″, Ar₂′, and Ar₂″ may be identical to or different from one another and each independently represent an aromatic hydrocarbon or heterocyclic group optionally having a condensed ring structure and a substituent; Ar₁′ and Ar₁″ may form a condensed ring, and Ar₂′ and Ar₂″ may form a condensed ring; a, b, c, and d each represent 0 or a natural number; a or b represents a natural number; c or d represents a natural number; L₁ and L₂ each represent a single bond or divalent linking group that links Ar₁′ and Ar₁″; Ar₁′ and Ar₁″ may form a condensed ring with L₁ and L₂; L₃ and L₄ each represent a single bond or divalent linking group that links Ar₂′ and Ar₂″; Ar₂′ and Ar₂″ may form a condensed ring with L₃ and L₄; if a, b, c, or d is 2 or more, the groups L₁, L₂, L₃, or L₄ may be identical to or different from one another; k and m each represent 0 or a natural number; k or m represents a natural number; A and B each represent a single bond or a divalent linking group; if k or m is 2 or more, the groups A or B may be identical to or different from one another; and Ar₁′, Ar₂′, and A may form a condensed ring, and Ar₁″, Ar₂″, and B may form a condensed ring.

The light-emitting compound according to the present invention preferably has a structure represented by Formula (3).

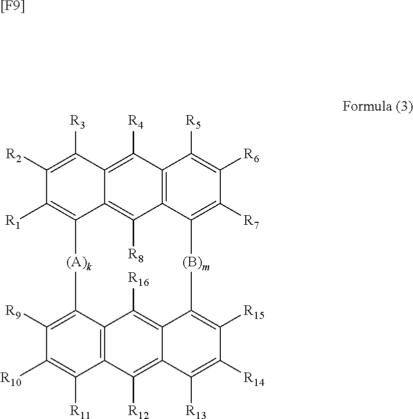

In Formula (3), A and B each independently represent a single bond or a linking group containing a carbon or silicon atom; two anthracene rings linked by A and/or B may form a condensed ring with R₁, R₉, and A or with R₇, R₁₅, and B; k represents a natural number, and if k is 2 or more, the groups A may be different from one another; R₁ to R₁₆ each represent a substituted or unsubstituted aliphatic hydrocarbon group or a substituted or unsubstituted aromatic hydrocarbon group, and may form a ring; each of R₁ to R₁₆ may be a heteroaromatic hydrocarbon group containing a nitrogen, oxygen, or sulfur atom; m represents 0 or a natural number and if m is 2 or more, the groups B may be different from one another; and each of the two anthracene rings linked by A and/or B may have a non-planar electronic conjugated structure, or the two anthracene rings may form a single aromatic ring.

The light-emitting compound according to the present invention preferably has a structure represented by Formula (4).

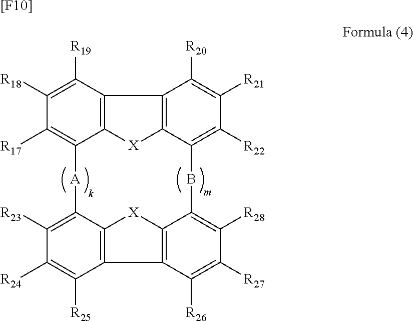

In Formula (4), X represents boron, carbon, nitrogen, oxygen, sulfur, or silicon; X optionally has a hydrogen atom or a substituent; R₁₇ to R₂₈ each independently represent a hydrogen atom or a substituent; two aromatic rings linked by A and/or B may form a condensed ring structure with any of R₁₇ to R₂₈, A, and B; k and m each represent 0 or a natural number; k or m represents a natural number; A and B each represent a single bond or a divalent linking group; if k or m is 2 or more, the groups A or B may be identical to or different from one another; and each of the two aromatic rings linked by A and/or B may have a non-planar electronic conjugated structure, or the two aromatic rings may form a single aromatic ring.

The light-emitting compound according to the present invention preferably has a structure represented by Formula (5).

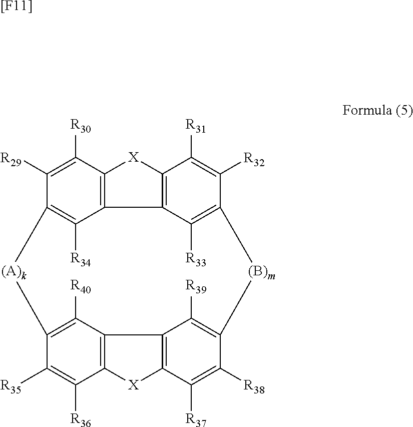

In Formula (5), X represents boron, carbon, nitrogen, oxygen, sulfur, or silicon; X optionally has a hydrogen atom or a substituent; R₂₉ to R₄₀ each represent a hydrogen atom or a substituent; two aromatic rings linked by A and/or B may form a condensed ring structure with any of R₂₉ to R₄₀, A, and B; k and m each represent 0 or a natural number; k or m represents a natural number; A and B each represent a single bond or a divalent linking group; if k or m is 2 or more, the groups A or B may be identical to or different from one another; and each of the two aromatic rings linked by A and/or B may have a non-planar electronic conjugated structure, or the two aromatic rings may form a single aromatic ring.

Examples of preferred light-emitting compounds used in the present invention include, but are not limited to, the following compounds.

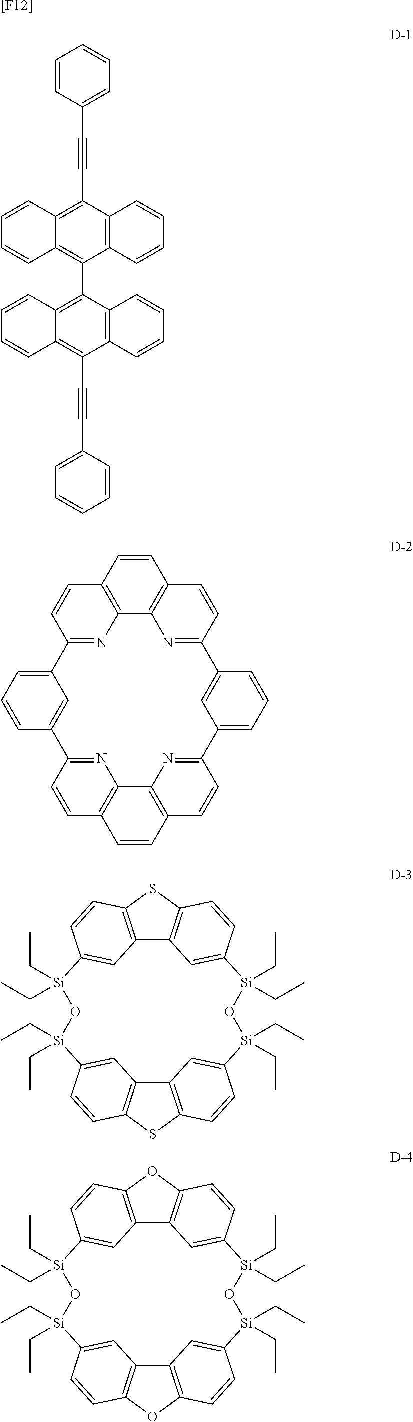

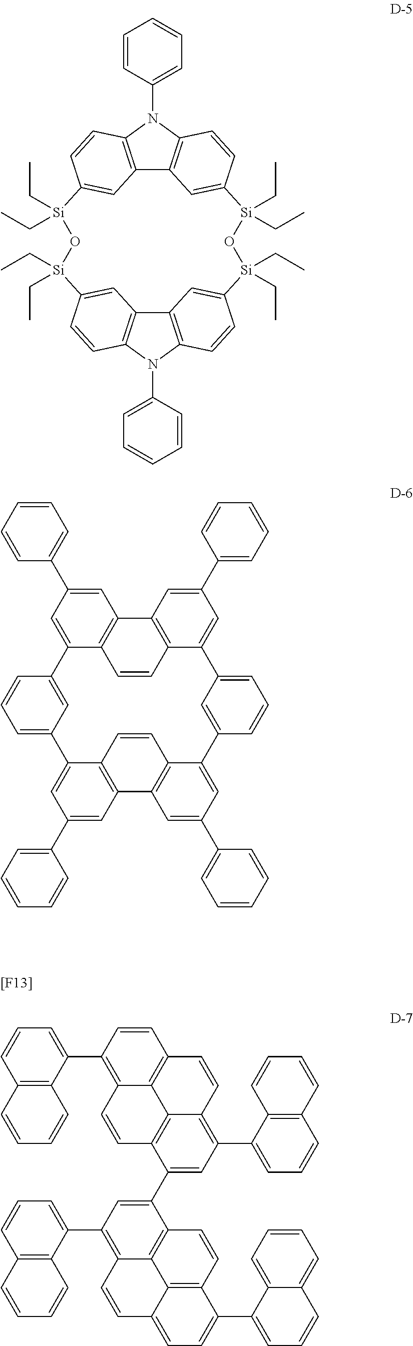

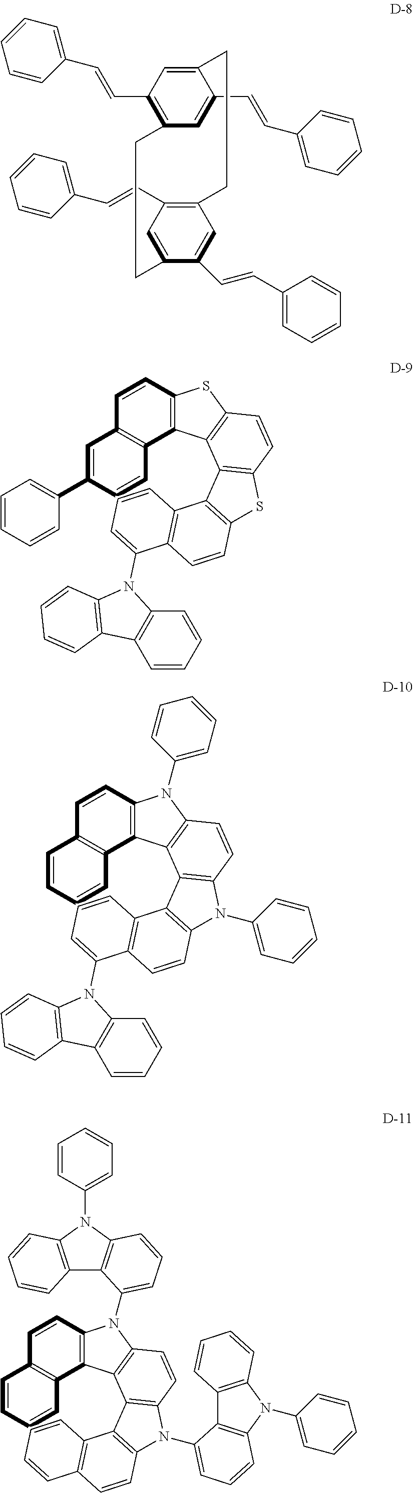

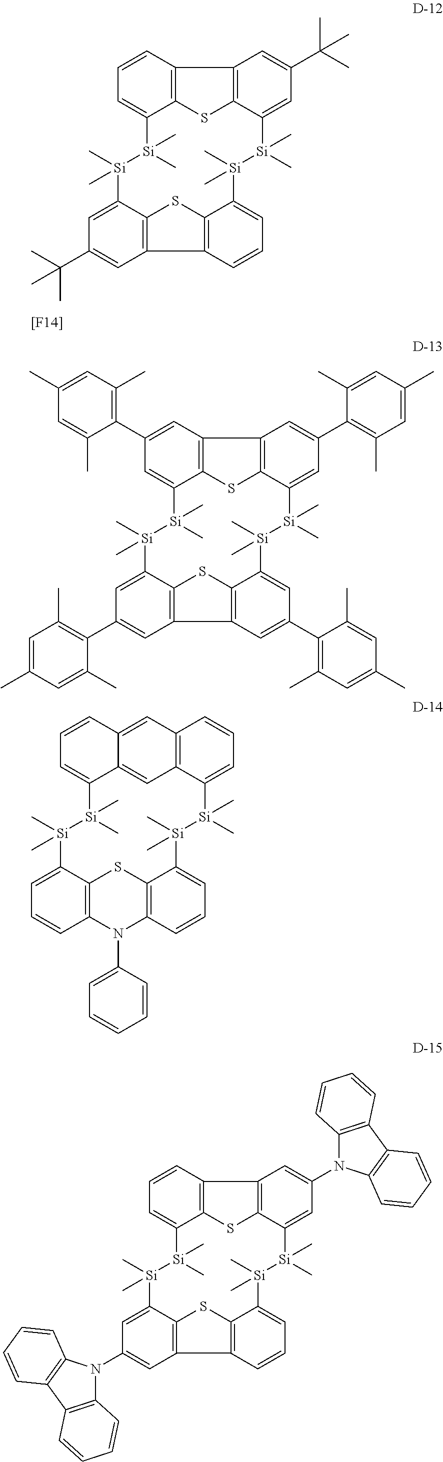

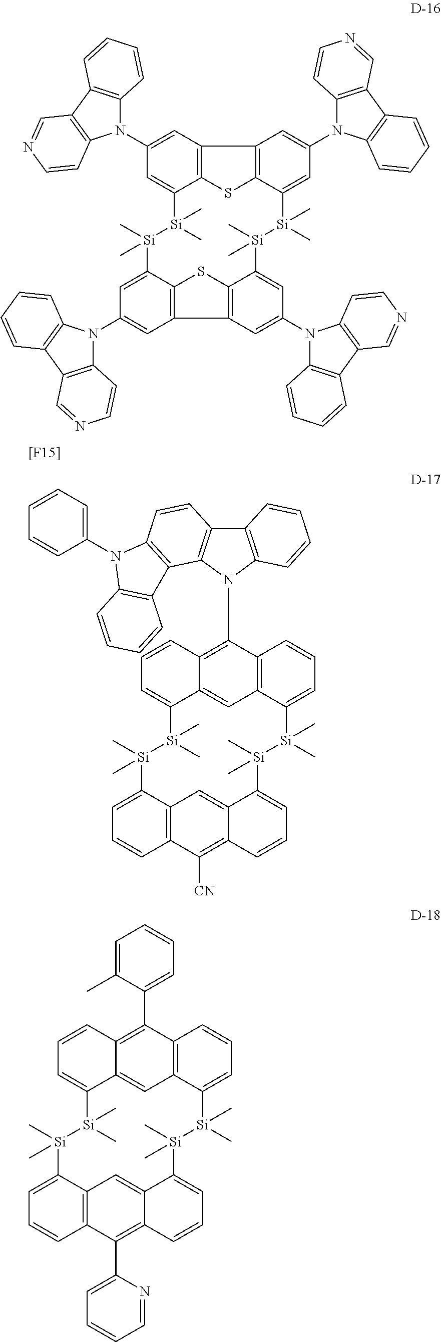

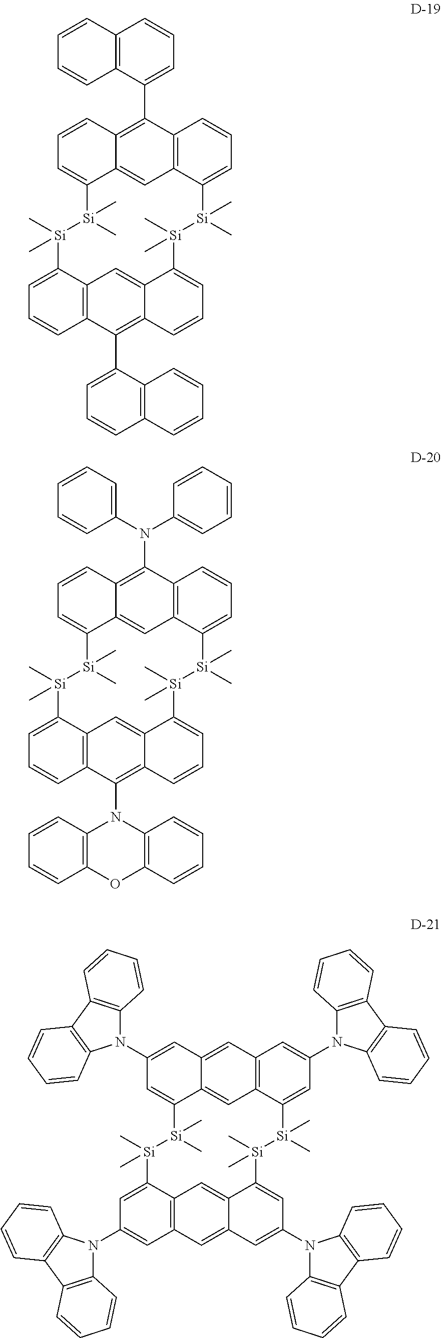

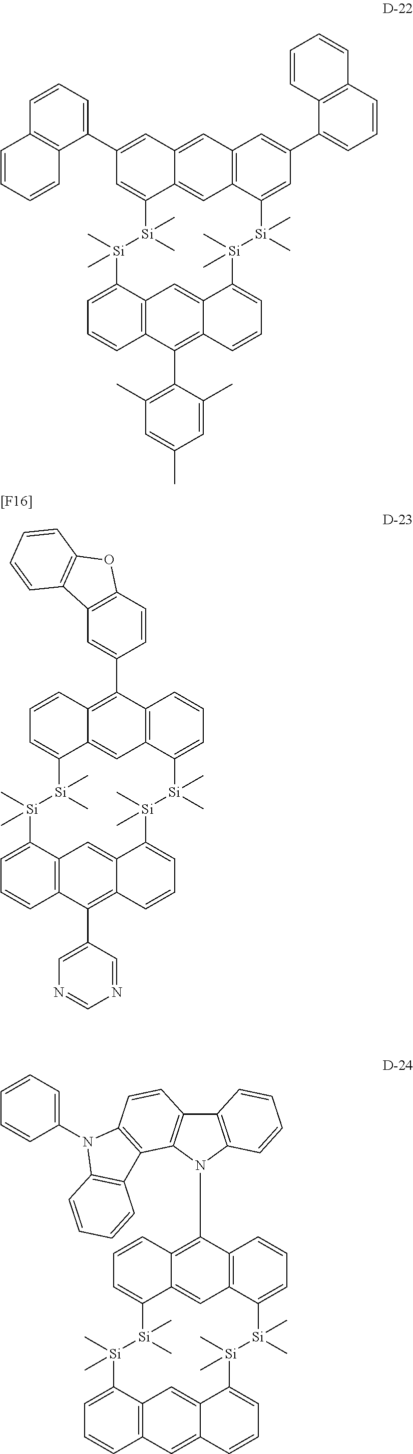

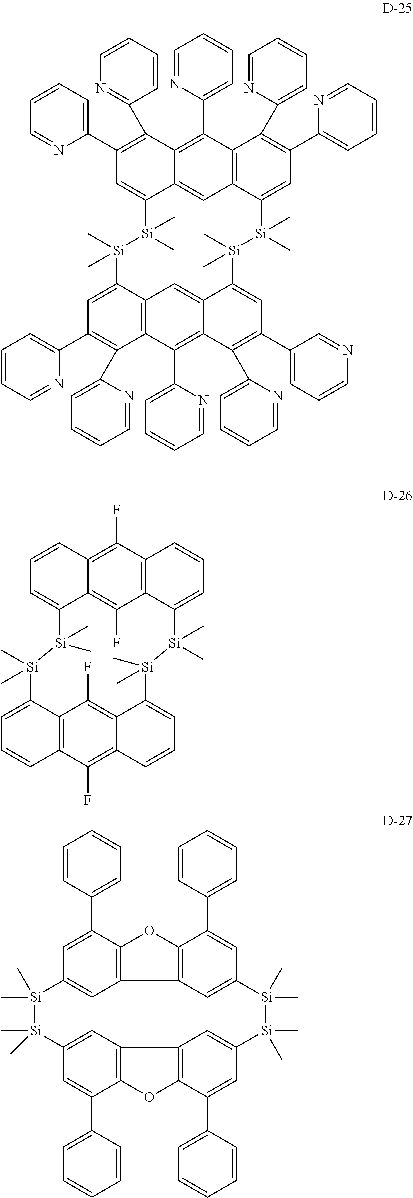

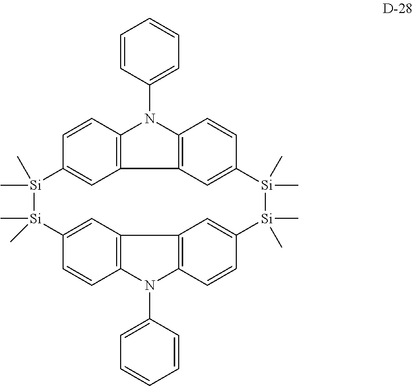

### (1.2) Phosphorescent Dopant

Now will be described the phosphorescent dopant used in the present invention.

Phosphorescent Dopant used in the present invention emits light from the excited triplet state. Specifically, the phosphorescent compound is defined as a compound which emits phosphorescent light at room temperature (25° C.) and has a phosphorescent quantum yield of 0.01 or more at 25° C. The preferred phosphorescent quantum yield is 0.1 or more.

The phosphorescent quantum yield is determined by the method described in page 398 of Bunko II of Jikken Kagaku Koza 7 (Spectroscopy II, Experimental Chemistry 7) (4th Edition, 1992, published by Maruzen Company, Limited). The phosphorescent quantum yield in a solution can be determined with any suitable solvent. The phosphorescent dopant used in the present invention has a phosphorescent quantum yield of 0.01 or more determined with any appropriate solvent.

The phosphorescent compound may be appropriately selected from known ones used for the luminous layer of a common organic EL element. Specific examples of known phosphorescent dopants usable in the present invention include compounds described in the following publications.

Examples of compounds are described in Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), International Patent Publication WO2009/100991, WO2008/101842, and WO2003/040257, U.S. Patent Application Publication Nos. 2006/835469, 2006/0202194, 2007/0087321, and 2005/0244673, Inorg. Chem. 40, 1704 (2001), Chem. Mater. 16, 2480 (2004), Adv. Mater. 16, 2003 (2004), Angew. Chem. lnt. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), International Patent Publication WO2009/050290, WO2002/015645, and WO2009/000673, U.S. Patent Application Publication No. 2002/0034656, U.S. Pat. No. 7,332,232, U.S. Patent Application Publication Nos. 2009/0108737 and 2009/0039776, U.S. Pat. Nos. 6,921,915 and 6,687,266, U.S. Patent Application Publication Nos. 2007/0190359, 2006/0008670, 2009/0165846, and 2008/0015355, U.S. Pat. Nos. 7,250,226 and 7,396,598, U.S. Patent Application Publication Nos. 2006/0263635, 2003/0138657, and 2003/0152802, U.S. Pat. No. 7,090,928, Angew. Chem. lnt. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), International Patent Publication WO2002/002714, WO2006/009024, WO2006/056418, WO2005/019373, WO2005/123873, WO2005/123873, WO2007/004380, and WO2006/082742, U.S. Patent Application Publication Nos. 2006/0251923 and 2005/0260441, U.S. Pat. Nos. 7,393,599, 7,534,505, and 7,445,855, U.S. Patent Application Publication Nos. 2007/0190359 and 2008/0297033, U.S. Pat. No. 7,338,722, U.S. Patent Application Publication No. 2002/0134984, U.S. Pat. No. 7,279,704, U.S. Patent Application Publication Nos. 2006/098120 and 2006/103874, International Patent Publication WO2005/076380, WO2010/032663, WO2008/140115, WO2007/052431, WO2011/134013, WO2011/157339, WO2010/086089, WO2009/113646, WO2012/020327, WO2011/051404, WO2011/004639, and WO2011/073149, U.S. Patent Application Publication Nos. 2012/228583 and 2012/212126, and Japanese Unexamined Patent Application Publication Nos. 2012-069737, 2012-195554, 2009-114086, 2003-81988, 2002-302671, and 2002-363552.

In the present invention, the phosphorescent dopant is preferably an organometallic complex containing Ir as a central metal, more preferably a complex containing at least one coordination mode of metal-carbon bond, metal-nitrogen bond, metal-oxygen bond, and metal-sulfur bond.

### (2) Host Compound

In the present invention, the host compound is used for injection and transportation of carriers in the light-emitting layer. The host compound emits substantially no light in the organic EL element.

The host compound is preferably contained in the light-emitting layer in an amount of 20 mass % or more.

A single host compound may be used, or a plurality of host compounds may be used in combination. The use of a plurality of host compounds leads to control of charge transfer, resulting in high light emission efficiency of the organic EL element.

Now will be described host compounds preferably used in the present invention.

In the present invention, any host compound may be used in combination with the light-emitting compound. In view of reverse energy transfer, the host compound used in the present invention preferably has an excited singlet energy level higher than that of the light-emitting compound according to the present invention, and more preferably, the host compound has an excited triplet energy level higher than that of the light-emitting compound.

In the light-emitting layer, the host compound transports carriers and generates excitons. Preferably, the host compound is stable in the state of active chemical species (i.e., cationic radical state, anionic radical state, and excited state) and does not undergo any chemical change (e.g., decomposition or addition reaction). More preferably, molecules of the host compound do not migrate in the light-emitting layer on the order of angstrom during application of current.

If the light-emitting dopant used in combination with the host compound exhibits TADF emission, the TADF material is present in the triplet excitation state for a long period of time, and thus appropriate molecular design is required for the host compound for preventing a reduction in T₁. Requirements for the molecular design include an increase in energy level T₁ of the host compound, an increase in energy level T₁ of associated molecules of the host compound, no exciplex formation between the TADF material and the host compound, and no electromer formation from the host compound by electric excitation.

In order to satisfy such requirements, the host compound needs to exhibit high electron hopping mobility and high hole hopping mobility, and to undergo a small change in structure in the triplet excitation state. The host compound satisfying such requirements is preferably a compound partially having an extended π-conjugated structure (14-π-electron system) exhibiting high energy level T₁, such as a structure of carbazole, azacarbazole, dibenzofuran, dibenzothiophene, or azadibenzofuran. In particular, incorporation of a carbazole derivative into the light-emitting layer is preferred for appropriate promotion of carrier hopping and dispersion of the light-emitting material in the light-emitting layer, resulting in improved light emission efficiency of the organic EL element and enhanced stability of the thin film.

Typical examples of the host compound include compounds having a biaryl ring structure and/or a multi-aryl ring structure. As used herein, the term “aryl” refers to both an aromatic hydrocarbon ring and an aromatic heterocyclic ring.

The host compound is more preferably a compound prepared by direct bonding between a carbazole structure and an aromatic heterocyclic compound having a 14-π-electron system and a molecular structure different from the carbazole structure, more preferably a carbazole derivative having, in the molecule, two or more aromatic heterocyclic rings having a 14-π-electron system. In particular, the carbazole derivative is preferably a compound having two or more conjugated structures each having 14 or more π-electrons for further enhancing the advantageous effects of the present invention.

The host compound used in the present invention is also preferably a compound represented by Formula (I), because the compound represented by Formula (I) has a condensed ring structure (i.e., extended π-electron clouds), high carrier transportability, and high glass transition temperature (Tg). Although a condensed aromatic ring generally has a low excited triplet energy level (T₁), a compound represented by Formula (I) has a high T₁ and is suitable for use in the light-emitting material having a short emission wavelength (i.e., high T₁ and S₁).

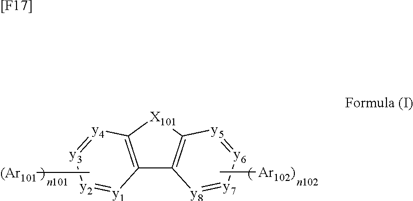

In Formula (I), X₁₀₁ represents NR₁₀₁, an oxygen atom, a sulfur atom, CR₁₀₂R₁₀₃, or SiR₁₀₂R₁₀₃, and y₁ to y₈ each represent CR₁₀₄ or a nitrogen atom.

R₁₀₁ to R₁₀₄ each represent a hydrogen atom or a substituent and may be bonded together to form a ring.

Ar₁₀₁ and Ar₁₀₂ each represent an aromatic ring and may be identical to or different from each other.

In Formula (I), n101 and n102 each represents an integer of 0 to 4 and if R₁₀₁ is a hydrogen atom, n101 is 1 to 4.

In Formula (I), R₁₀₁ to R₁₀₄ each represent a hydrogen atom or a substituent. The host compound used in the present invention may have any substituent that does not impede the function of the host compound. For example, the present invention encompasses a compound in which such a substituent is introduced through a synthetic scheme and which exhibits the advantageous effects of the present invention.

Examples of the substituent represented by R₁₀₁ to R₁₀₄ include linear or branched alkyl groups (e.g., methyl, ethyl, propyl, isopropyl, t-butyl, pentyl, hexyl, octyl, dodecyl, tridecyl, tetradecyl, and pentadecyl), alkenyl groups (e.g., vinyl and allyl), alkynyl groups (e.g., ethynyl and propargyl), aromatic hydrocarbon groups (also referred to as aromatic carbon groups or aryl groups, such as groups derived from rings of benzene, biphenyl, naphthalene, azulene, anthracene, phenanthrene, pyrene, chrysene, naphthacene, triphenylene, o-terphenyl, m-terphenyl, terphenyl, acenaphthene, coronene, indene, fluorene, fluoranthrene, naphthacene, pentacene, perylene, pentaphene, picene, pyrene, pyranthrene, anthranthrene, and tetralin), aromatic heterocyclic groups (e.g., groups derived from rings of furan, dibenzofuran, thiophene, dibenzothiophene, oxazole, pyrrole, pyridine, pyridazine, pyrimidine, pyrazine, triazine, benzimidazole, oxadiazole, triazole, imidazole, pyrazole, thiazole, indole, indazole, benzimidazole, benzothiazole, benzoxazole, quinoxaline, quinazoline, cinnoline, quinoline, isoquinoline, phthalazine, naphthyridine, carbazole, carboline, and diazacarbazole (one of the carbon atoms forming the carboline ring is replaced with a nitrogen atom in the ring); a carboline ring and a diazacarbazole ring may be collectively referred to as “azacarbazole ring”), non-aromatic hydrocarbon groups (e.g., cyclopentyl and cyclohexyl), non-aromatic heterocyclic groups (e.g., pyrrolidyl, imidazolidyl, morpholyl, and oxazolidyl), alkoxy groups (e.g., methoxy, ethoxy, propyloxy, pentyloxy, hexyloxy, octyloxy, and dodecyloxy), cycloalkoxy groups (e.g., cyclopentyloxy and cyclohexyloxy), aryloxy groups (e.g., phenoxy and naphthyloxy), alkylthio groups (e.g., methylthio, ethylthio, propylthio, pentylthio, hexylthio, octylthio, and dodecylthio), cycloalkylthio groups (e.g., cyclopentylthio and cyclohexylthio), arylthio groups (e.g., phenylthio and naphthylthio), alkoxycarbonyl groups (e.g., methyloxycarbonyl, ethyloxycarbonyl, butyloxycarbonyl, octyloxycarbonyl, and dodecyloxycarbonyl), aryloxycarbonyl groups (e.g., phenyloxycarbonyl and naphthyloxycarbonyl), sulfamoyl groups (e.g., aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, and 2-pyridylaminosulfonyl), acyl groups (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, and pyridylcarbonyl), acyloxy groups (e.g., acetyloxy, ethylcarbonyloxy, butylcarbonyloxy, octylcarbonyloxy, dodecylcarbonyloxy, and phenylcarbonyloxy), amido groups (e.g., methylcarbonylamino, ethylcarbonylamino, dimethylcarbonylamino, propylcarbonylamino, pentylcarbonylamino, cyclohexylcarbonylamino, 2-ethyhexylcarbonylamino, octylcarbonylamino, dodecylcarbonylamino, phenylcarbonylamino, and naphthylcarbonylamino), carbamoyl groups (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, and 2-pyridylaminocarbonyl), ureido groups (e.g., methylureido, ethylureido, pentylureido, cyclohexylureido, octylureido, dodecylureido, phenylureido, naphthylureido, and 2-pyridylaminoureido), sulfinyl groups (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, and 2-pyridylsulfinyl), alkylsulfonyl groups (e.g., methylsulfonyl, ethylsulfonyl, butylsulfonyl, cyclohexylsulfonyl, 2-ethylhexylsulfonyl, and dodecylsulfonyl), arylsulfonyl and heteroarylsulfonyl groups (e.g., phenylsulfonyl, naphthylsulfonyl, and 2-pyridylsulfonyl), amino groups (e.g., amino, ethylamino, dimethylamino, butylamino, cyclopentylamino, 2-ethylhexylamino, dodecylamino, anilino, naphthylamino, and 2-pyridylamino), halogen atoms (e.g., fluorine, chlorine, and bromine), fluorohydrocarbon groups (e.g., fluoromethyl, trifluoromethyl, pentafluoromethyl, and pentafluorophenyl), a cyano group, a nitro group, a hydroxy group, a thiol group, silyl groups (e.g., trimethylsilyl, triisopropylsilyl, triphenylsilyl, and phenyldiethylsilyl), and atomic deuterium.

These substituents may further have any of the aforementioned substituents. These substituents may be bonded together to form a ring.

In Formula (I), preferably, at least three of y₁ to y₄ or at least three of y₅ to y₈ are CR₁₀₂, and more preferably, all of y₁ to y₈ are CR₁₀₂. Such a structure exhibits high hole transportability or high electron transportability. Thus, holes and electrons injected from the anode and the cathode are efficiently recombined in the light-emitting layer, to emit light.

Particularly preferred is a compound represented by Formula (I) wherein X₁₀₁ is NR₁₀₁, an oxygen atom, or a sulfur atom, the compound having a low energy level of LUMO and exhibiting high electron transportability. The condensed ring formed by X₁₀₁ and y₁ to y₈ is more preferably a carbazole ring, an azacarbazole ring, a dibenzofuran ring, or an azadibenzofuran ring.

In view that the host compound preferably has rigidity, when X₁₀₁ is NR₁₀₁, R₁₀₁ is preferably an aromatic hydrocarbon group or an aromatic heterocyclic group, which has a π-conjugated structure. R₁₀₁ may further have a substituent represented by R₁₀₁ to R₁₀₃.

In Formula (I), the aromatic ring represented by Ar₁₀₁ or Ar₁₀₂ is an aromatic hydrocarbon ring or an aromatic heterocyclic ring. The aromatic ring may be a single ring or a condensed ring. The aromatic ring may be unsubstituted or may have a substituent similar to that represented by R₁₀₁ to R₁₀₄.

In Formula (I), the aromatic hydrocarbon ring represented by Ar₁₀₁ or Ar₁₀₂ may be similar to that exemplified above as a substituent represented by R₁₀₁ to R₁₀₄.

In the partial structure represented by Formula (I), the aromatic heterocyclic ring represented by Ar₁₀₁ or Ar₁₀₂ may be similar to that exemplified above as a substituent represented by R₁₀₁ to R₁₀₄.

In view that the host compound represented by Formula (I) should have a high T₁, the aromatic ring represented by Ar₁₀₁ or Ar₁₀₂ preferably has a high T₁. Examples of preferred aromatic rings include rings of benzene (including polyphenylene structures composed of a plurality of linked benzene rings (e.g., biphenyl, terphenyl, and quarterphenyl)), fluorene, triphenylene, carbazole, azacarbazole, dibenzofuran, azadibenzofuran, dibenzothiophene, dibenzothiophene, pyridine, pyrazine, indoloindole, indole, benzofuran, benzothiophene, imidazole, and triazine. More preferred are rings of benzene, carbazole, azacarbazole, and dibenzofuran.

If Ar₁₀₁ or Ar₁₀₂ is a carbazole ring or an azacarbazole ring, the ring is more preferably bonded at position N (also referred to as “position 9”) or position 3.

If Ar₁₀₁ or Ar₁₀₂ is a dibenzofuran ring, the ring is more preferably bonded at position 2 or 4.

In view of the use of the organic EL element in a vehicle, the host compound preferably has a high Tg under the assumption that the temperature in the vehicle increases to a high level. In a preferred embodiment, the aromatic ring represented by Ar₁₀₁ or Ar₁₀₂ is a condensed ring composed of three or more rings for increasing the Tg of the host compound represented by Formula (I).

Specific examples of the aromatic hydrocarbon condensed ring composed of three or more rings include rings of naphthacene, anthracene, tetracene, pentacene, hexacene, phenanthrene, pyrene, benzopyrene, benzazulene, chrysene, benzochrysene, acenaphthene, acenaphthylene, triphenylene, coronene, benzocoronene, hexabenzocoronene, fluorene, benzofluorene, fluoranthene, perylene, naphthoperylene, pentabenzoperylene, benzoperylene, pentaphene, picene, pyranthrene, coronene, naphthocoronene, ovalene, and anthranthrene. Each of these rings may further have any of the aforementioned substituents.

Specific examples of the aromatic heterocyclic ring composed of three or more rings include rings of acridine, benzoquinoline, carbazole, carboline, phenazine, phenanthridine, phenanthroline, carboline, cyclazine, quindoline, tepenidine, quinindoline, triphenodithiazine, triphenodioxazine, phenanthrazine, anthrazine, perimidine, diazacarbazole (any one of the carbon atoms forming the carboline ring is replaced with a nitrogen atom in the ring), phenanthroline, dibenzofuran, dibenzothiophene, naphthofuran, naphthothiophene, benzodifuran, benzodithiophene, naphthodifuran, naphthodithiophene, anthrafuran, anthradifuran, anthrathiophene, anthradithiophene, thianthrene, phenoxathiine, and thiophanthrene (naphthothiophene). Each of these rings may further have a substituent.

In Formula (I), each of n101 and n102 is preferably 0 to 2, and n101+n102 is more preferably 1 to 3. If R₁₀₁ is a hydrogen atom and both n101 and n102 are zero, the host compound represented by Formula (I) has a low molecular weight and a low Tg. Thus, if R₁₀₁ is a hydrogen atom, n101 is 1 to 4.

The host compound used in the present invention is preferably a carbazole derivative having a structure represented by Formula (II), because such a compound exhibits particularly high carrier transportability.

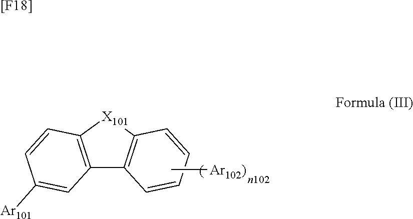

In Formula (II), X₁₀₁, Ar₁₀₁, Ar₁₀₂, and n102 are the same as those defined above in Formula (I).

In Formula (II), n102 is preferably 0 to 2, more preferably 0 or 1.

In Formula (II), the condensed ring including X₁₀₁ may have any substituent that does not impede the function of the host compound of the present invention, in addition to Ar₁₀₁ and Ar₁₀₂.

The compound represented by Formula (II) is preferably represented by Formula (III-1), (III-2), or (III-3).

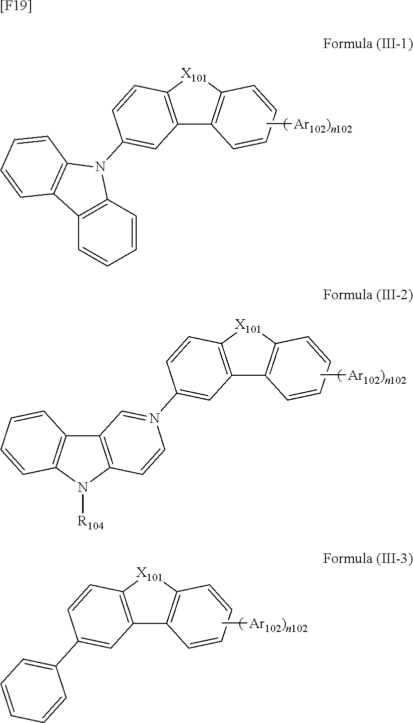

In Formulae (III-1) to (III-3), X₁₀₁, Ar₁₀₂, and n102 are the same as those defined above in Formula (II).

In Formulae (III-1) to (III-3), the condensed ring including X₁₀₁, the carbazole ring, or the benzene ring may further have any substituent that does not impede the function of the host compound of the present invention.

Specific examples of the host compounds used in the present invention represented by Formulae (I), (II), and (III-1) to (III-3) and having other structures include, but are not limited to, the following compounds.

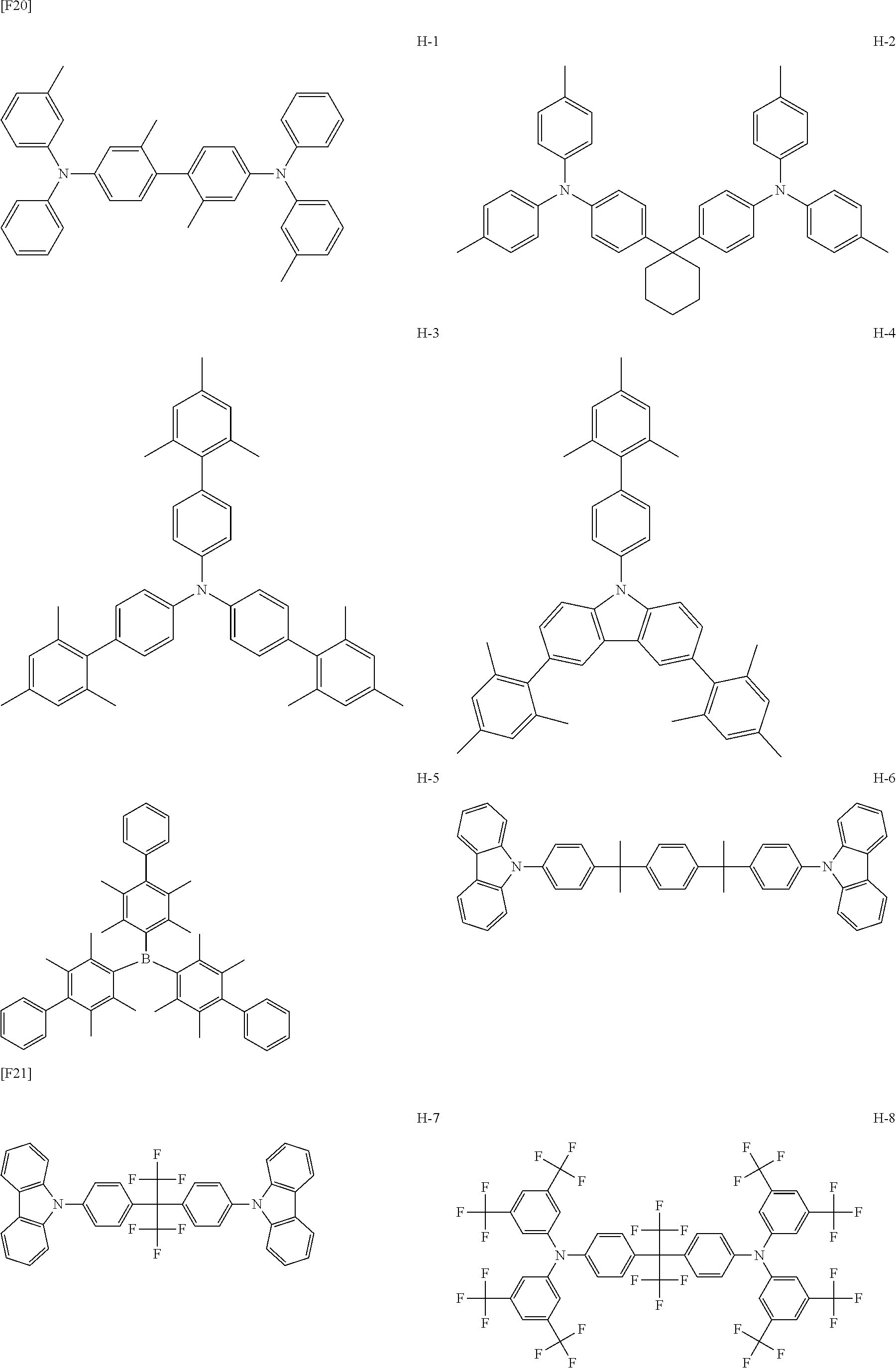

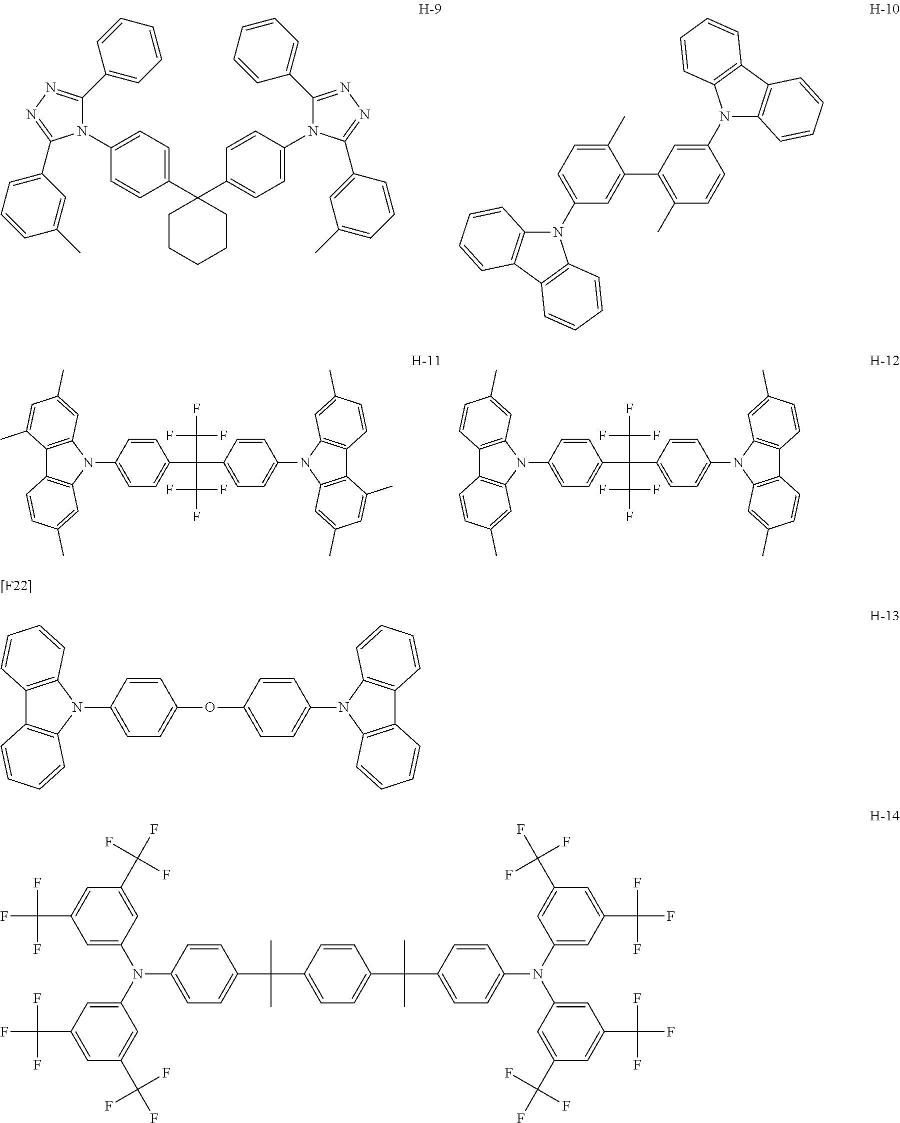

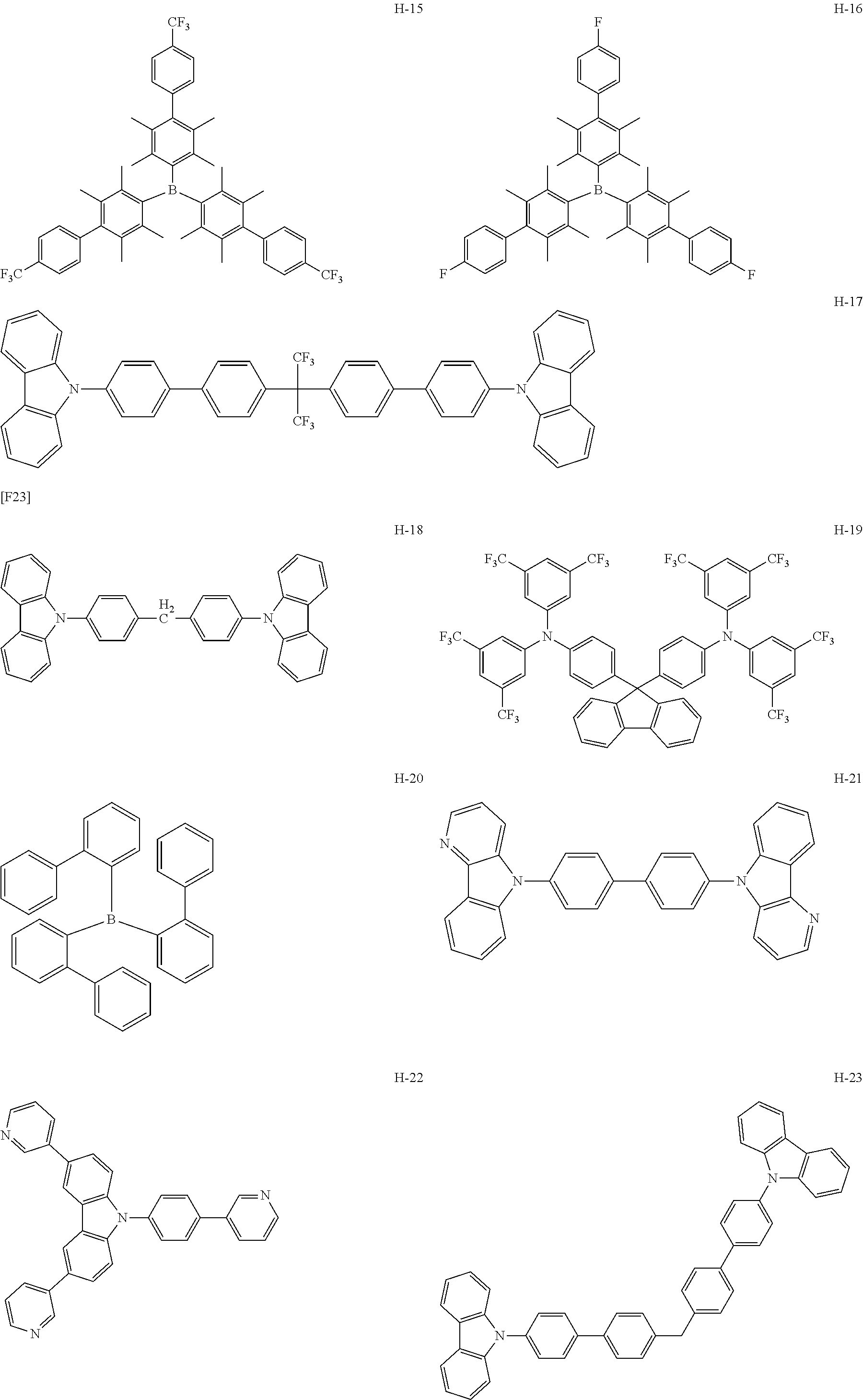

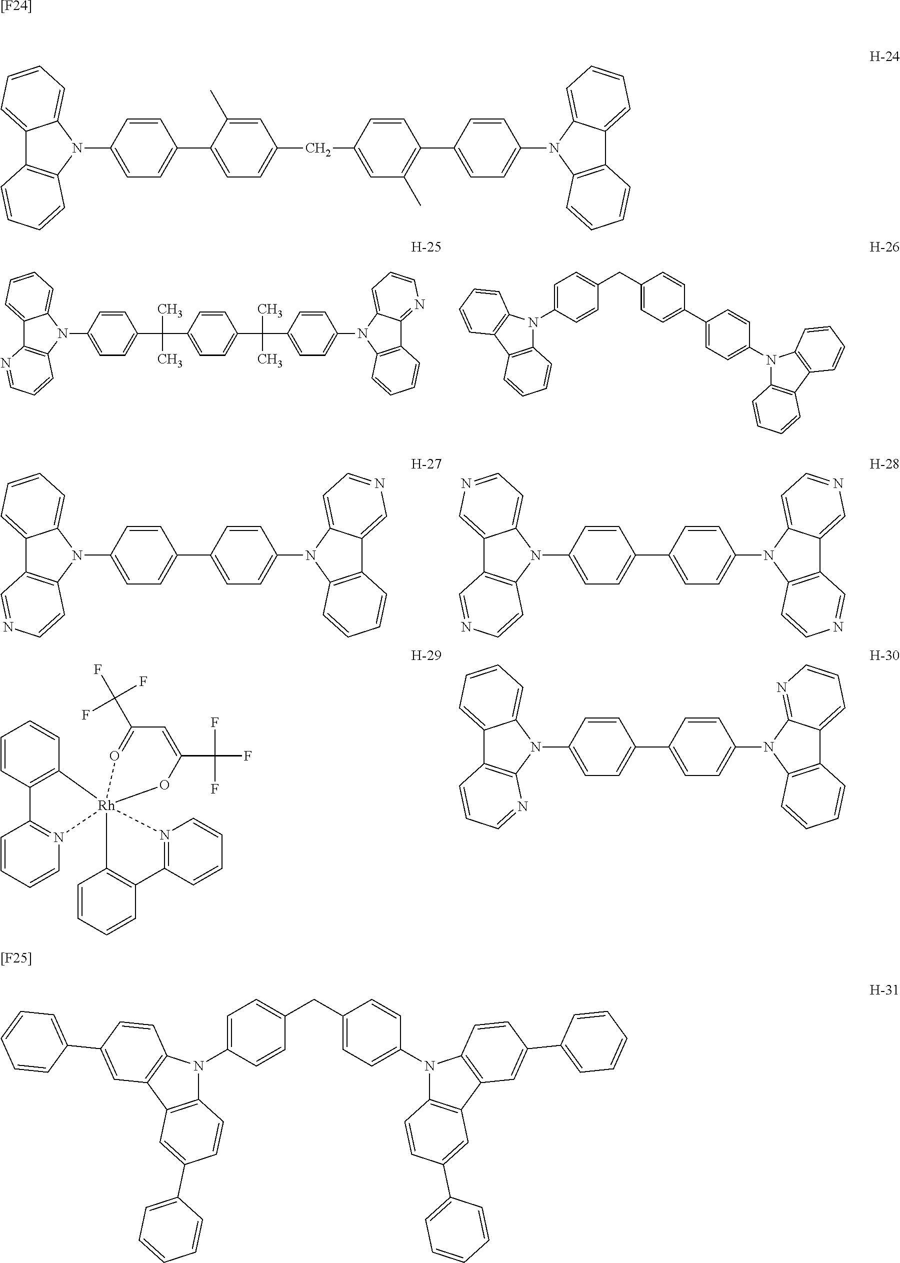

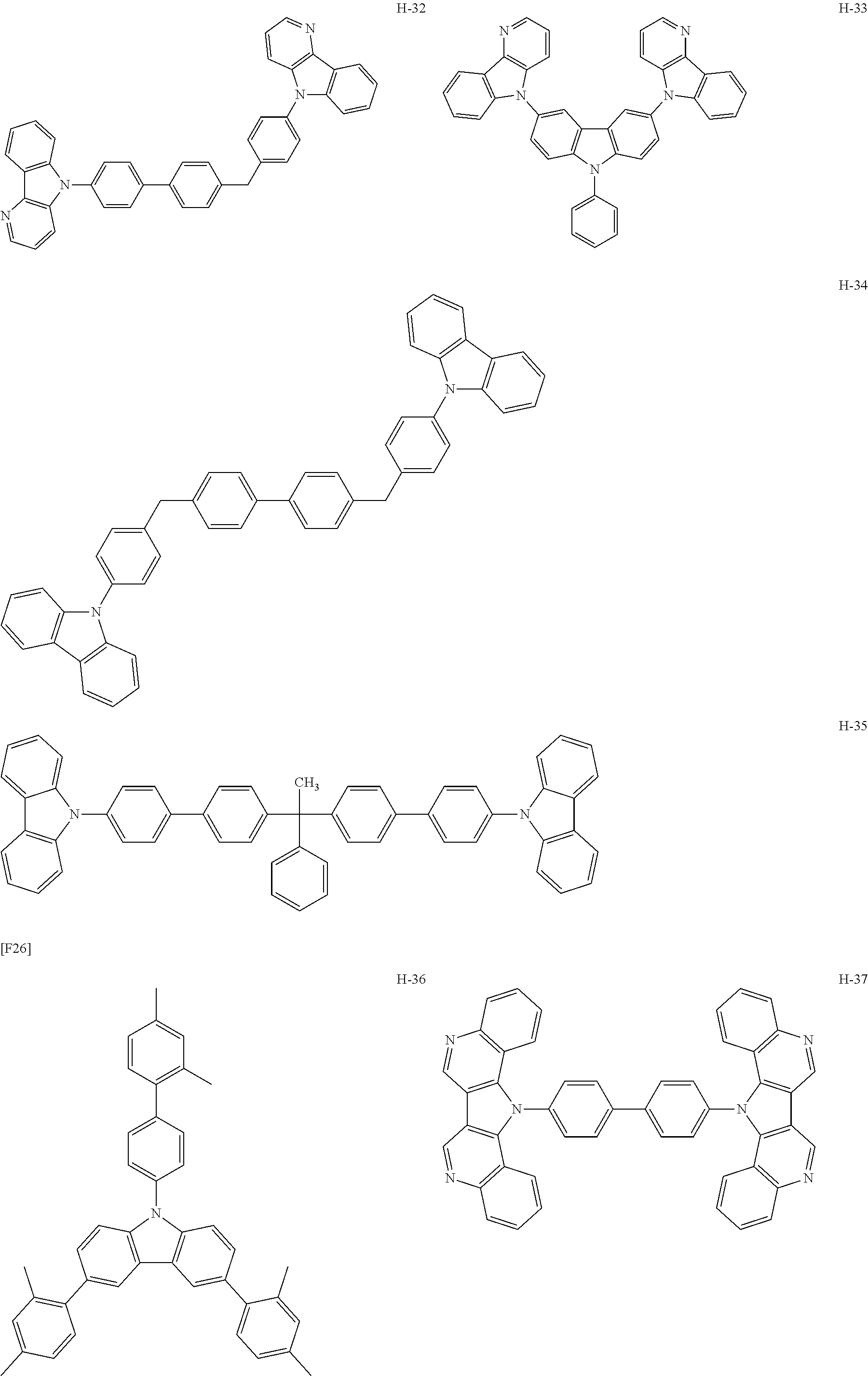

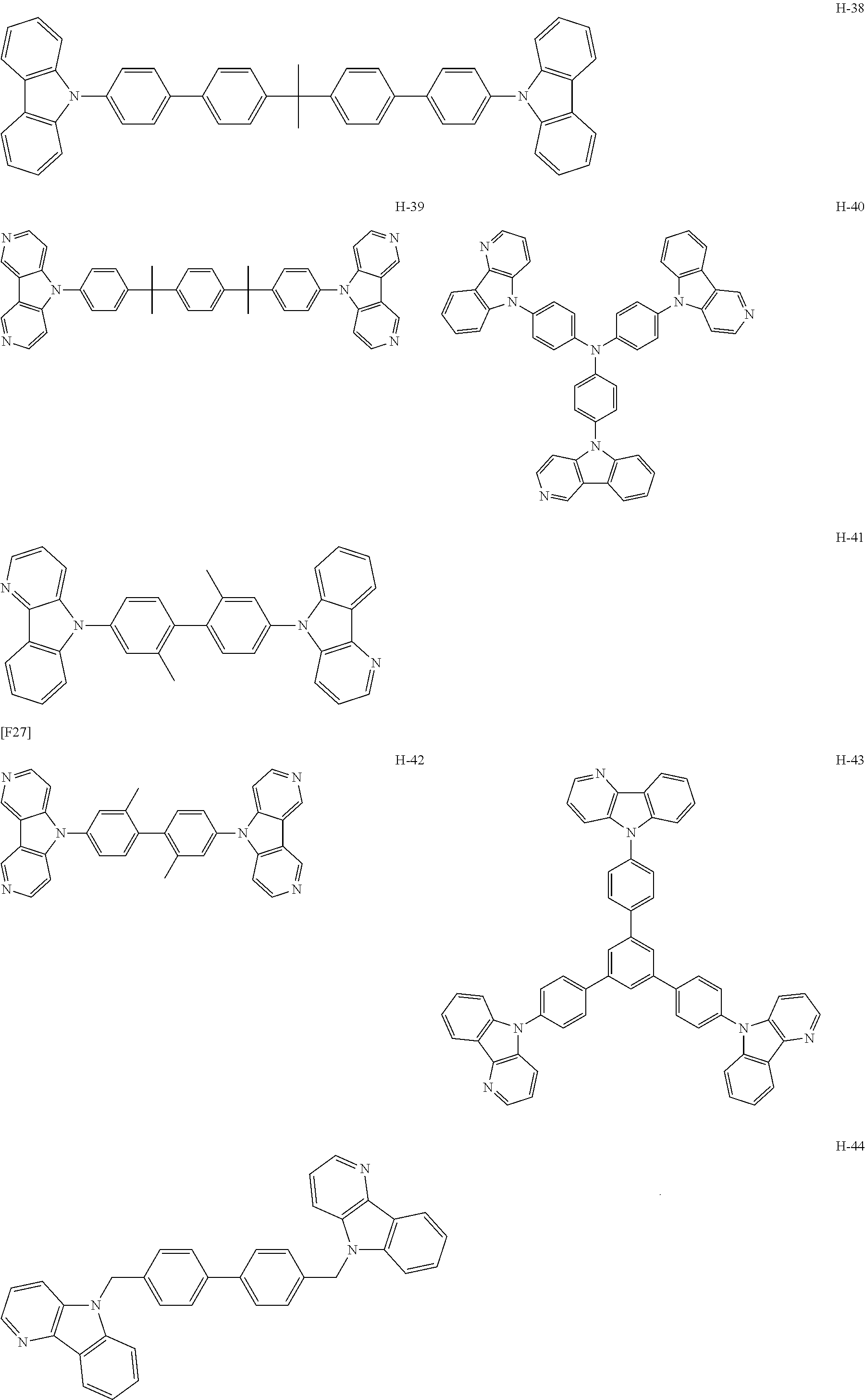

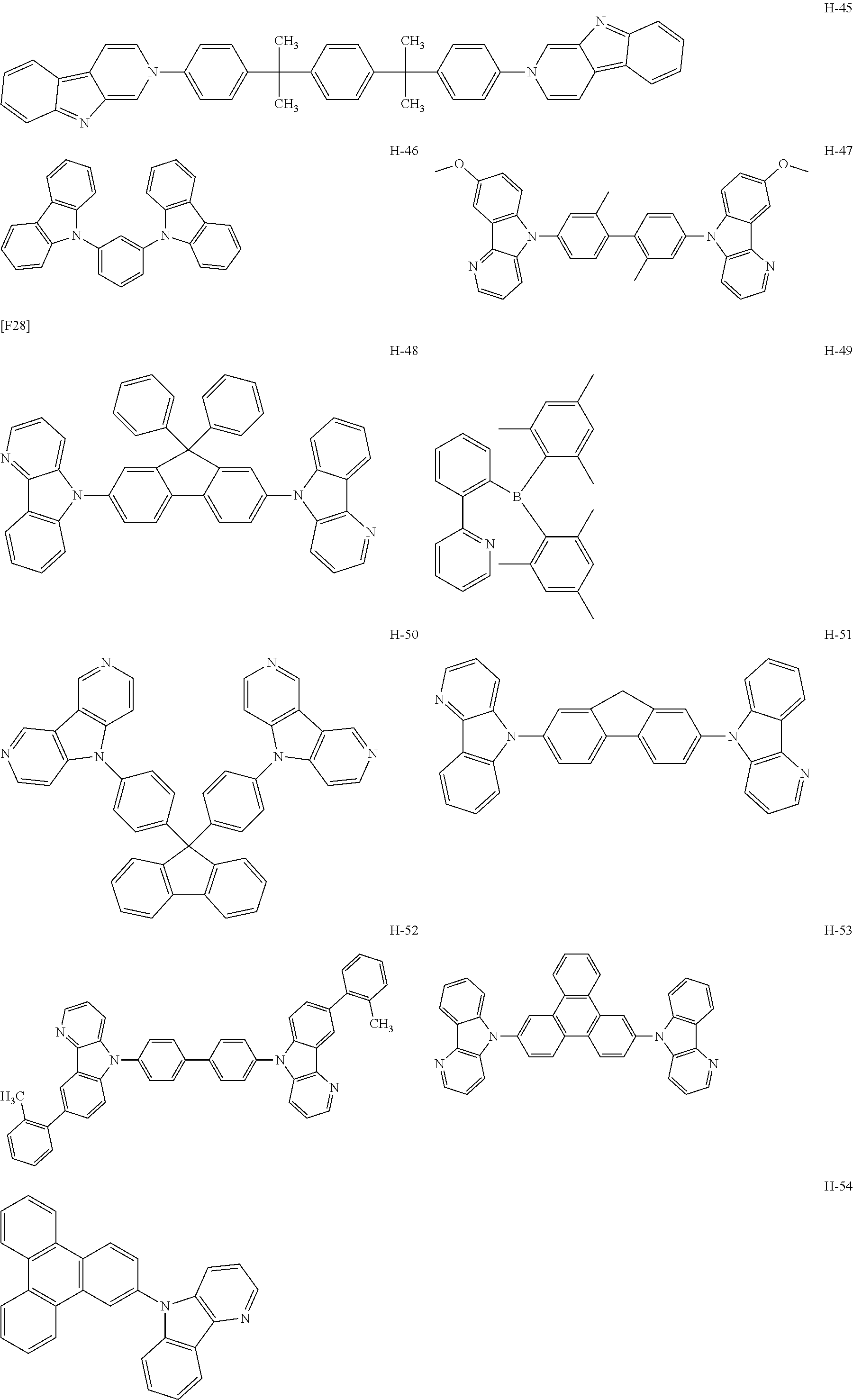

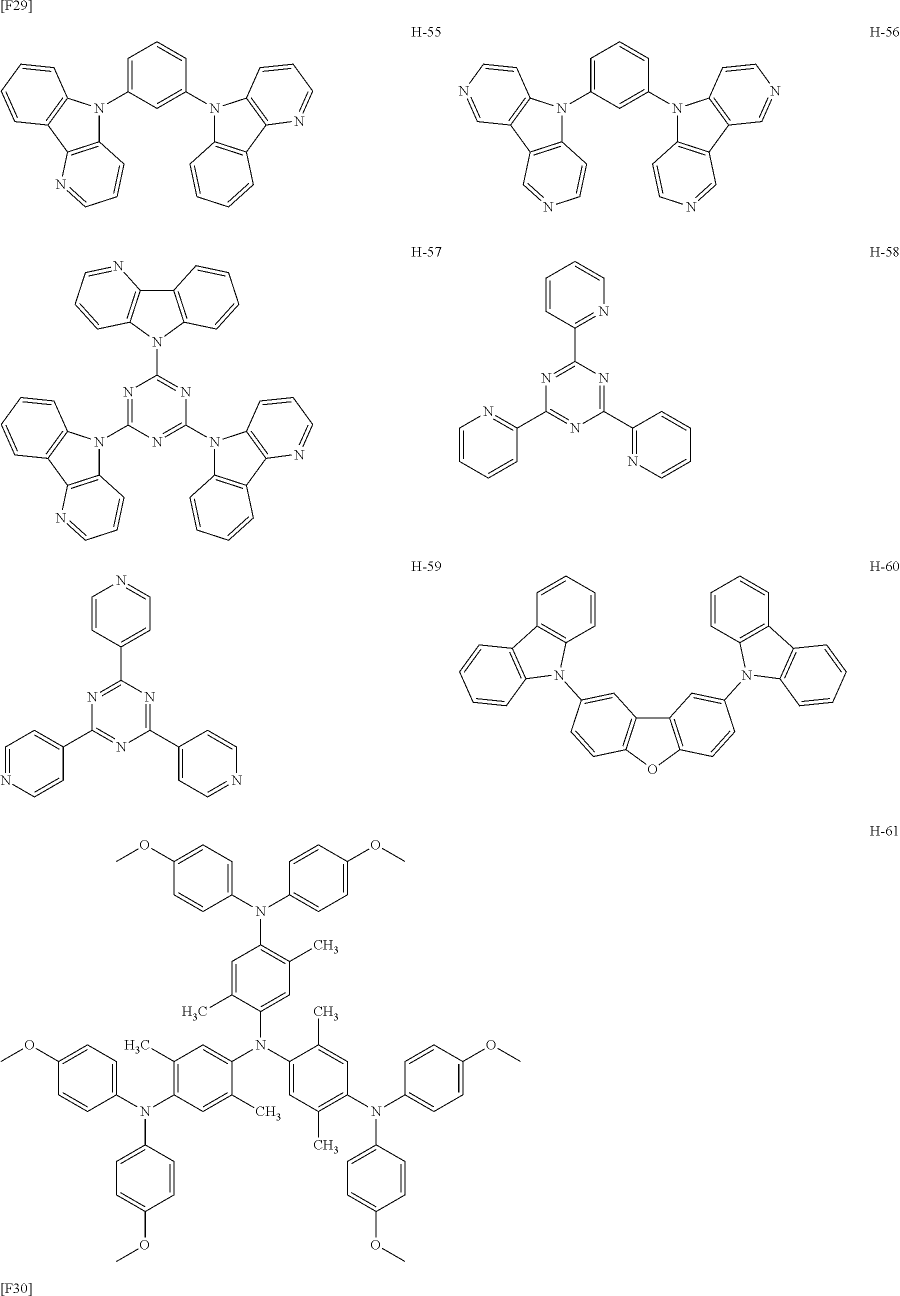

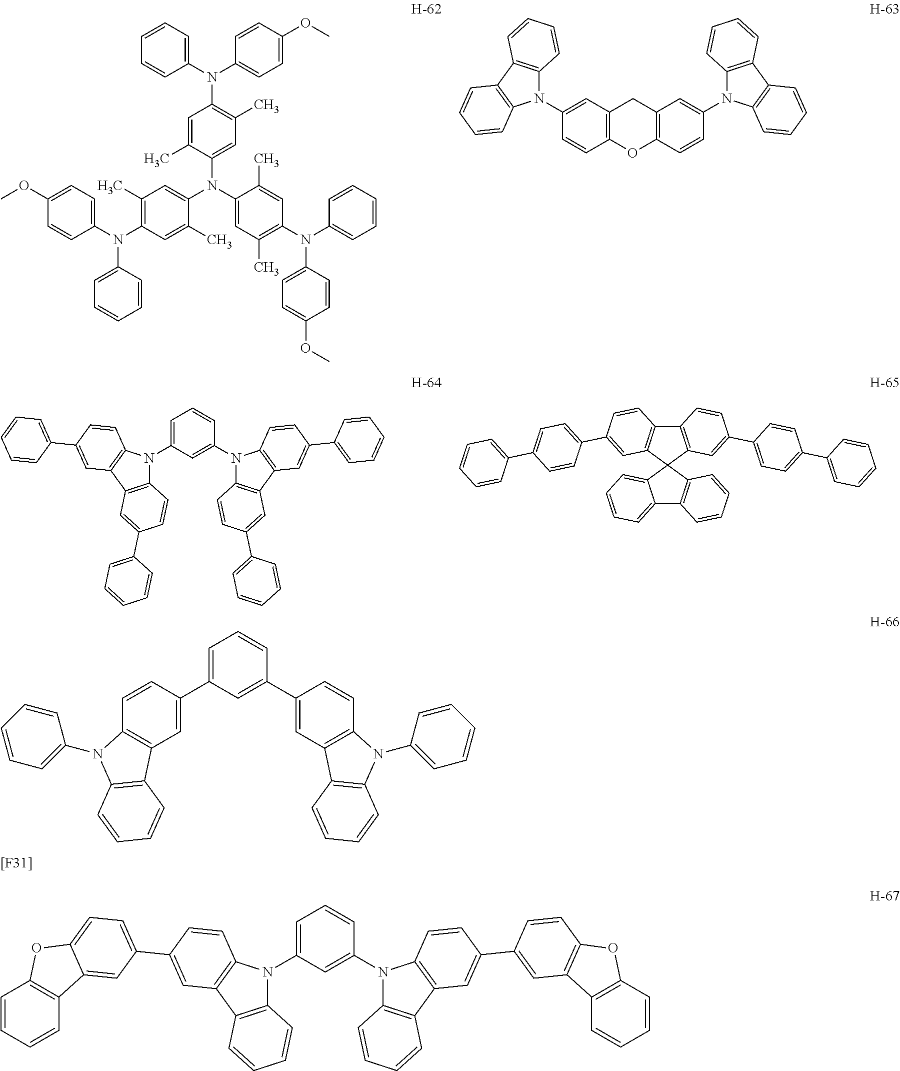

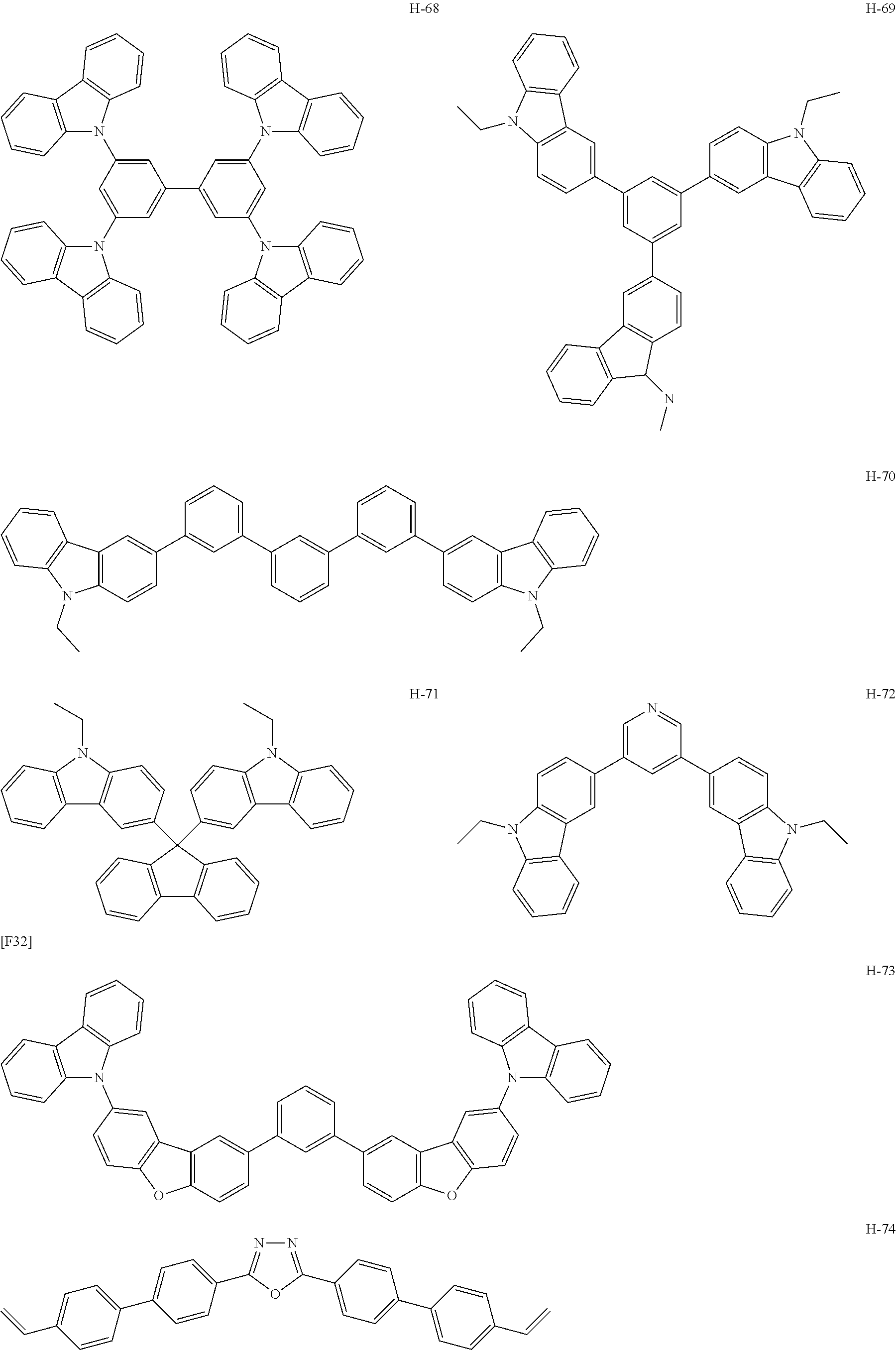

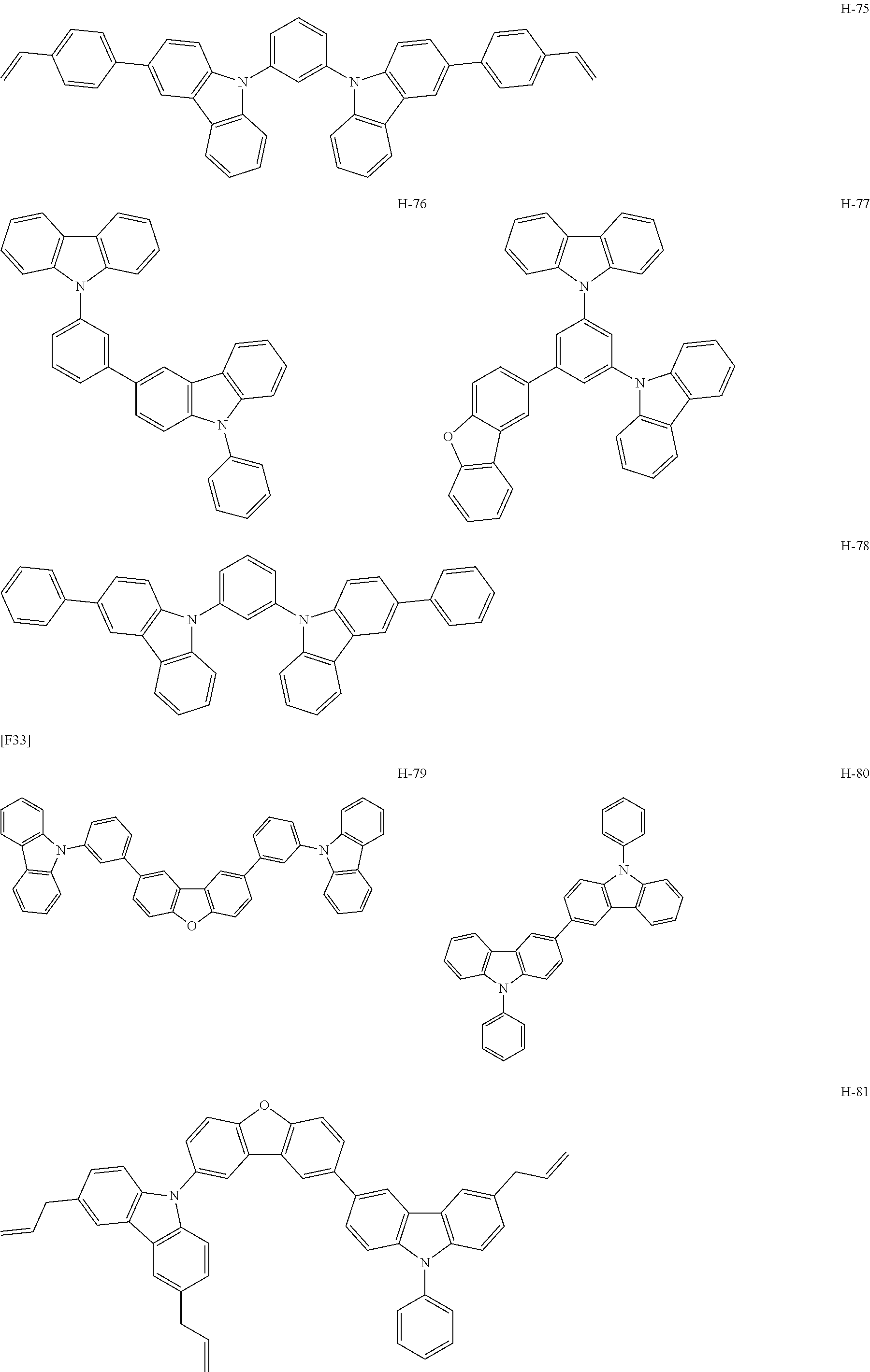

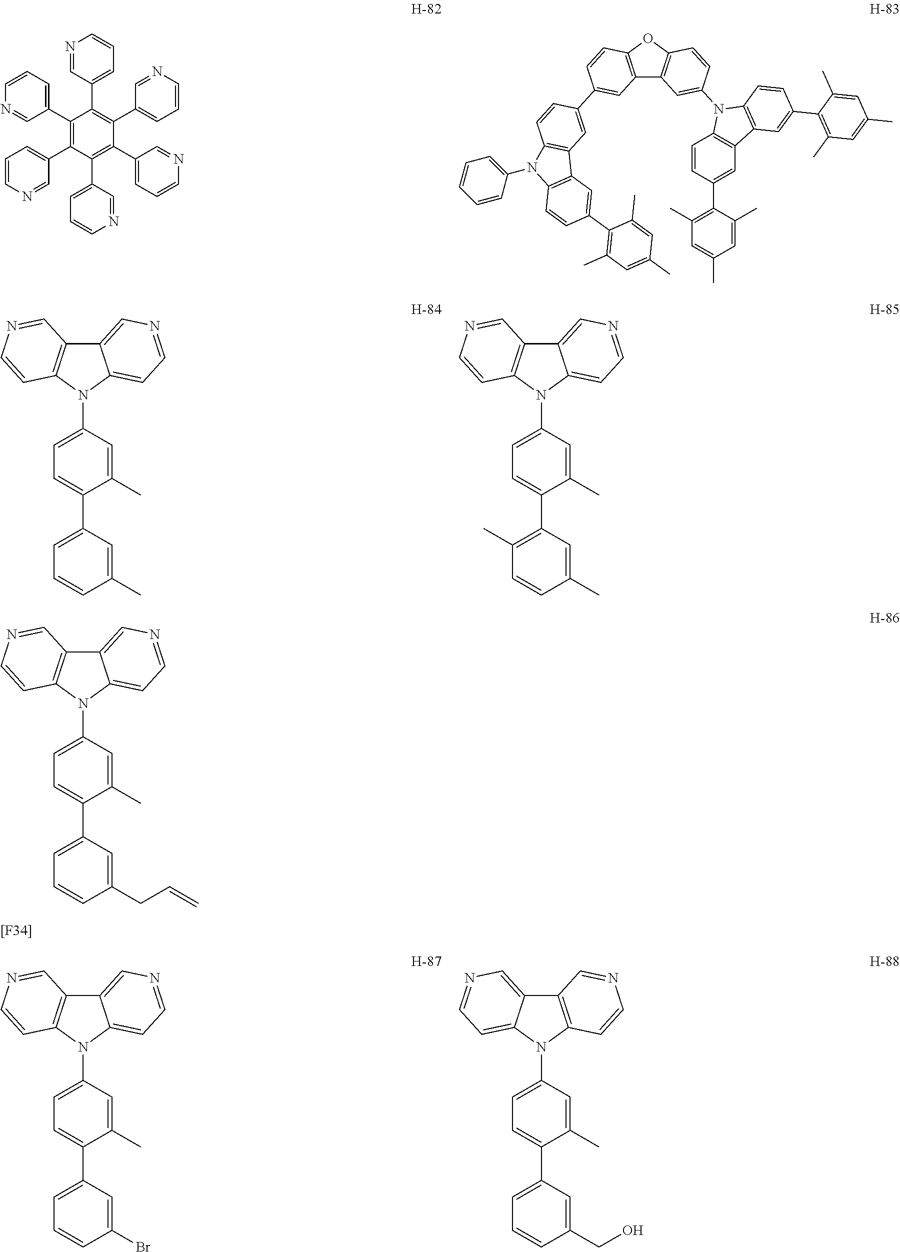

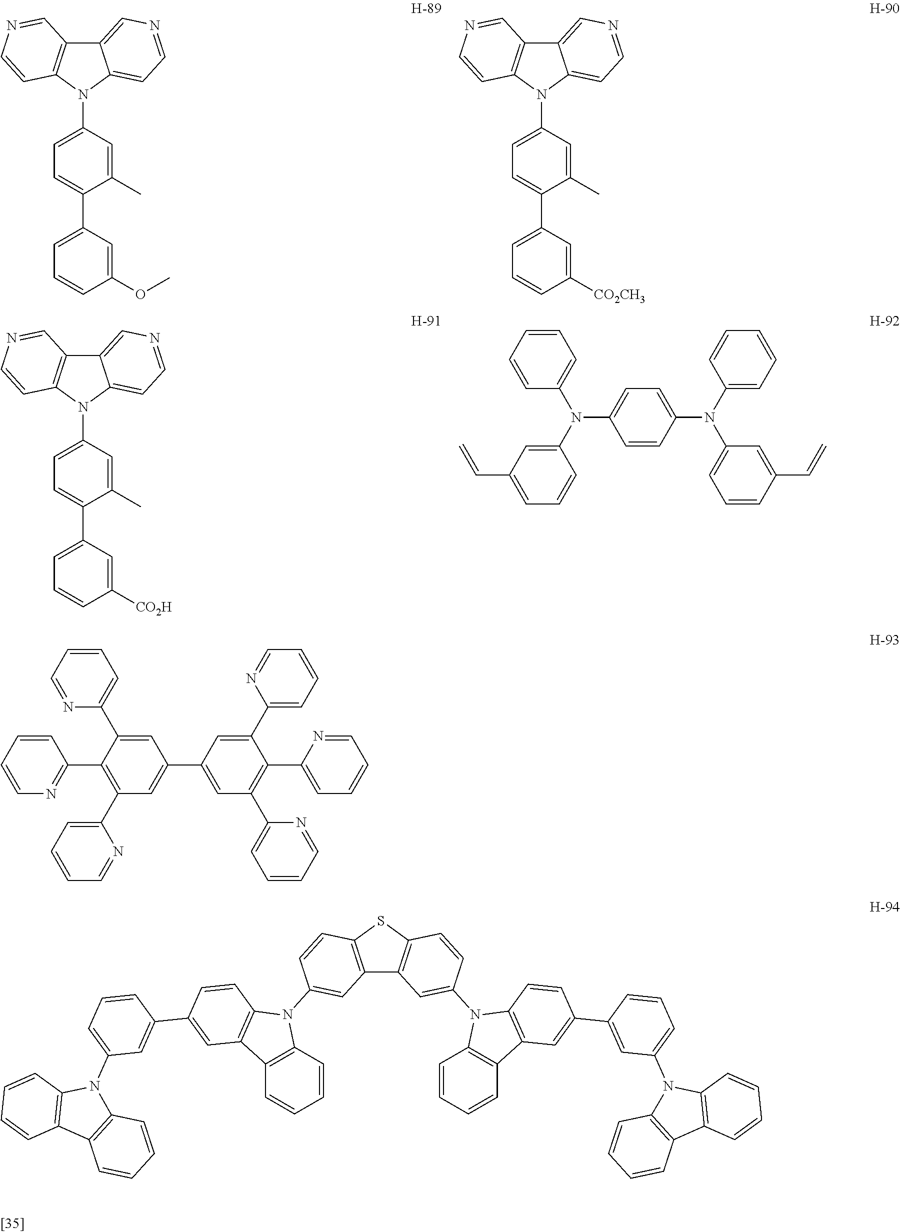

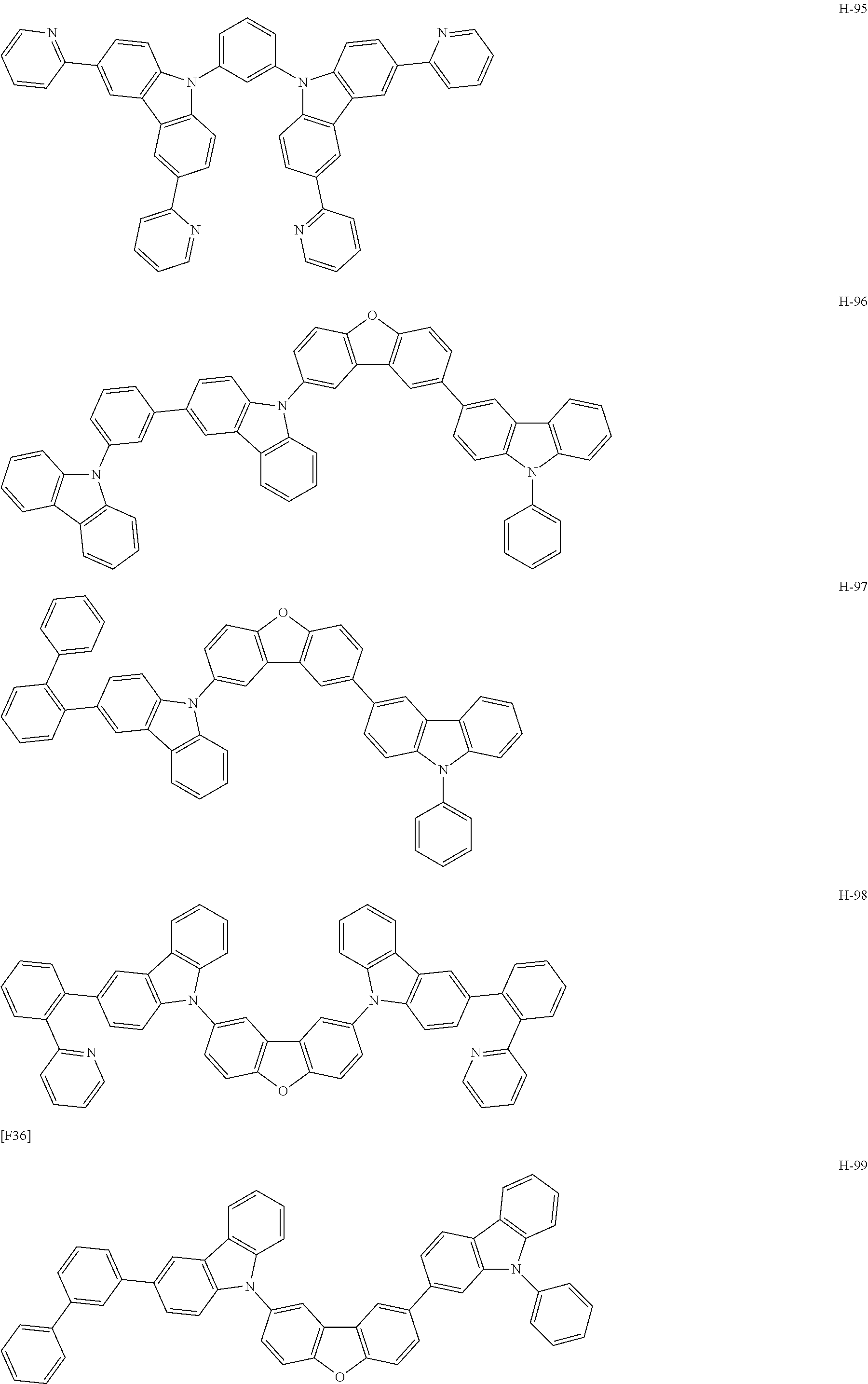

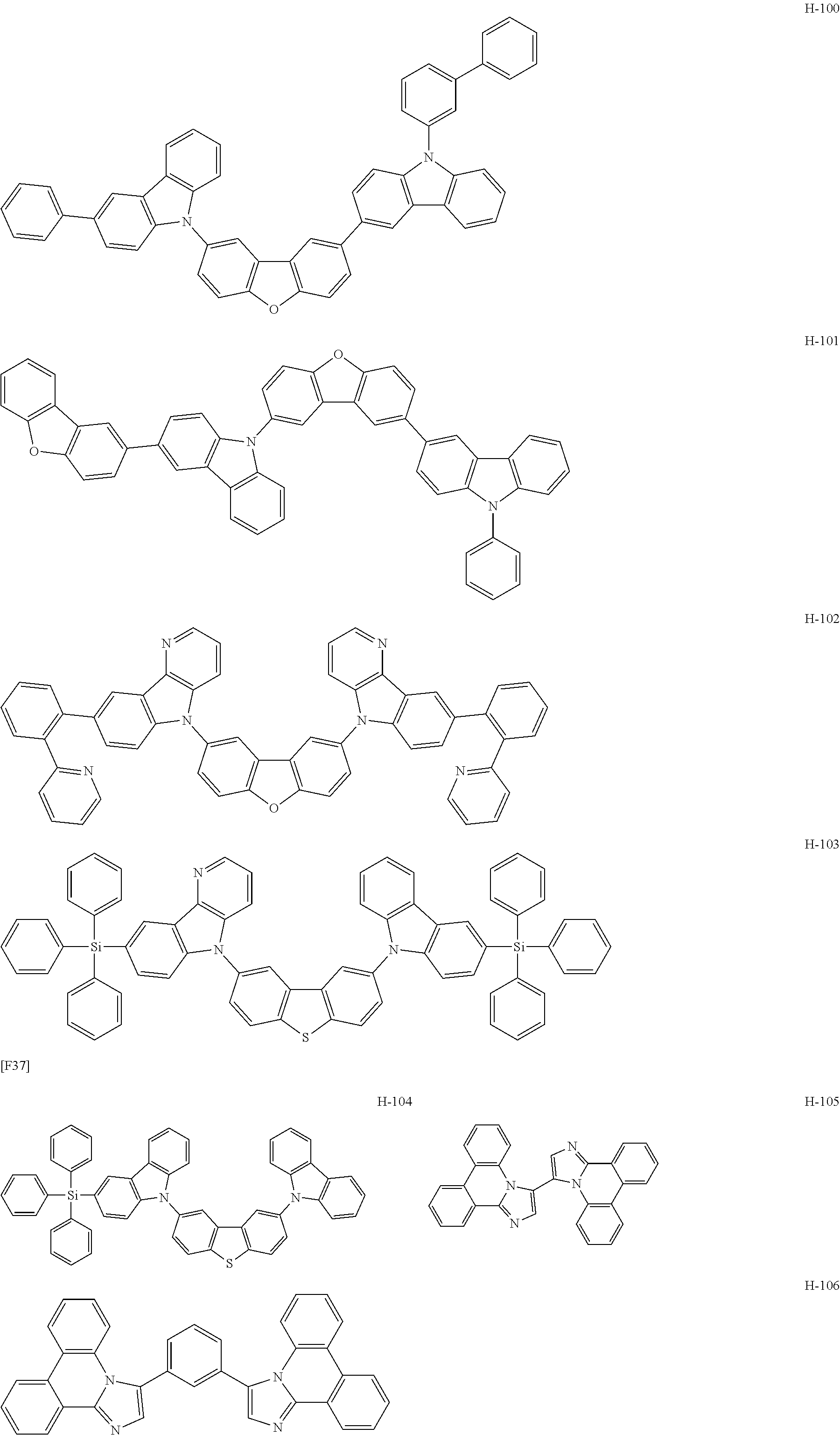

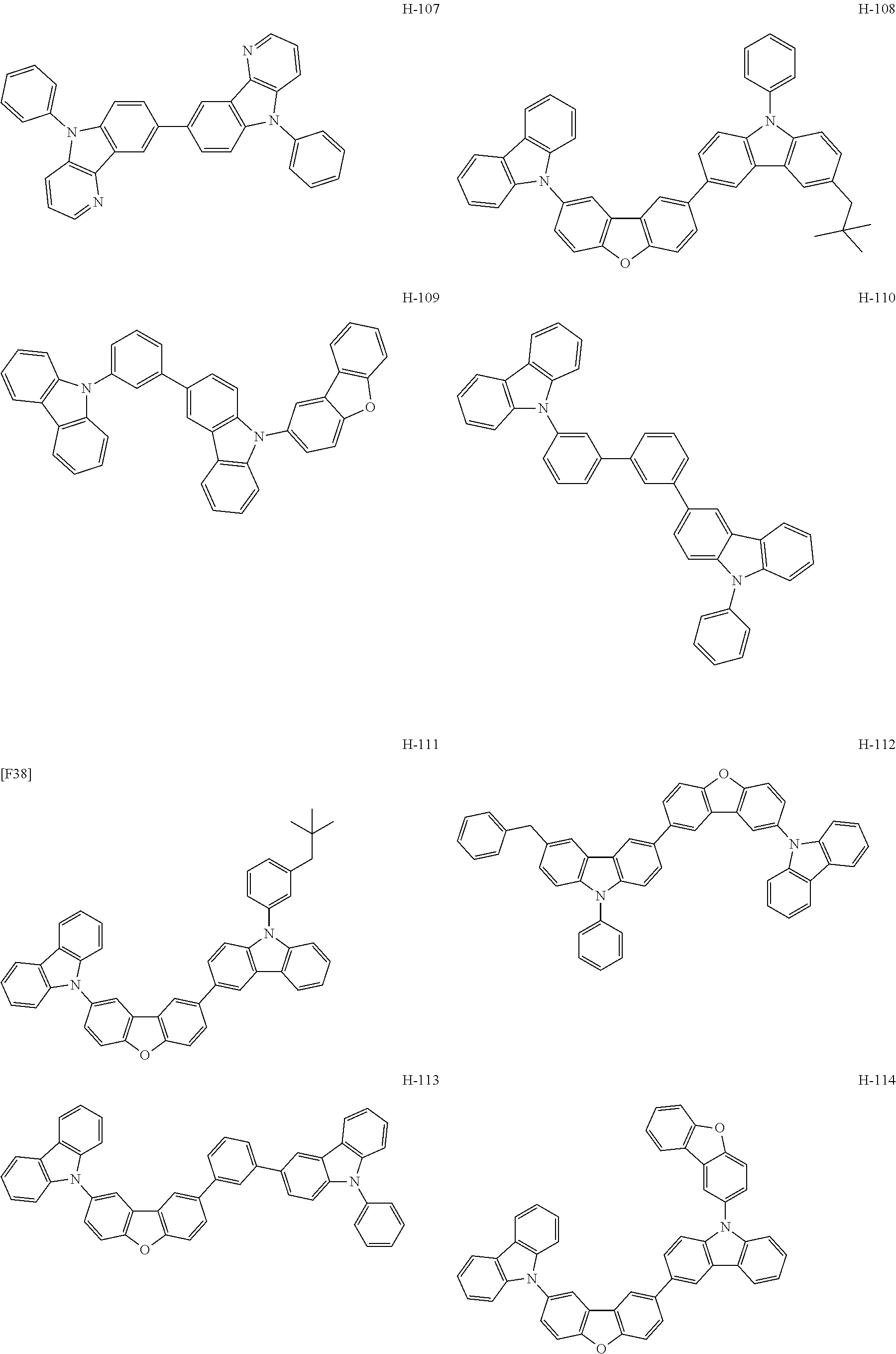

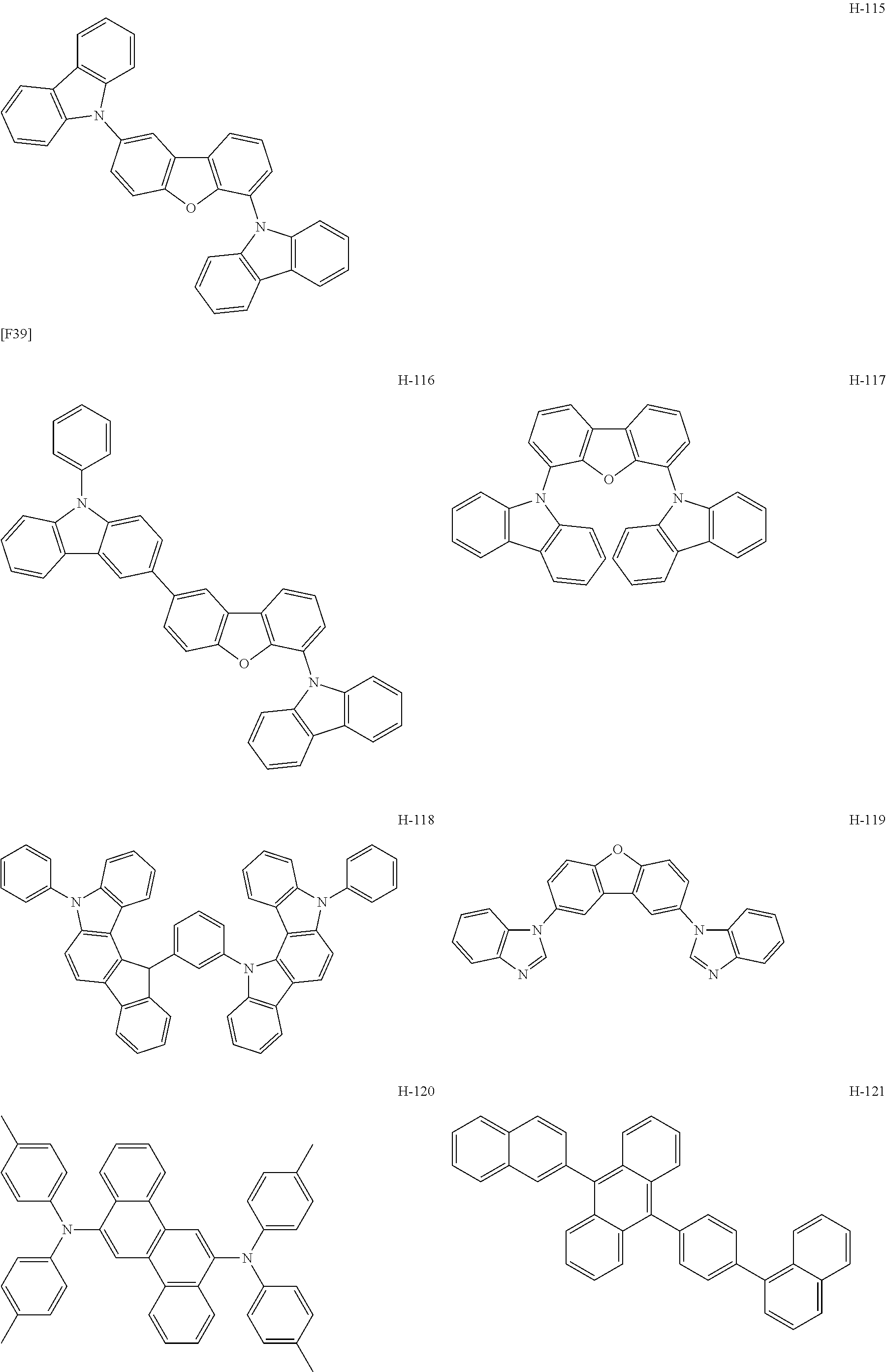

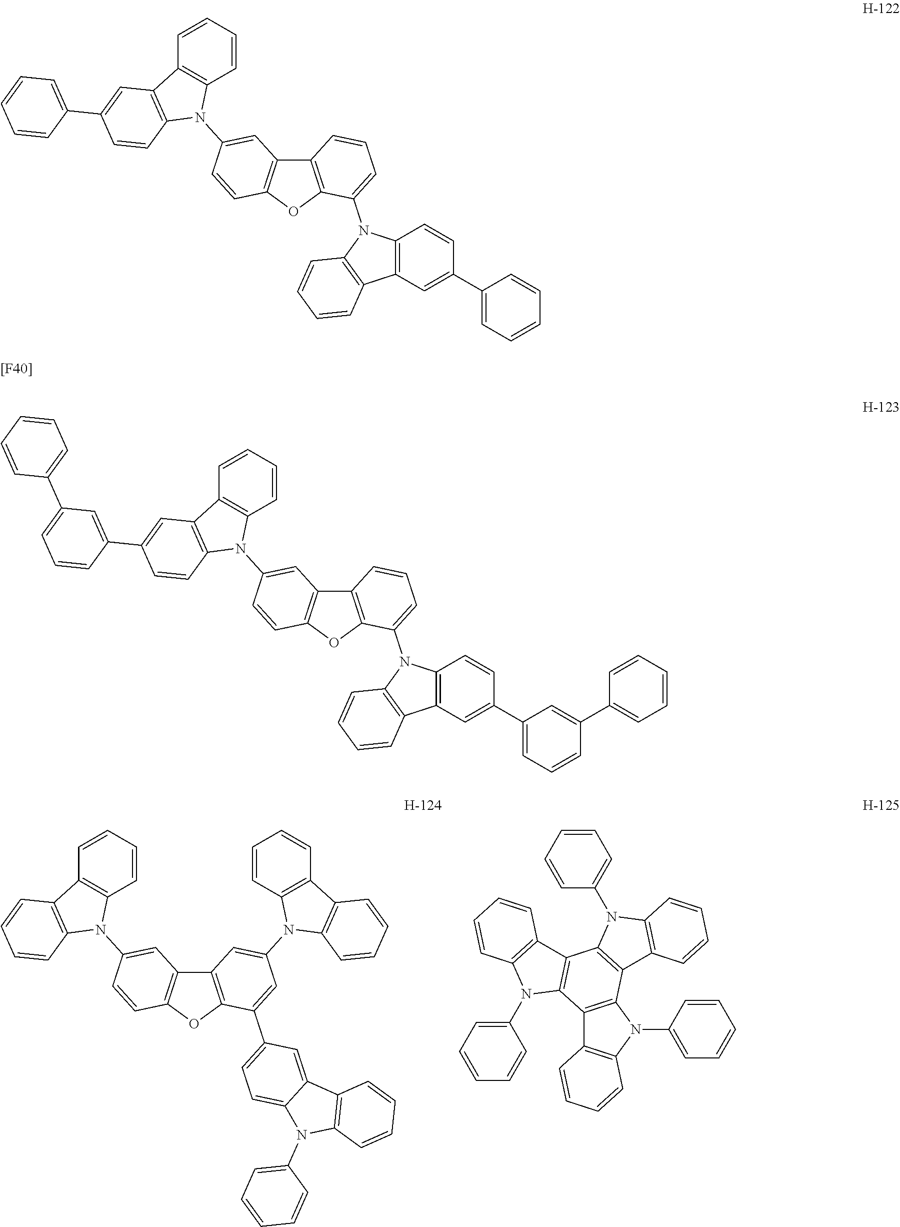

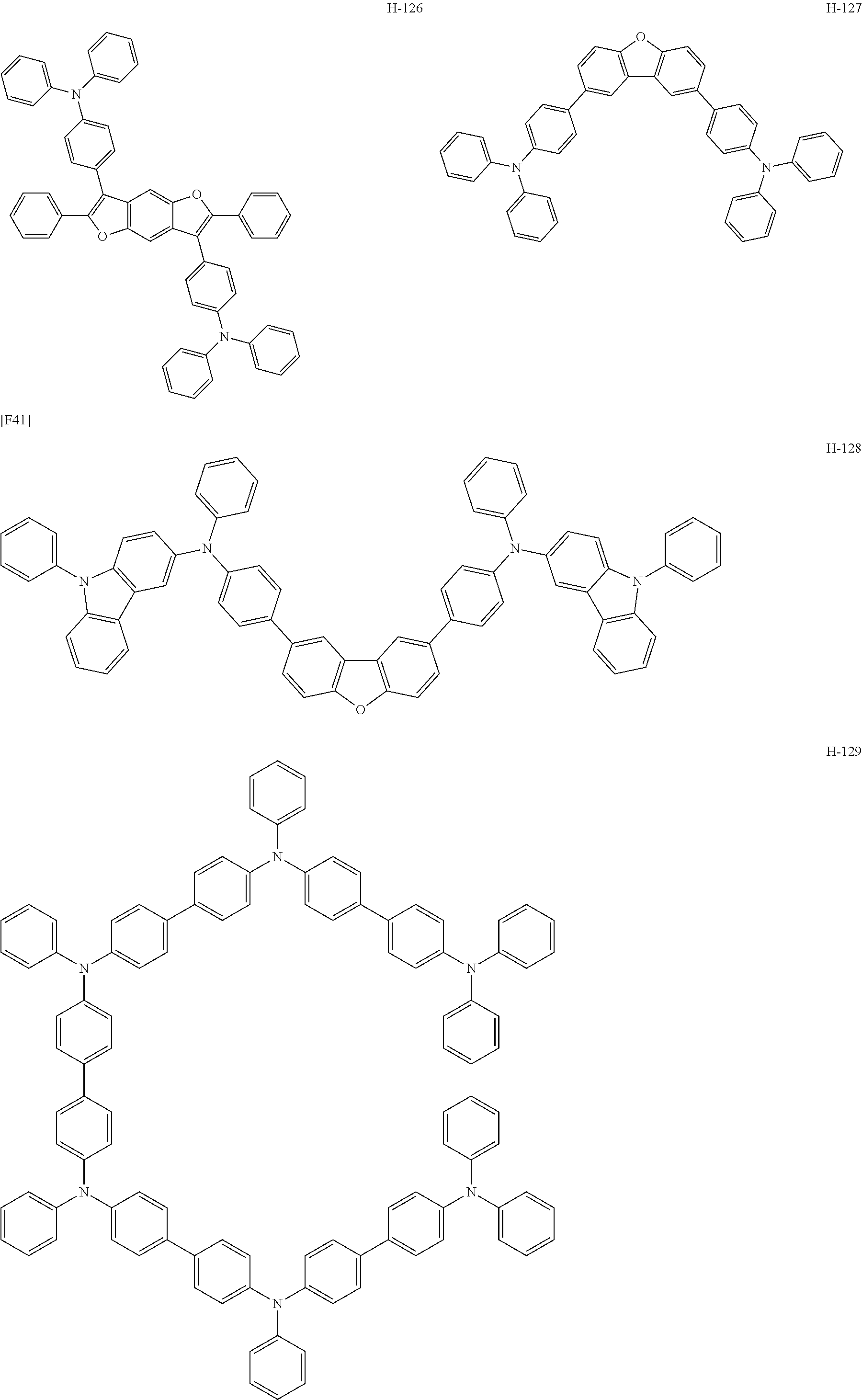

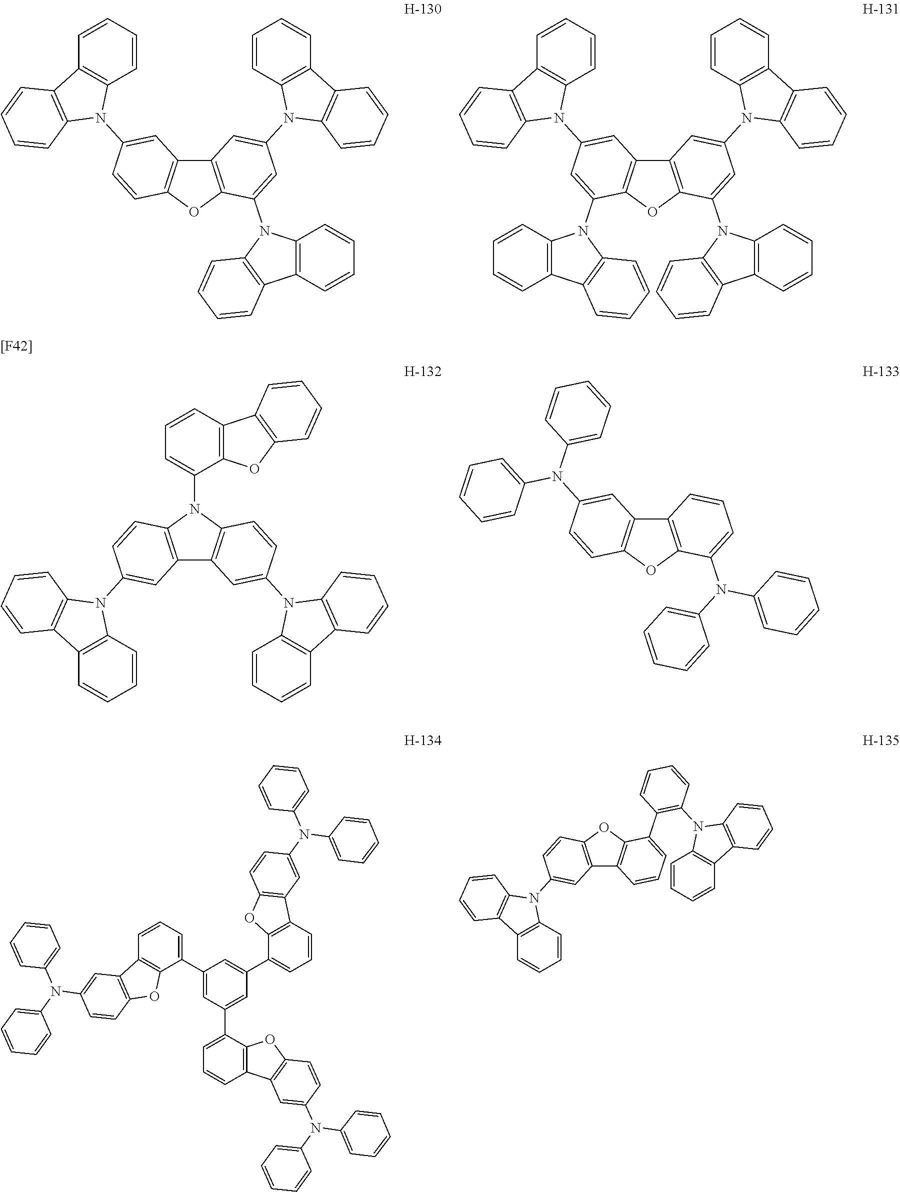

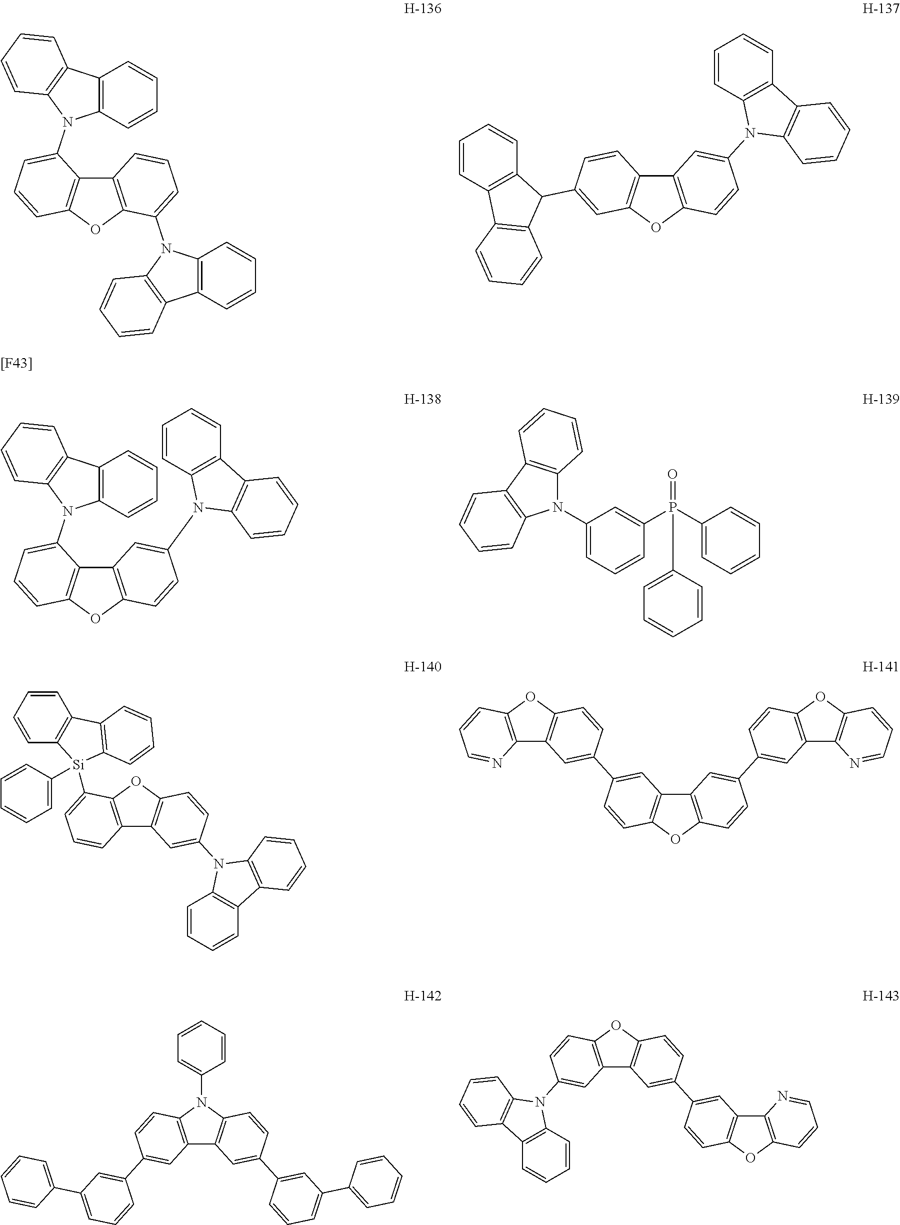

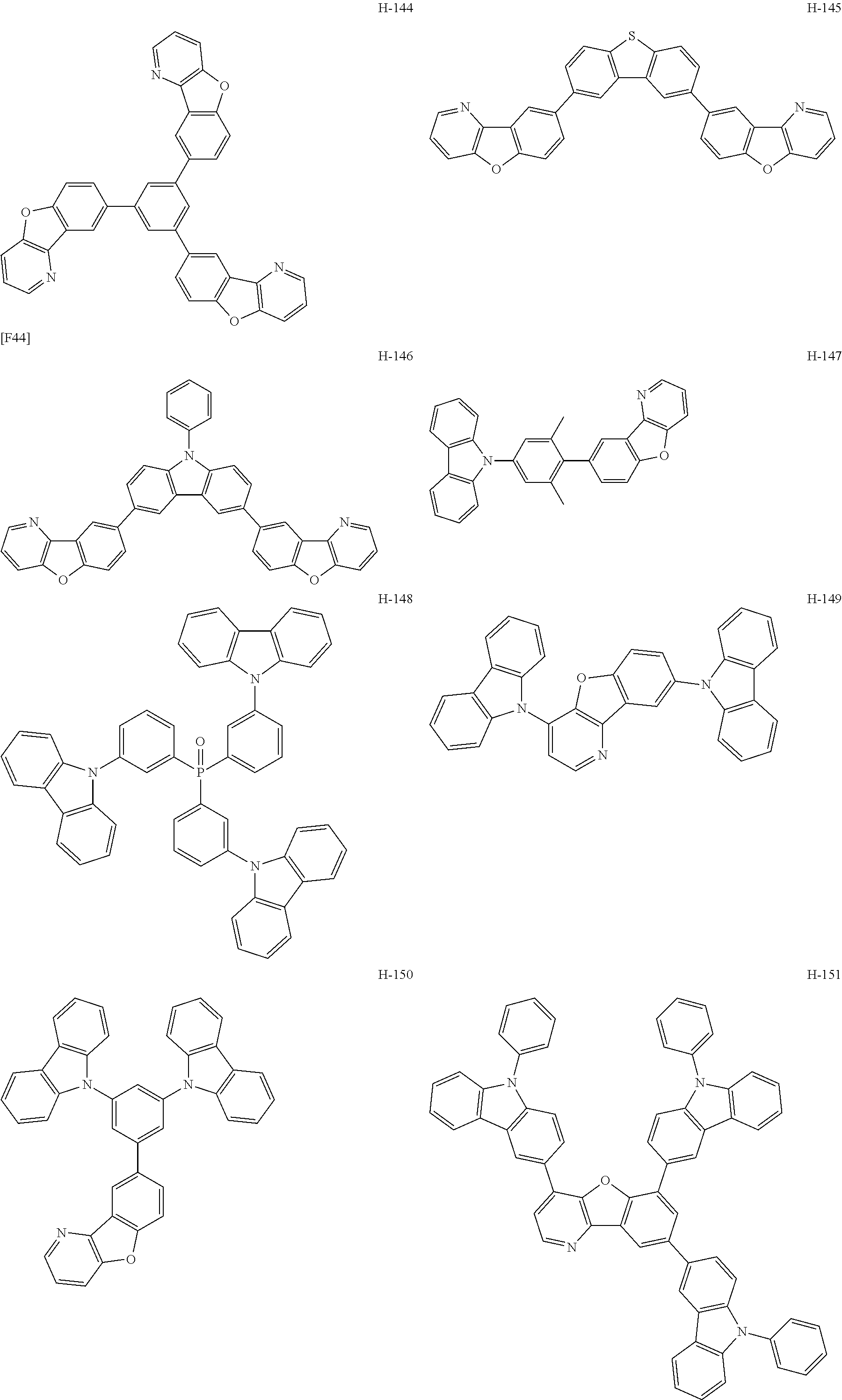

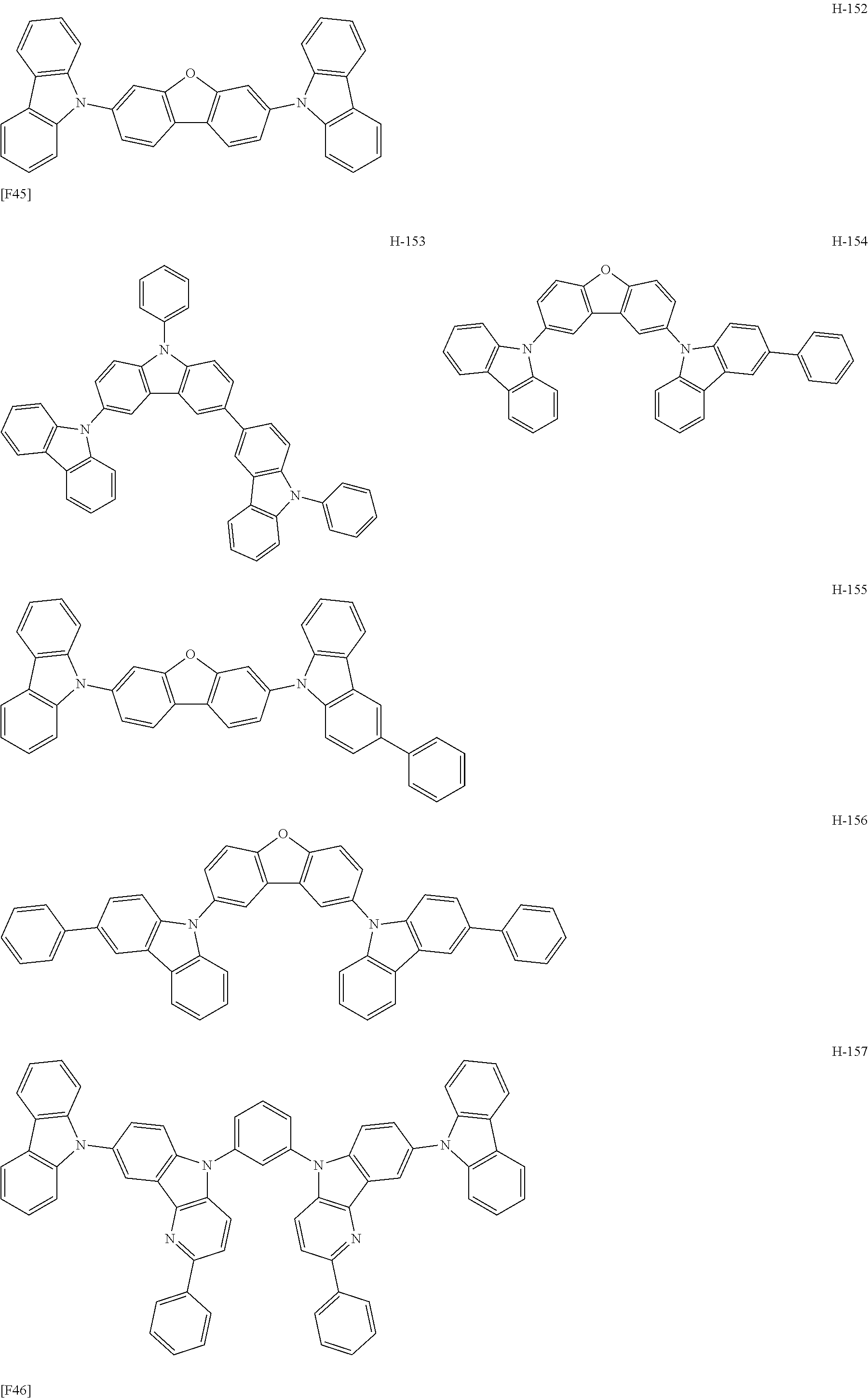

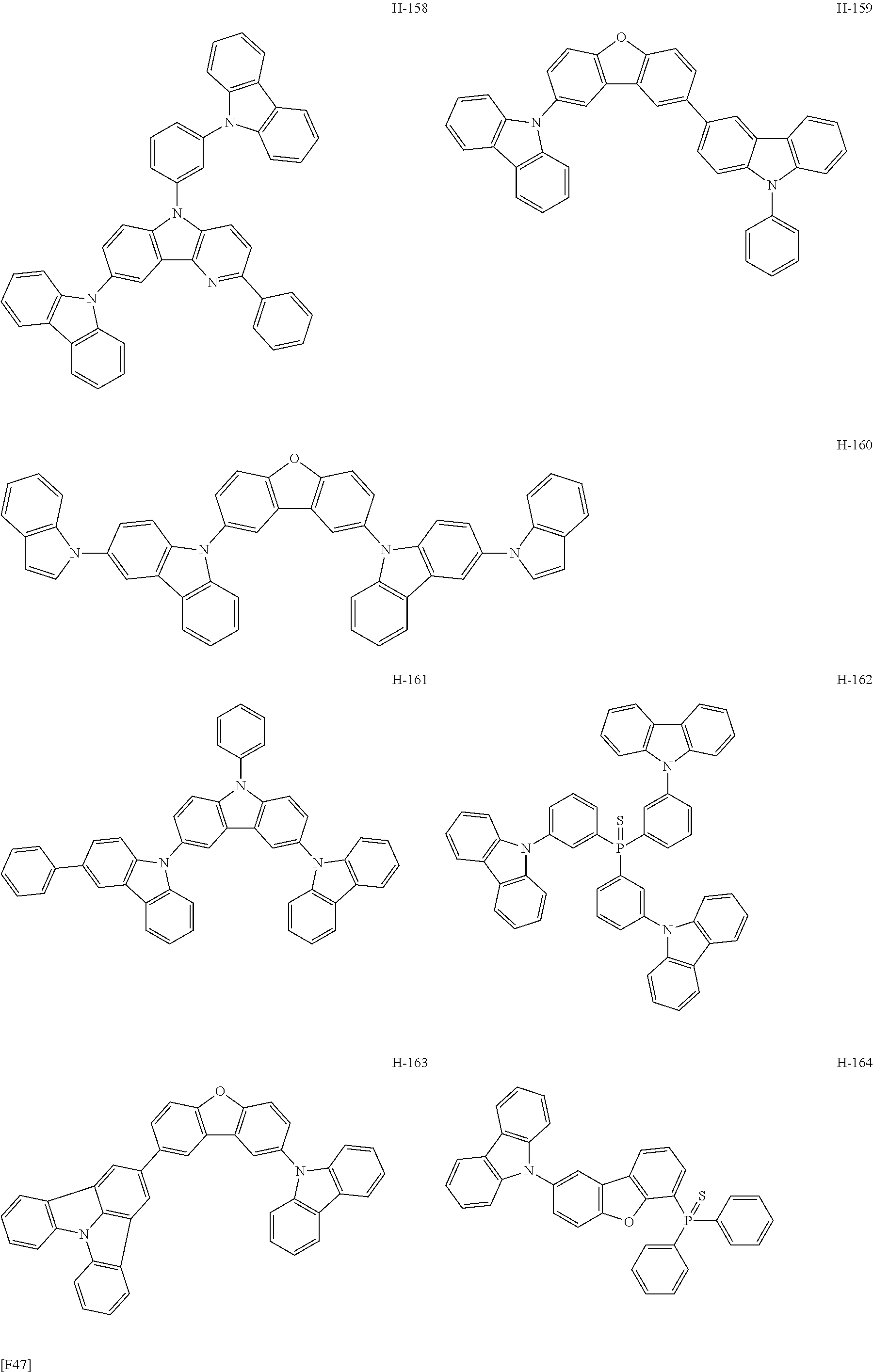

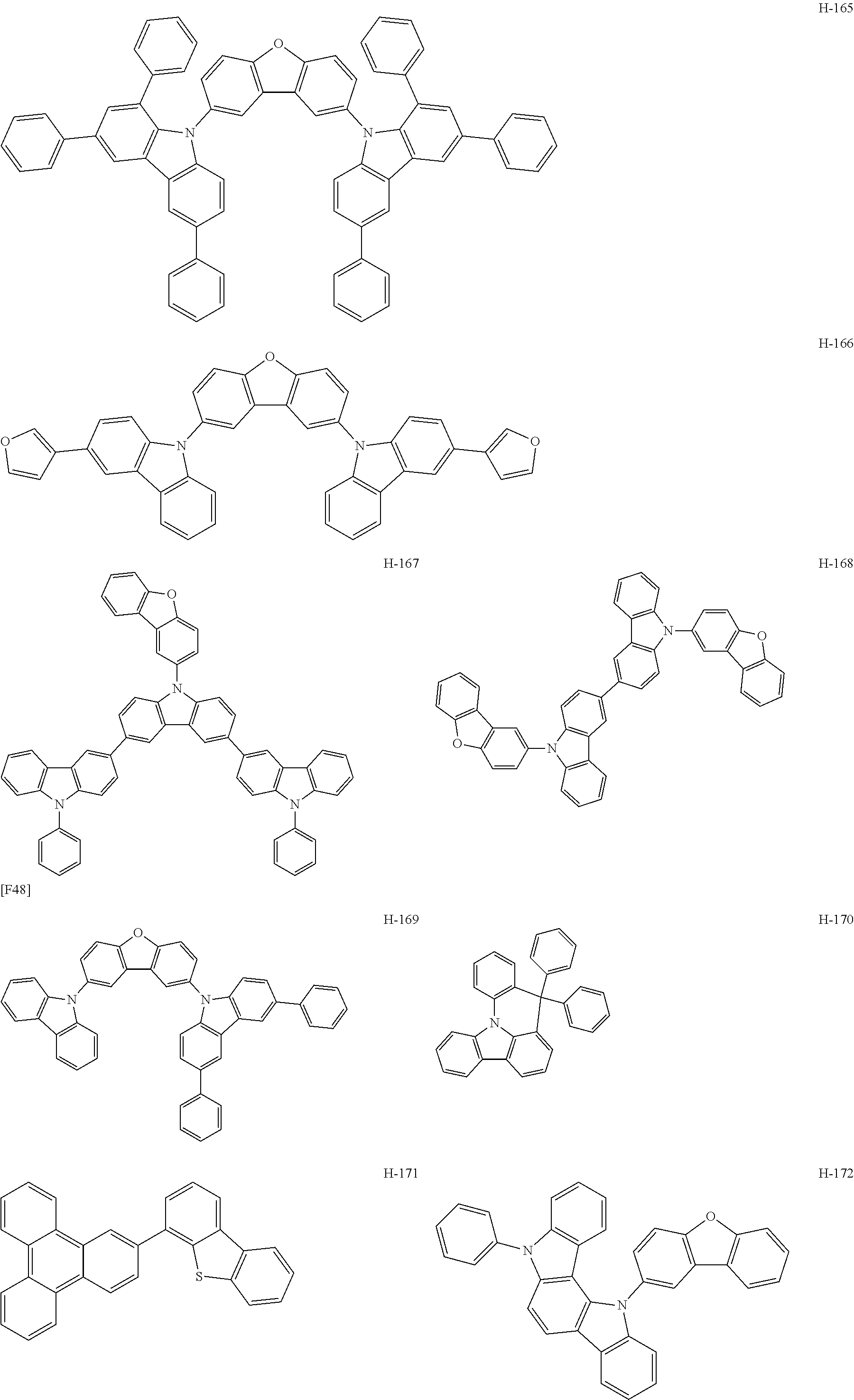

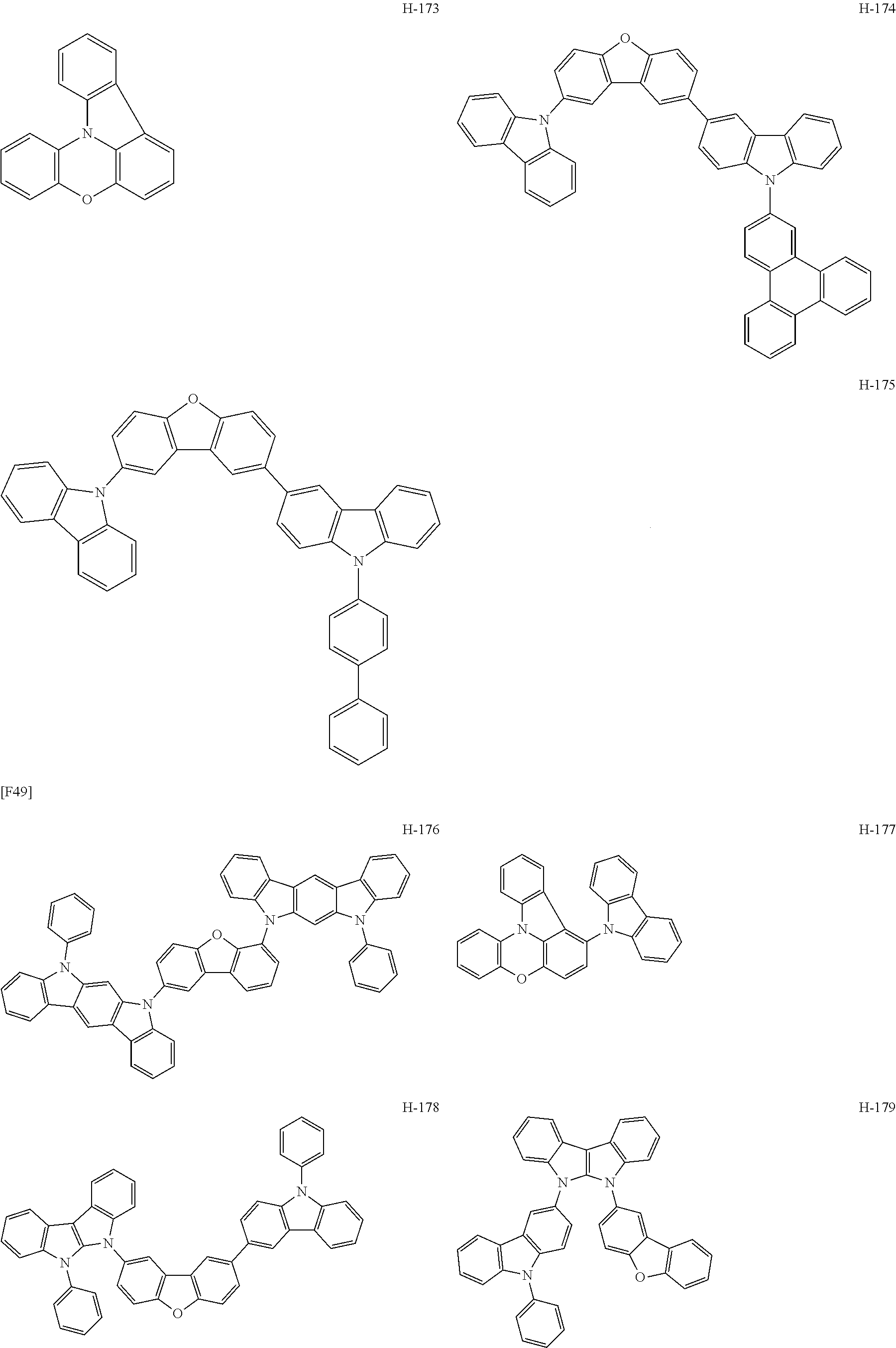

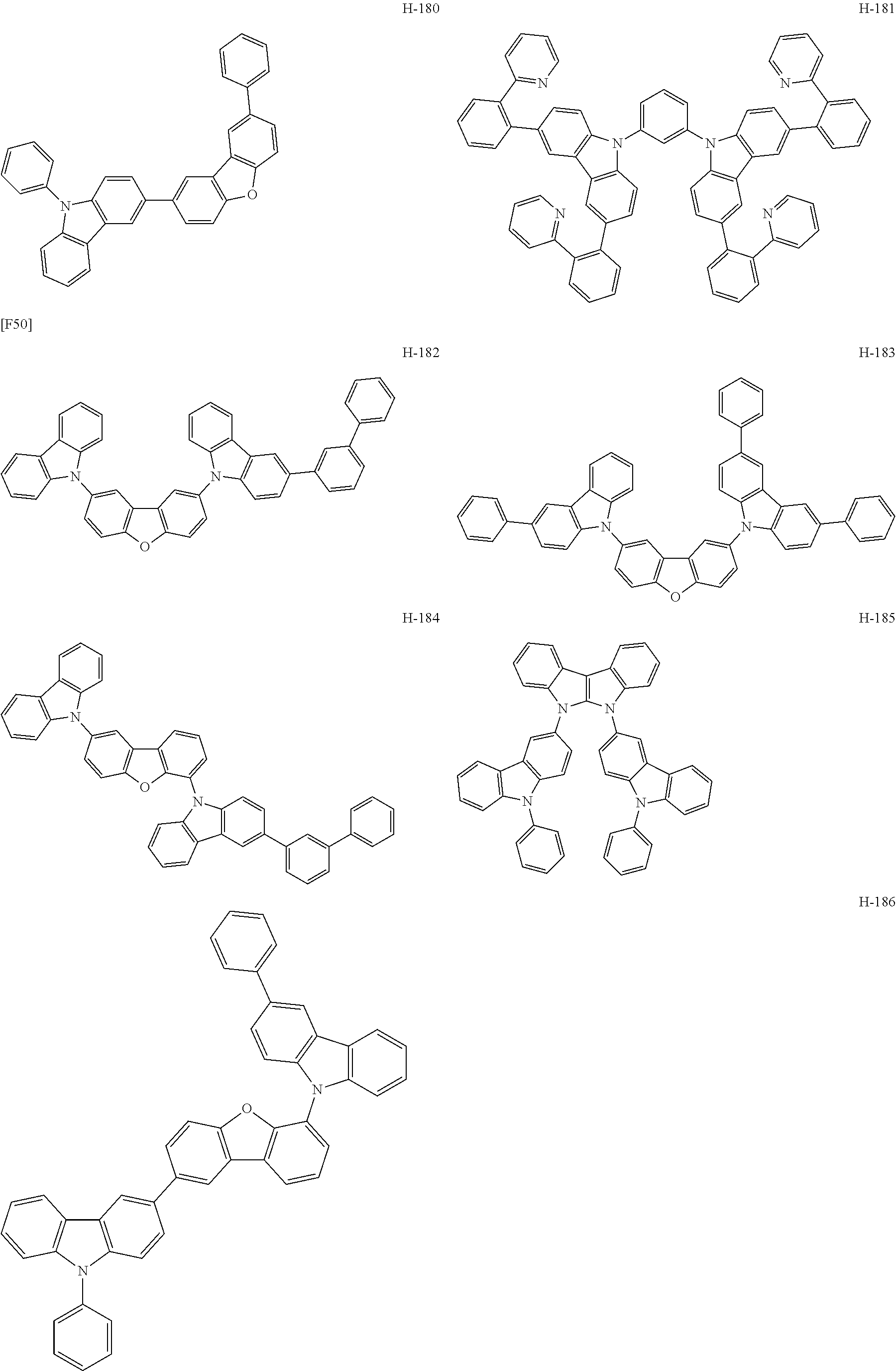

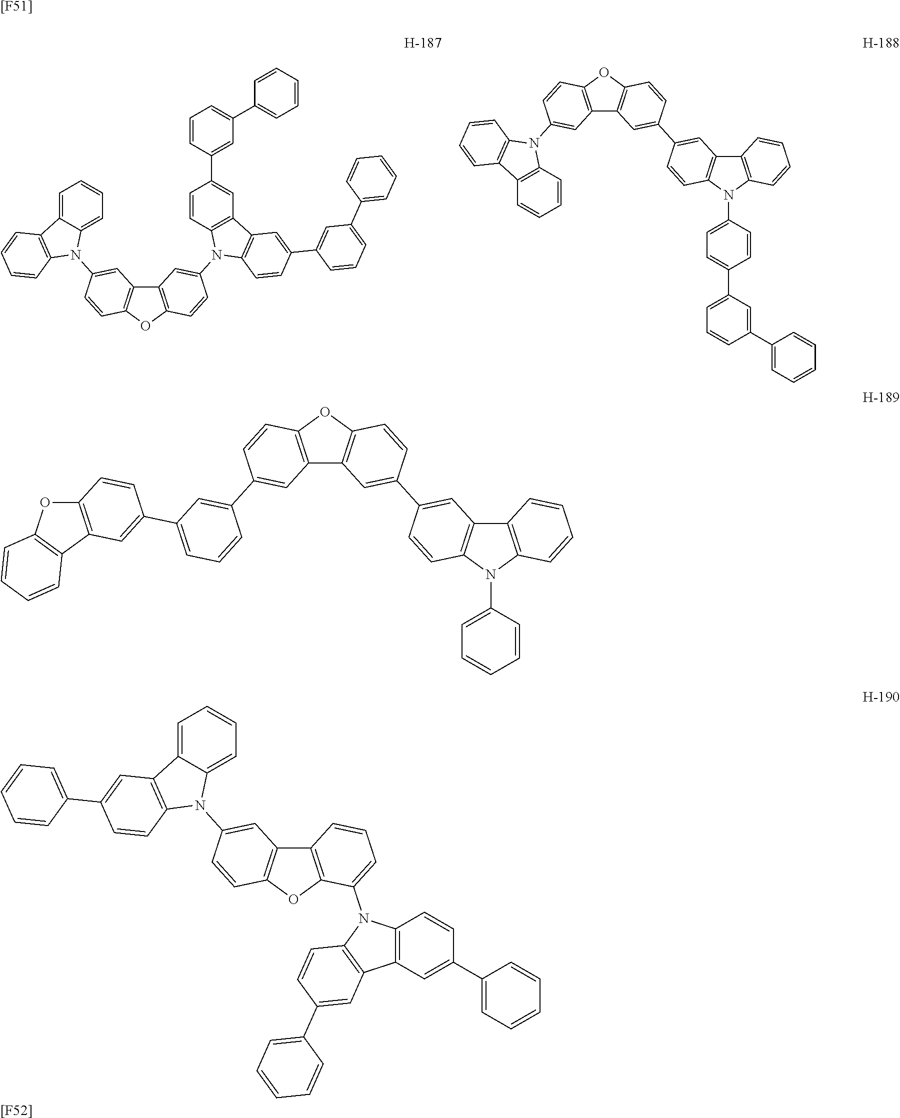

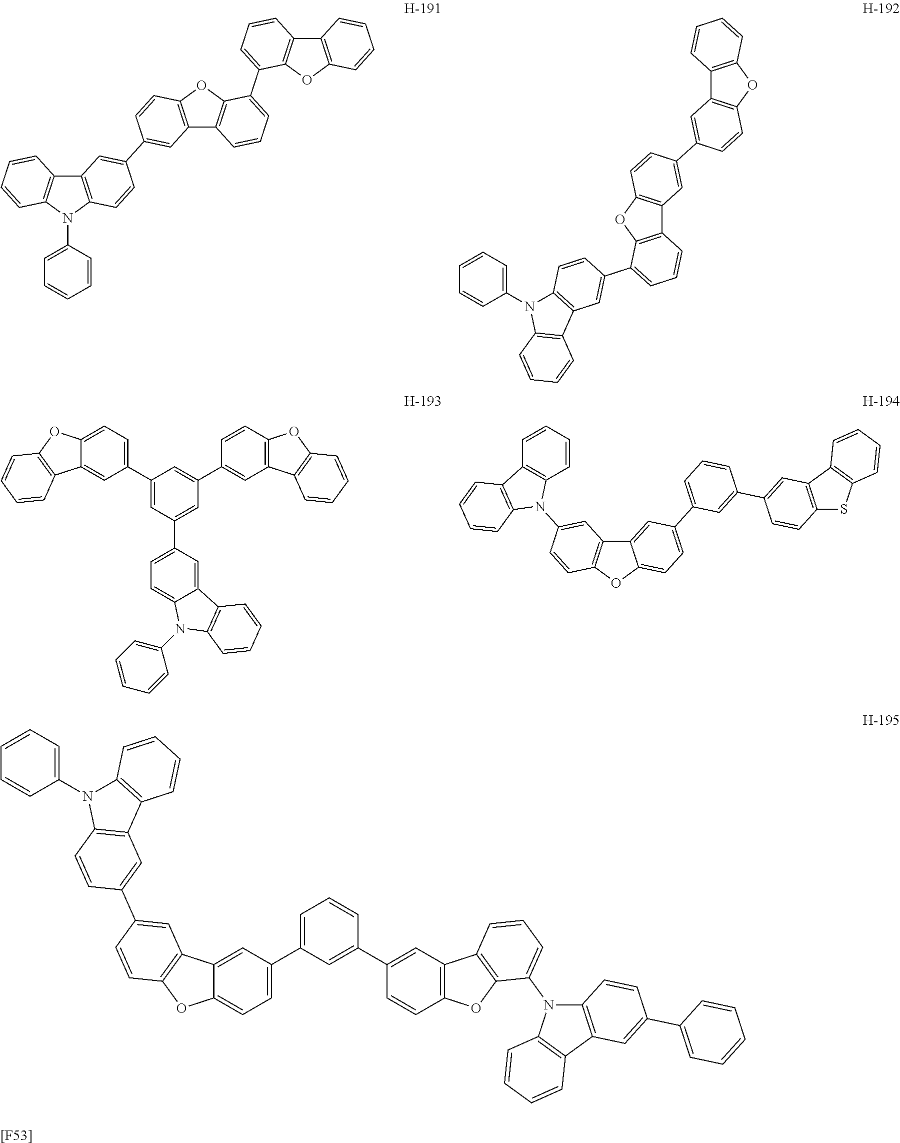

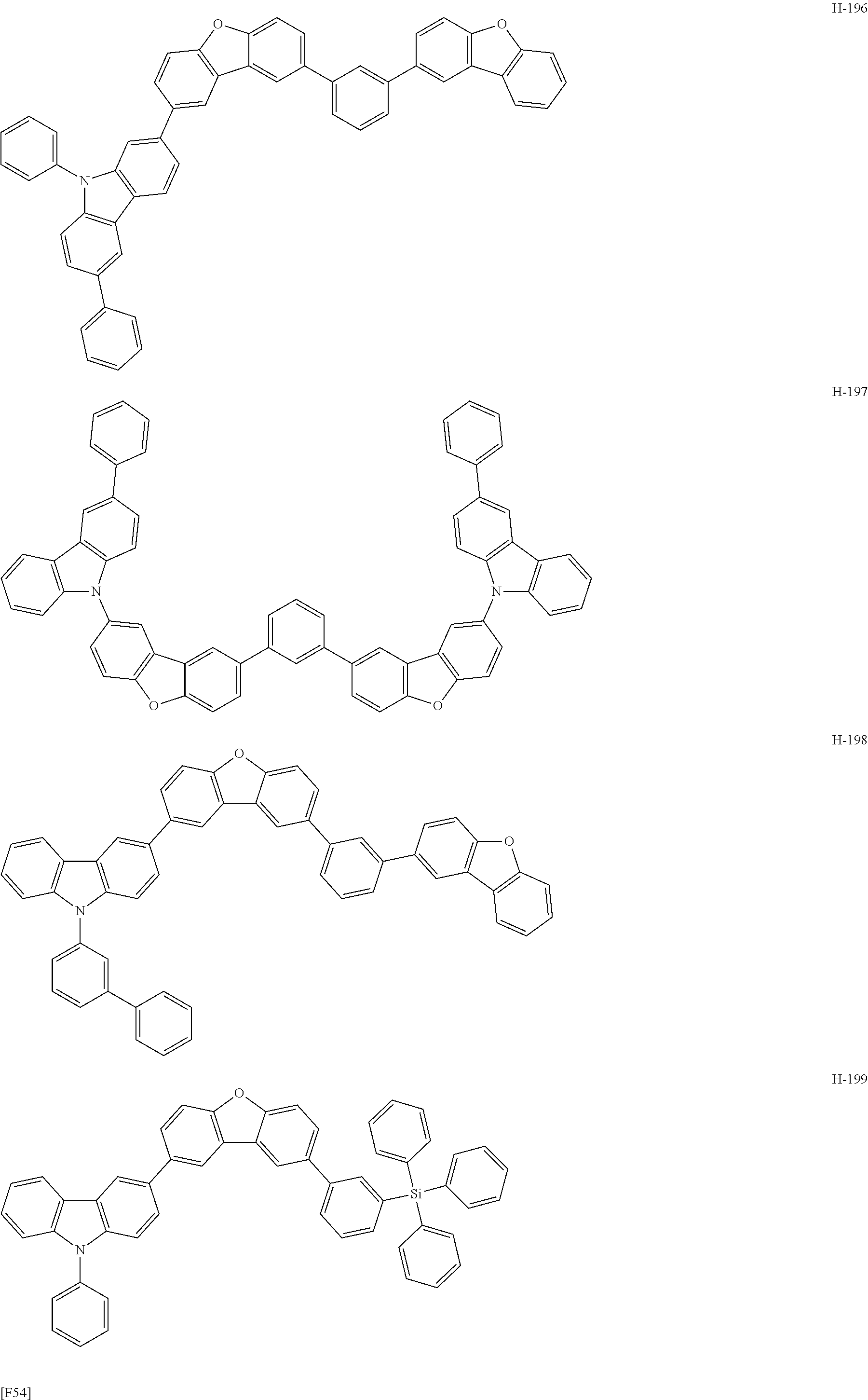

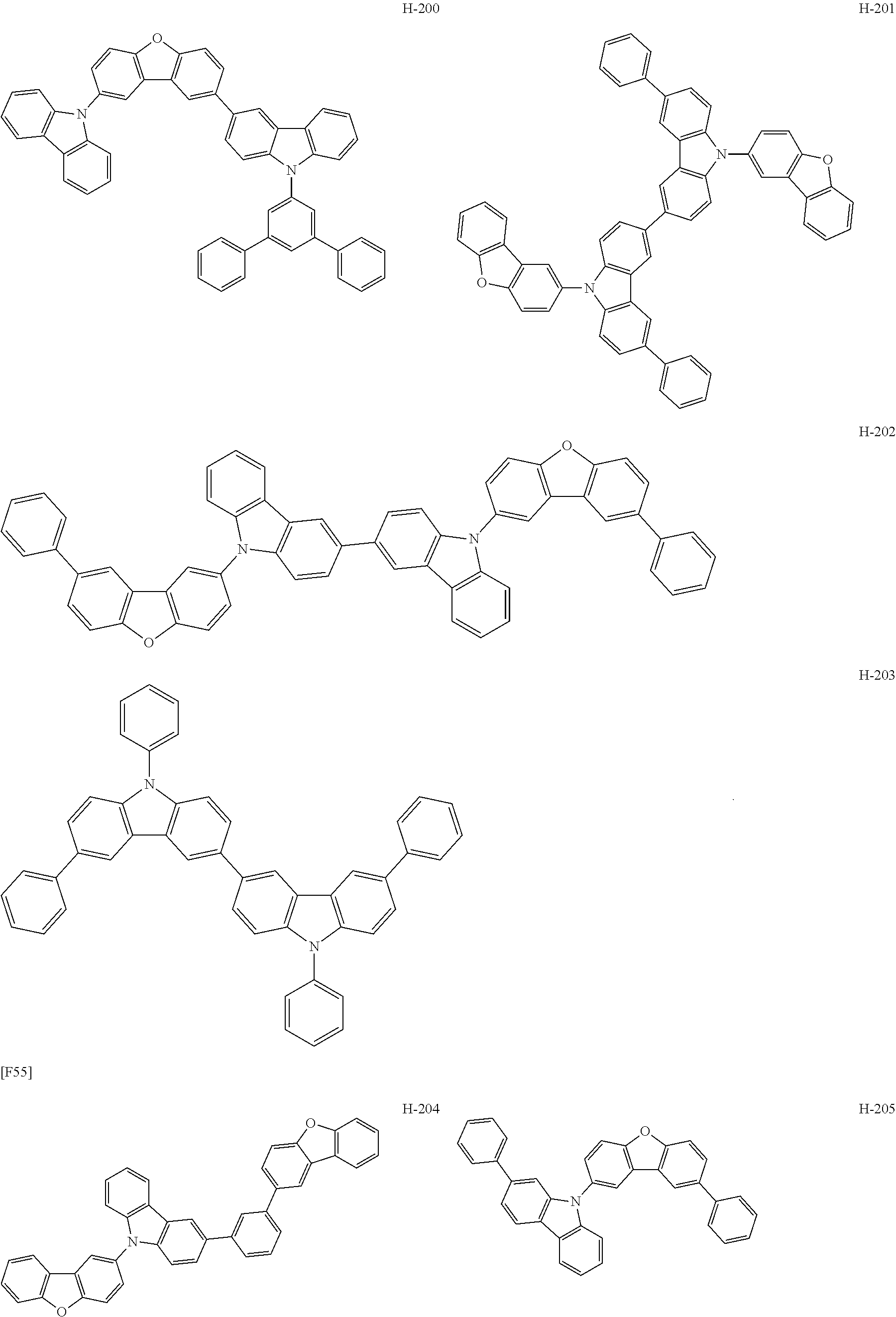

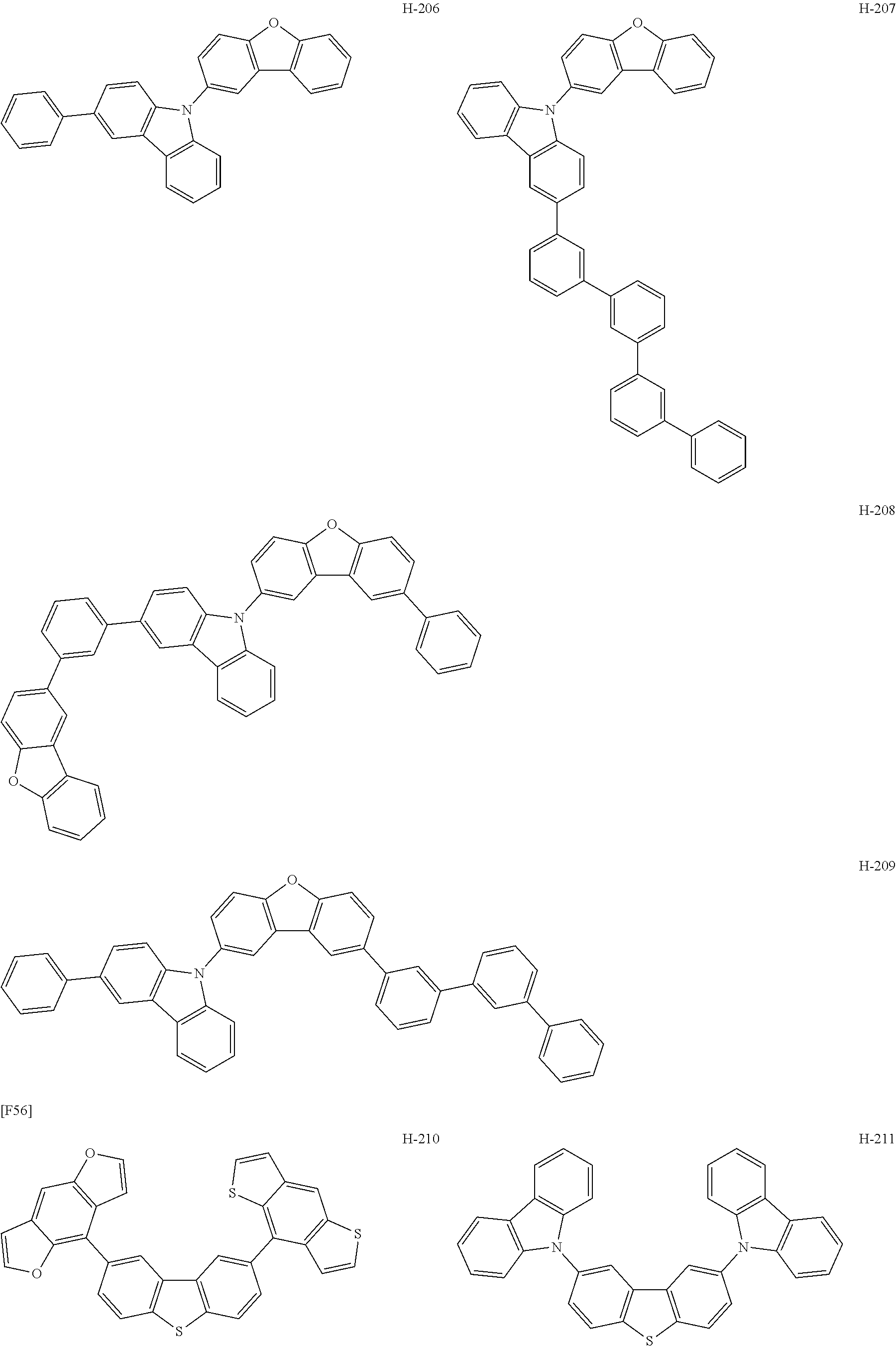

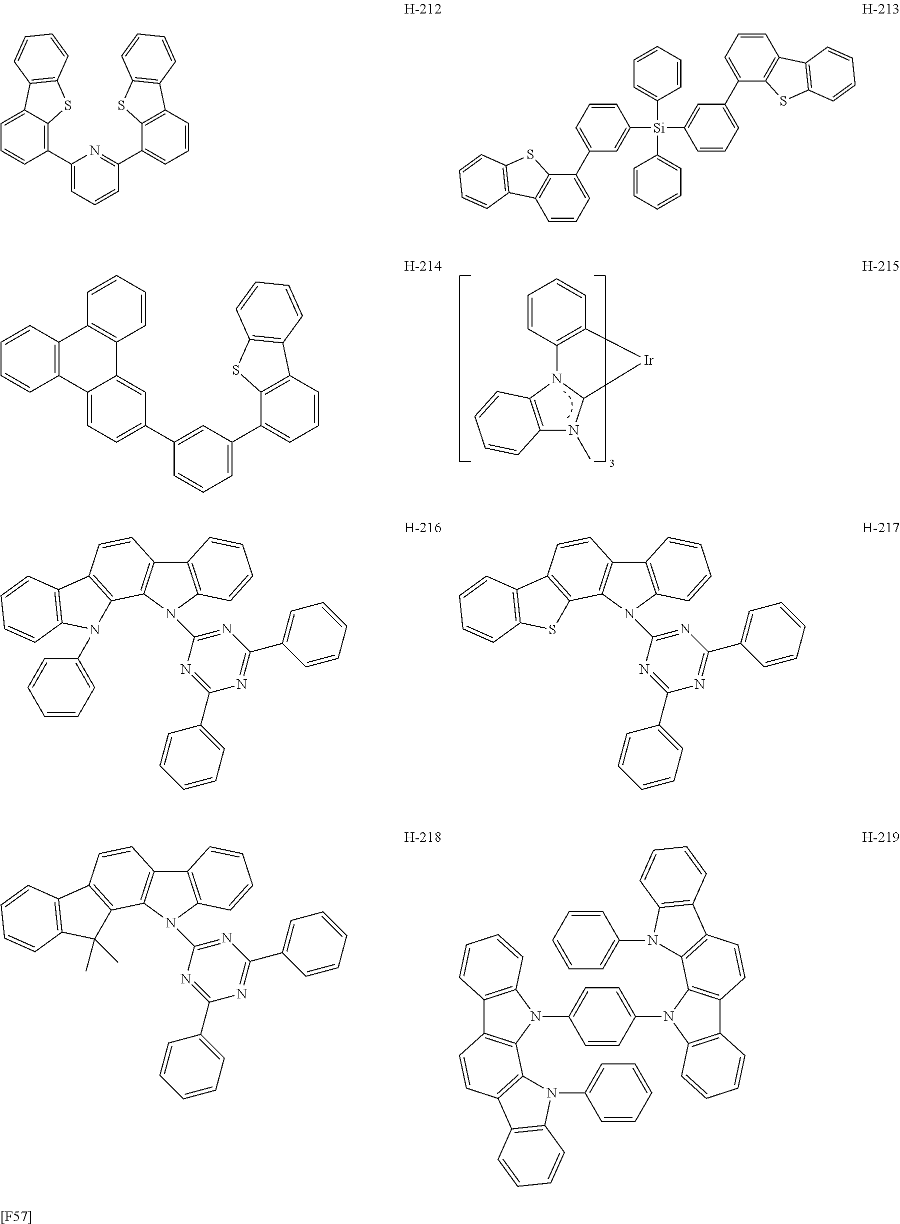

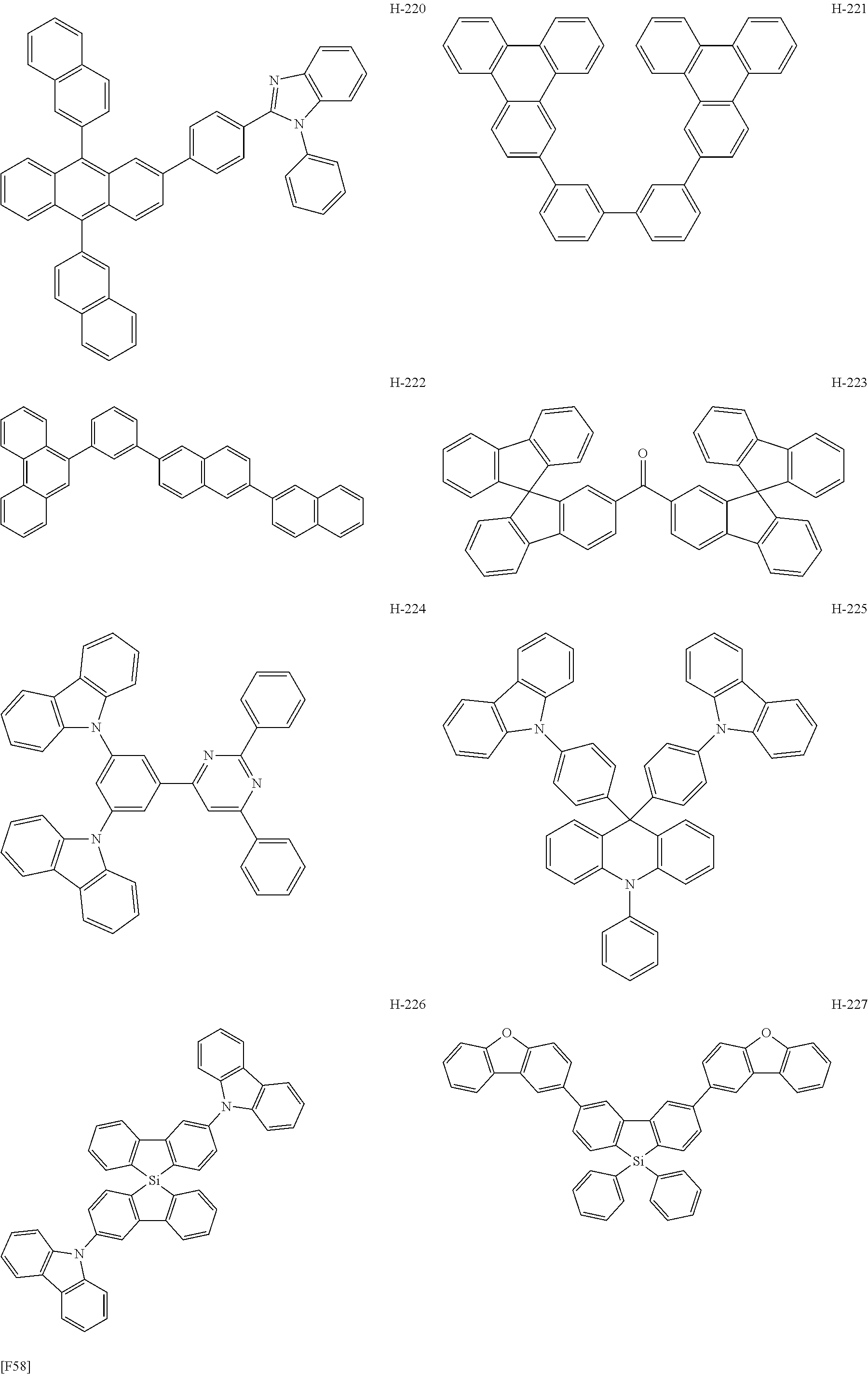

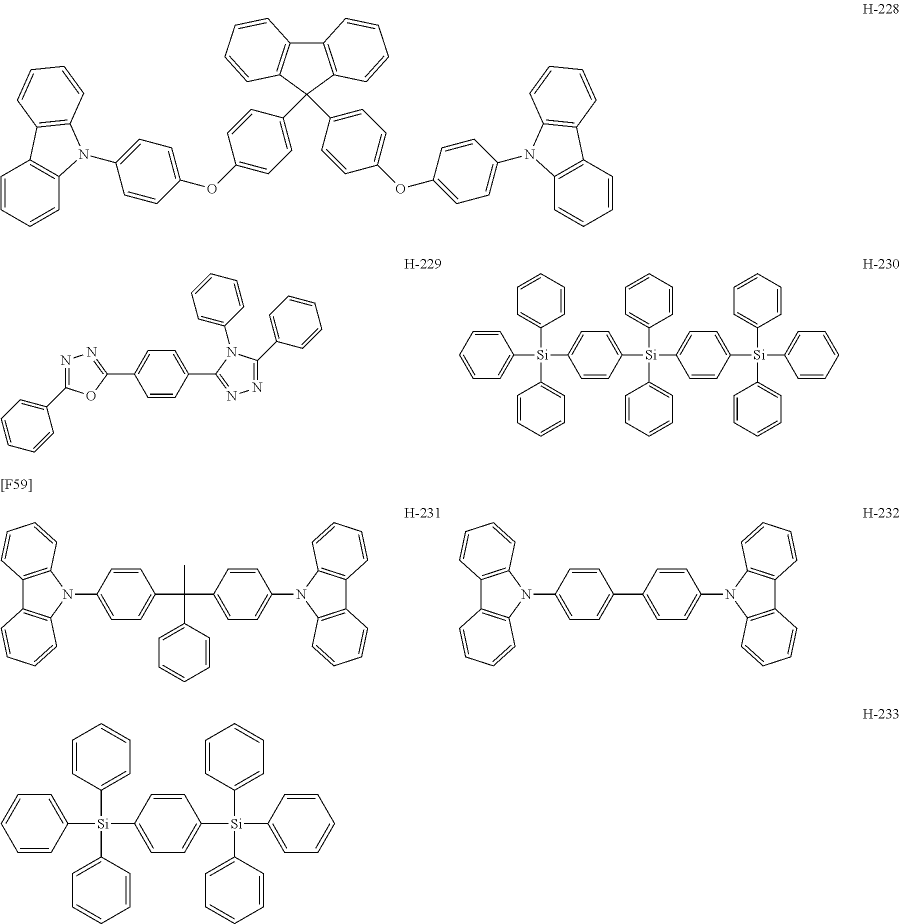

Among the compounds represented by Formulae (I) to (III-3), compounds represented by Formula (SH) are particularly preferred.

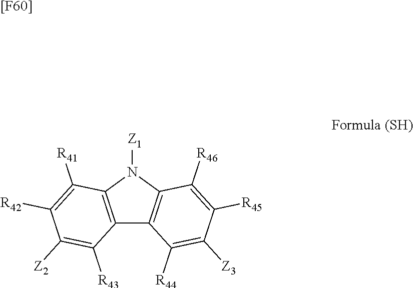

In Formula (SH), Z₁ to Z₃ and R₄₁ to R₄₆ each independently represent a hydrogen atom or a substituent; at least one of Z₁ to Z₃ and R₄₁ to R₄₆ represents an aromatic cyclic group having 14 or more π-electrons; and adjacent substituents may form a ring structure through condensation.

In Formula (SH), at least one of Z₁ to Z₃ is preferably a substituted or unsubstituted dibenzofuran ring for further enhancing the advantageous effects of the present invention.

The below-exemplified compounds include compounds represented by Formulae (I) to (III-3).

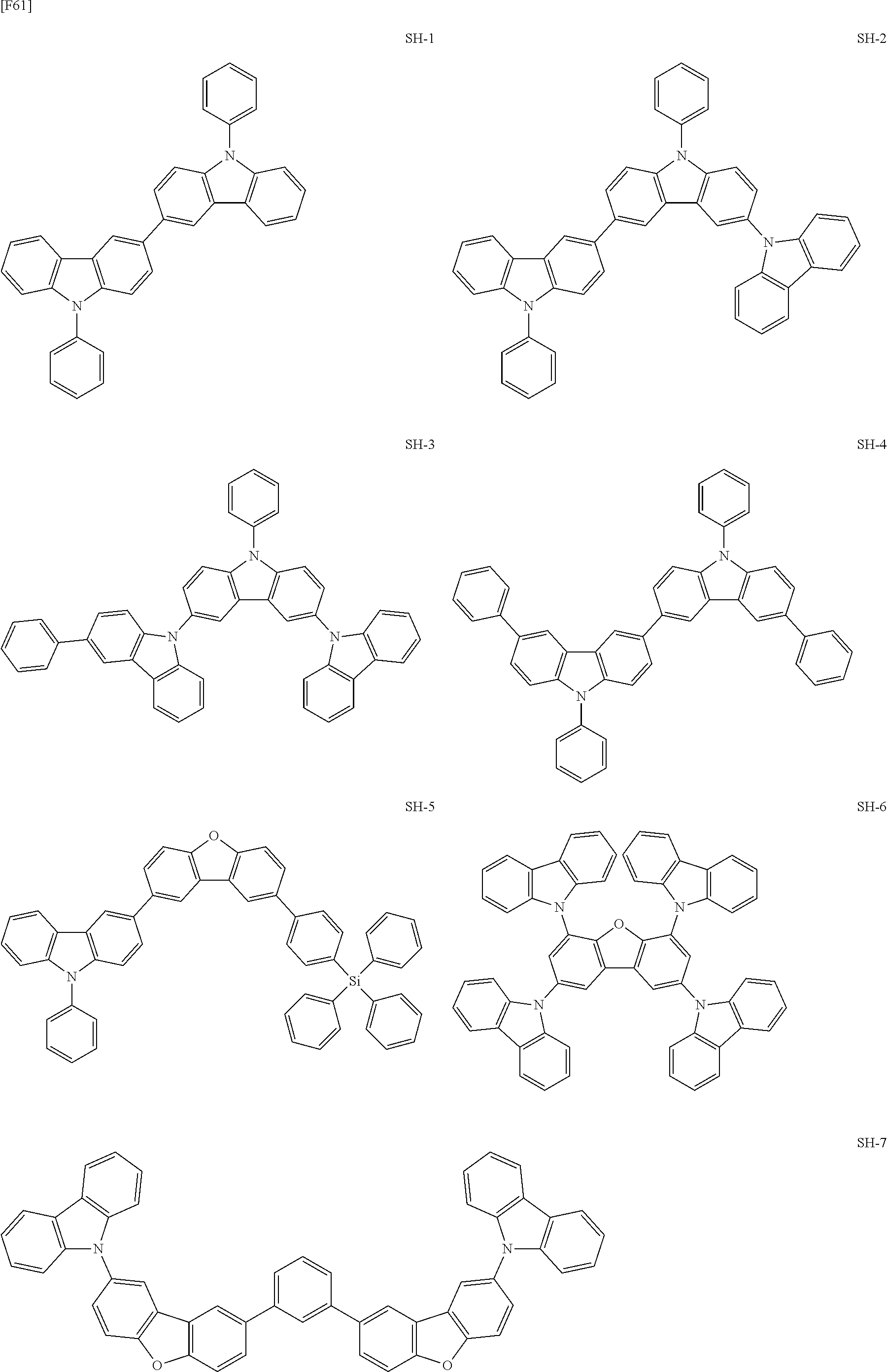

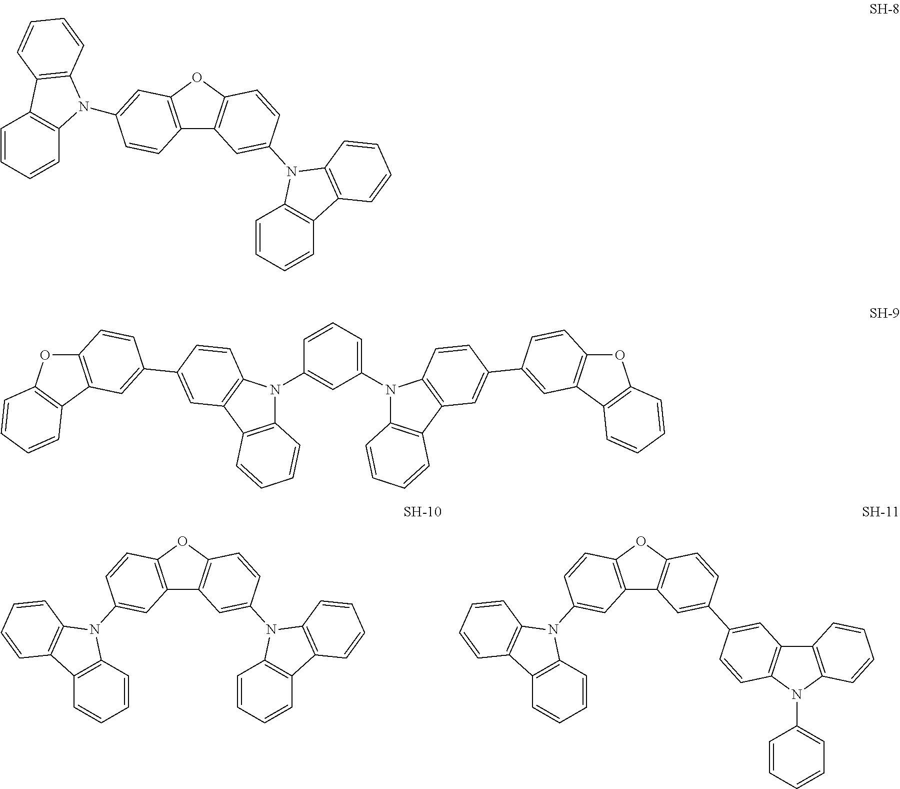 [SMILES: c1ccc2c(c1)c1ccccc1n2-c1ccc2c(c1)oc1ccc(-n3c4ccccc4c4ccccc43)cc12 ; c1cc(-n2c3ccccc3c3cc(-c4ccc5oc6ccccc6c5c4)ccc32)cc(-n2c3ccccc3c3cc(-c4ccc5oc6ccccc6c5c4)ccc32)c1 ; c1ccc2c(c1)c1ccccc1n2-c1ccc2oc3ccc(-n4c5ccccc5c5ccccc54)cc3c2c1 ; c1ccc(-n2c3ccccc3c3cc(-c4ccc5oc6ccc(-n7c8ccccc8c8ccccc87)cc6c5c4)ccc32)cc1]

The preferred host compound used in the present invention may be a compound having a low molecular weight that allows for purification by sublimation, or may be a polymer having repeating units.

The compound of low molecular weight has an advantage that it can be readily purified by sublimation into a high-purity material. The compound may have any molecular weight that allows for purification by sublimation. The molecular weight is preferably 3,000 or less, more preferably 2,000 or less.

The polymer or oligomer having repeating units has an advantage that it is readily formed into a film by a wet process. The polymer, which has high Tg in general, is preferred. The host compound used in the present invention may be any polymer that can achieve desired properties of the organic EL element, and is preferably a polymer having any of the structures represented by Formulae (I), (II), (III-1) to (III-3), and (SH) in the main chain or side chains. The polymer may have any molecular weight. The polymer preferably has a molecular weight of 5,000 or more or 10 or more repeating units.

The host compound preferably has a high glass transition temperature (Tg) in view of hole or electron transportability, prevention of an increase in emission wavelength, and stable operation of the organic EL element at high temperature. The glass transition temperature (Tg) is preferably 90° C. or higher, more preferably 120° C. or higher.

The glass transition point (Tg) is determined by differential scanning calorimetry (DSC) in accordance with JIS K 7121-2012.

### <<Electron Transporting Layer>>

The electron transporting layer according to the present invention, which is composed of a material having electron transportability, only needs to have a function of transferring electrons injected from the cathode to the light-emitting layer.

The electron transporting layer may have any thickness. The electron transporting layer generally has a thickness of nm to 5 μm, more preferably 2 to 500 nm, still more preferably 5 to 200 nm.

In the organic EL element, when light emitted from the light-emitting layer is extracted through an electrode, light extracted directly from the light-emitting layer interferes with light reflected by the counter electrode. If light is reflected by the cathode, the thickness of the electron transporting layer can be appropriately adjusted to several nm to several μm, to effectively utilize this interference phenomenon.

An increase in thickness of the electron transporting layer tends to cause an increase in voltage. Thus, an electron transporting layer having a large thickness preferably has an electron mobility of 10⁻⁵ cm²/Vs or more.

The material used for the electron transporting layer (hereinafter referred to as “electron transporting material”) may be any of conventional compounds capable of injecting or transporting electrons or blocking holes.

The material used for the electron transporting layer (hereinafter referred to as “electron transporting material”) may be any of conventional compounds capable of injecting or transporting electrons or blocking holes.

Examples of the electron transporting material include nitrogen-containing aromatic heterocyclic derivatives (e.g., carbazole derivatives, azacarbazole derivatives (wherein at least one of the carbon atoms forming the carbazole ring is substituted by a nitrogen atom), pyridine derivatives, pyrimidine derivatives, pyrazine derivatives, pyridazine derivatives, triazine derivatives, quinolone derivatives, quinoxaline derivatives, phenanthroline derivatives, azatriphenylene derivatives, oxazole derivatives, thiazole derivatives, oxadiazole derivatives, thiadiazole derivatives, triazole derivatives, benzimidazole derivatives, benzoxazole derivatives, and benzothiazole derivatives), dibenzofuran derivatives, dibenzothiophene derivatives, silole derivatives, and aromatic hydrocarbon derivatives (e.g., naphthalene derivatives, anthracene derivatives, and triphenylene).

The electron transporting material may be a metal complex having a quinolinol or dibenzoquinolinol structure as a ligand. Examples of the metal complex include tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, bis(8-quinolinol)zinc (Znq), and metal complexes where the central metal of any of these complexes is substituted by In, Mg, Cu, Ca, Sn, Ga or Pb.

The electron transporting material may also be a metal phthalocyanine, a metal-free phthalocyanine, or a metal or metal-free phthalocyanine whose end is substituted by an alkyl group or a sulfonate group. The electron transporting material may also be a distyrylpyrazine derivative, which has been exemplified as a material for the light-emitting layer, or may be an inorganic semiconductor material (e.g., n-type Si or n-type SiC) as in the case of the hole injecting layer or the hole transporting layer.

The electron transporting material may be a polymer material prepared by incorporation of any of these materials into a polymer chain, or a polymer material having a main chain composed of any of these materials.

The electron transporting layer according to the present invention may be a highly negative (electron-rich) electron transporting layer doped with a dopant serving as a guest. Examples of the dopant include n-type dopants, such as metal compounds (e.g., metal complexes and metal halides). Specific examples of the electron transporting layer having the aforementioned configuration include those disclosed in Japanese Patent Application Laid-Open Publication Nos. H4-297076, H10-270172, 2000-196140, and 2001-102175, and J. Appl. Phys., 95, 5773 (2004).

Specific examples of known electron transporting materials preferably used in the organic EL element of the present invention include, but are not limited to, compounds described in U.S. Pat. Nos. 6,528,187 and 7,230,107, U.S. Patent Application Publication Nos. 2005/0025993, 2004/0036077, 2009/0115316, 2009/0101870, and 2009/0179554, International Patent Publication WO2003/060956 and WO2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, U.S. Patent Application Publication No. 2009/030202, International Patent Publication WO2004/080975, WO2004/063159, WO2005/085387, WO2006/067931, WO2007/086552, WO2008/114690, WO2009/069442, WO2009/066779, WO2009/054253, WO2011/086935, WO2010/150593, and WO2010/047707, EP 2311826, Japanese Patent Application Laid-Open Publication Nos. 2010-251675, 2009-209133, 2009-124114, 2008-277810, 2006-156445, 2005-340122, 2003-45662, 2003-31367, and 2003-282270, and International Patent Publication WO2012/115034.

Examples of more preferred electron transporting materials in the present invention include an aromatic heterocyclic ring including at least one nitrogen atom, su as pyridine derivatives, pyrimidine derivatives, pyrazine derivatives, triazine derivatives, dibenzofuran derivatives, dibenzothiophene derivatives, azadibenzofuran derivatives, azadibenzonethiophene derivatives, carbazole derivatives, azacarbazole derivatives, and benzimidazoles derivatives.

These electron transporting materials may be used alone or in combination.

### <<Hole Blocking Layer>>

The hole blocking layer functions as an electron transporting layer in a broad sense and is preferably composed of a material which transports electrons and has a low capability of transporting holes. The hole blocking layer transports electrons and blocks holes, thereby increasing the probability of recombination of electrons and holes.

The aforementioned electron transporting layer may optionally be used as the hole blocking layer according to the present invention.

In the organic EL element of the present invention, the hole blocking layer is preferably disposed adjacent to the light-emitting layer on the cathode side.

The hole blocking layer according to the present invention has a thickness of preferably 3 to 100 nm, more preferably 5 to 30 nm.

The hole blocking layer is preferably composed of a material used for the aforementioned electron transporting layer, and is also preferably composed of any of the aforementioned host compounds.

### <<Electron Injecting Layer>>

The electron injecting layer according to the present invention (also referred to as “cathode buffer layer”) is provided between the cathode and the light-emitting layer for a reduction in driving voltage or an increase in luminance. The electron injecting layer is detailed in Chapter 2 “Denkyoku Zairyo (Electrode Materials)” (pp. 123-166) of Part 2 of “Yuki EL Soshi to Sono Kogyoka Saizensen (Organic EL element and its forefront of industrialization)” published by NTS Corporation, Nov. 30, 1998.

In the present invention, the electron injecting layer is optionally provided. The electron injecting layer may be disposed between the cathode and the light-emitting layer as described above, or between the cathode and the electron transporting layer.

The electron injecting layer is preferably composed of a very thin film, and has a thickness of preferably 0.1 to 5 nm, which may vary depending on the raw material used. The electron injecting layer may be composed of a layer (film) containing a non-uniformly distributed material.

The electron injecting layer is also detailed in Japanese Patent Application Laid-Open Publication Nos. H6-325871, H9-17574, and H10-74586. Specific examples of materials preferably used for the electron injecting layer include metals, such as strontium and aluminum, alkali metal compounds, such as lithium fluoride, sodium fluoride, and potassium fluoride; alkaline earth metal compounds, such as magnesium fluoride and calcium fluoride, metal oxides, such as aluminum oxide, and metal complexes, such as lithium 8-hydroxyquinolate (Liq). The aforementioned electron transporting materials may also be used.

These materials for the electron injecting layer may be used alone or in combination.

### [Hole Transporting Layer]

The hole transporting layer according to the present invention, which is composed of a material having hole transportability, only needs to have a function of transferring holes injected from the anode to the light-emitting layer.

The hole transporting layer may have any thickness. The electron transporting layer generally has a thickness of nm to 5 μm, more preferably 2 to 500 nm, still more preferably 5 to 200 nm.

The material used for the hole transporting layer (hereinafter referred to as “hole transporting material”) may be any of conventional compounds capable of injecting or transporting holes or blocking electrons.

Examples of the hole transporting material include porphyrin derivatives, phthalocyanine derivatives, oxazole derivatives, oxadiazole derivatives, triazole derivatives, imidazole derivatives, pyrazoline derivatives, pyrazolone derivatives, phenylenediamine derivatives, hydrazine derivatives, stilbene derivatives, polyarylalkane derivatives, triarylamine derivatives, carbazole derivatives, indolocarbazole derivatives, isoindole derivatives, acene derivatives, such as anthracene and naphthalene, fluorine derivatives, fluorenone derivatives, poly(vinylcarbazole), polymer materials and oligomers having an aromatic amine in the main chain or side chain, polysilanes, and conductive polymers and oligomers (e.g., PEDOT/PSS, aniline copolymers, polyaniline, and polythiophene).

Examples of the triarylamine derivatives include benzidine derivatives, such as α-NPD, starburst amine derivatives, such as MTDATA, and compounds having fluorine or anthracene on the bonding cores of tryarylamines.

The hole transporting material may also be hexaazatriphenylene derivatives described in Japanese Translation of PCT International Application Publication No. 2003-519432 and Japanese Patent Application Laid-Open Publication No. 2006-135145.

The hole transporting layer may be a highly positive hole transporting layer doped with an impurity. Examples of such an electron transporting layer include those described in Japanese Patent Application Laid-Open Publication Nos. H4-297076, 2000-196140, and 2001-102175, and J. Appl. Phys., 95, 5773 (2004).

The hole transporting material may be a p-type hole transporting material or an inorganic compound (e.g., p-type Si or p-type SiC) described in Japanese Patent Application Laid-Open Publication No. H11-251067 and J. Huang, et al., Applied Physics Letters 80 (2002), p. 139. The hole transporting material is preferably an ortho-metalated organometallic complex having Ir or Pt as a central metal, such as Ir(ppy)₃.

Among the aforementioned hole transporting materials, preferred are triarylamine derivatives, carbazole derivatives, indolocarbazole derivatives, azatriphenylene derivatives, organometallic complexes, and polymer materials and oligomers having an aromatic amine in the main chain or side chain.

Specific examples of known hole transporting materials preferably used in the organic EL element of the present invention include, but are not limited to, compounds described in the aforementioned publications and described in Appl. Phys. Lett. 69, 2160 (1996), J. Lumin. 72-74, 985 (1997), Appl. Phys. Lett. 78, 673 (2001), Appl. Phys. Lett. 90, 183503 (2007), Appl. Phys. Lett. 90, 183503 (2007), Appl. Phys. Lett. 51, 913 (1987), Synth. Met. 87, 171 (1997), Synth. Met. 91, 209 (1997), Synth. Met. 111, 421 (2000), SID Symposium Digest, 37, 923 (2006), J. Mater. Chem. 3, 319 (1993), Adv. Mater. 6, 677 (1994), Chem. Mater. 15, 3148 (2003), U.S. Patent Application Publication Nos. 2003/0162053, 2002/0158242, 2006/0240279, and 2008/0220265, U.S. Pat. No. 5,061,569, International Patent Publication WO2007/002683 and WO2009/018009, EP No. 650955, U.S. Patent Application Publication Nos. 2008/0124572, 2007/0278938, 2008/0106190, and 2008/0018221, International Patent Publication WO2012/115034, Japanese Translation of PCT International Application Publication No. 2003-519432, Japanese Patent Application Laid-Open Publication No. 2006-135145, and U.S. patent application Ser. No. 13/585,981.

These hole transporting materials may be used alone or in combination.

### <<Electron Blocking Layer>>

The electron blocking layer functions as a hole transporting layer in a broad sense and is preferably composed of a material which transports holes and has a low capability of transporting electrons. The electron blocking layer transports holes and blocks electros, thereby increasing the probability of recombination of electrons and holes.

The aforementioned hole transporting layer may optionally be used as the electron blocking layer according to the present invention.

In the organic EL element of the present invention, the electron blocking layer is preferably disposed adjacent to the light-emitting layer on the anode side.

The electron blocking layer according to the present invention has a thickness of preferably 3 to 100 nm, more preferably 5 to 30 nm.

The electron blocking layer is preferably composed of a material used for the aforementioned hole transporting layer, and is also preferably composed of any of the aforementioned host compounds.

### <<Hole Injecting Layer>>

The hole injecting layer according to the present invention (also referred to as “anode buffer layer”) is provided between the anode and the light-emitting layer for a reduction in driving voltage or an increase in luminance. The hole injecting layer is detailed in Chapter 2 “Denkyoku Zairyo (Electrode Materials)” (pp. 123-166) of Part 2 of “Yuki EL Soshi to Sono Kogyoka Saizensen (Organic EL element and its forefront of industrialization)” published by NTS Corporation, Nov. 30, 1998.”

In the present invention, the hole injecting layer is optionally provided. The hole injecting layer may be disposed between the anode and the light-emitting layer as described above, or between the anode and the hole transporting layer.

The hole injecting layer is also detailed in Japanese Patent Application Laid-Open Publication Nos. H9-45479, H9-260062, and H8-288069. Examples of the material for the hole injecting layer include those used for the aforementioned hole transporting layer.

Examples of particularly preferred materials include phthalocyanine derivatives, such as copper phthalocyanine, hexaazatriphenylene derivatives described in Japanese Translation of PCT International Application Publication No. 2003-519432 and Japanese Patent Application Laid-Open Publication No. 2006-135145, metal oxides, such as vanadium oxide, amorphous carbon, conductive polymers, such as polyaniline (emeraldine) and polythiophene, ortho-metalated complexes, such as a tris(2-phenylpyridine)iridium complex, and triarylamine derivatives.

These materials for the hole injecting layer may be used alone or in combination.

### <<Additive>>

Each of the aforementioned organic layers according to the present invention may contain any other additive.

Examples of the additive include halogens, such as bromine, iodine, and chlorine, halides, alkali metals and alkaline earth metals, such as Pd, Ca, and Na, transition metal compounds, complexes, and salts.

The additive content of the organic layer may be appropriately determined. The additive content is preferably 1,000 ppm or less, more preferably 500 ppm or less, still more preferably 50 ppm or less, relative to the entire mass % of the layer containing the additive.

The additive content may fall outside of this range for improvement of electron or hole transportability or effective energy transfer of excitons.

### <<Formation of Organic Layer>>

Now will be described a process of forming the organic layers (hole injecting layer, hole transporting layer, light-emitting layer, hole blocking layer, electron transporting layer, and electron injecting layer) according to the present invention.

The organic layer according to the present invention can be formed by any known process, such as a vacuum deposition process or a wet process.

Examples of the wet process include spin coating, casting, ink jetting, printing, die coating, blade coating, roll coating, spray coating, curtain coating, and the Langmuir-Blodgett (LB) method. Preferred are processes highly suitable for a roll-to-roll system, such as die coating, roll coating, ink jetting, and spray coating, in view of easy formation of a thin homogeneous film and high productivity.

Examples of the liquid medium for dissolution or dispersion of the organic EL materials according to the present invention include ketones, such as methyl ethyl ketone and cyclohexanone, fatty acid esters, such as ethyl acetate, halogenated hydrocarbons, such as dichlorobenzene, aromatic hydrocarbons, such as toluene, xylene, mesitylene, and cyclohexylbenzene, aliphatic hydrocarbons, such as cyclohexane, decalin, and dodecane, and organic solvents, such as DMF and DMSO.

Examples of the usable dispersion technique include ultrasonic dispersion, high shearing force dispersion, and medium dispersion.

Different layers may be formed through different processes. If a layer is formed through a deposition process, appropriate deposition conditions, which may vary depending on the type of a compound used, are as follows: a boat heating temperature of 50 to 450° C., a vacuum of 10⁻⁶ to 10⁻² Pa, a deposition rate of 0.01 to 50 nm/second, a substrate temperature of −50 to 300° C., and a layer (film) thickness of 0.1 nm to 5 μm (preferably 5 to 200 nm).

The organic EL element of the present invention is preferably produced by forming the aforementioned organic layers (from the hole injecting layer to the cathode) through a single vacuuming process. The vacuuming process may be intermitted, and a process other than the vacuuming process may then be performed for forming the layers. In such a case, the process is preferably carried out in a dry inert gas atmosphere.

### <<Anode>>

The anode of the organic EL element is preferably composed of an electrode material having a high work function (4 eV or more, preferably 4.5 eV or more), such as a metal, an alloy, a conductive compound, or a mixture thereof. Specific examples of the electrode material include metals, such as Au, and transparent conductive materials, such as CuI, indium thin oxide (ITO), SnO₂, and ZnO. An amorphous material capable of forming a transparent conductive film, such as IDIXO (In₂O₃—ZnO), may also be used.

The anode can be prepared through formation of a thin film from any of the aforementioned electrode materials by deposition or sputtering, followed by patterning through photolithography, to form a desired pattern. If high patterning accuracy is not required (i.e., an accuracy of about 100 μm or more), patterning may be performed with a mask having a desired shape in deposition or sputtering of the aforementioned electrode material.

If an applicable substance, such as an organic conductive compound, is used, a wet film forming process, such as printing or coating, may be performed. For extraction of light emitted from the anode, the transmittance of the anode is preferably 10% or more, and the sheet resistance of the anode is preferably several hundreds of Ω/square or less.

The anode has a thickness of 10 nm to 1 μm, preferably 10 to 200 nm, which may vary depending on the material used.

### <<Cathode>>

The cathode is composed of an electrode material having a low work function (4 eV or less), such as a metal (referred to as “electron-injecting metal”), an alloy, a conductive compound, or a mixture thereof. Specific examples of the electrode material include sodium, a sodium-potassium alloy, magnesium, lithium, a magnesium-copper mixture, a magnesium-silver mixture, a magnesium-aluminum mixture, a magnesium-indium mixture, an aluminum-aluminum oxide (Al₂O₃) mixture, indium, a lithium-aluminum mixture, aluminum, and rare earth elements. Among these material, preferred is a mixture of an electron-injecting metal and a second metal which is stable and has a work function higher than that of the electron-injecting material, such as a magnesium-silver mixture, a magnesium-aluminum mixture, a magnesium-indium mixture, an aluminum-aluminum oxide (Al₂O₃) mixture, a lithium-aluminum mixture, or aluminum, in view of electron injection and resistance against oxidation, for example.

The cathode can be prepared through formation of a thin film from any of the aforementioned electrode materials by deposition or sputtering. The cathode has a sheet resistance of preferably several hundreds of Ω/square or less, and has a thickness of 10 nm to 5 μm, preferably 50 to 200 nm.

From the viewpoint of transmission of emitted light, the anode or cathode of the organic EL element is preferably transparent or translucent for an increase in luminance.

The cathode can be imparted with transparency or translucency by forming of a film having a thickness of 1 to 20 nm on the cathode from any of the aforementioned metals, followed by deposition, on the film, of any of the transparent conductive materials used for the anode. Application of this process can produce an organic El element including a translucent anode and a translucent cathode.

### [Supporting Substrate]

The supporting substrate used for the organic EL element of the present invention (hereinafter also referred to as “substrate,” “base,” or “support”) may be composed of any glass or plastic material, and may be transparent or opaque. If light is extracted through the supporting substrate, the supporting substrate is preferably transparent. Examples of preferred transparent supporting substrates include glass films, quartz films, and transparent resin films. Particularly preferred is a resin film which can impart flexibility to the organic EL element.

Examples of the resin film include films of polyesters, such as poly(ethylene terephthalate) (PET) and poly(ethylene naphthalate) (PEN), polyethylene, polypropylene, cellophane, cellulose esters and their derivatives, such as cellulose diacetate, cellulose triacetate, cellulose acetate butyrate, cellulose acetate propionate (CAP), cellulose acetate phthalate (TAC), and cellulose nitrate, poly(vinylidene chloride), poly(vinyl alcohol), polyethylene/vinyl alcohol, syndiotactic polystyrene, polycarbonates, norbornene resins, polymethylpentene, polyether ketones, polyimides, polyethersulfone (PES), poly(phenylene sulfide), polysulfones, polyether imide, polyether ketone imide, polyamides, fluororesins, nylon, poly(methyl methacrylate), acrylic resins, polyarylates, and cycloolefin resins, such as ARTON (trade name, manufactured by JSR Corp.) and APEL (trade name, manufactured by Mitsui Chemicals Inc.).

On the surface of the resin film may be formed an inorganic or organic coating film or a hybrid coating film composed of both. The coating film is preferably a barrier film having a water vapor transmission rate (25±0.5° C., relative humidity (90±2)% RH) of 0.01 g/(m²·24 h) or less as determined in accordance with JIS K 7129-1992. The coating film is more preferably a high barrier film having an oxygen transmission rate of 1×10⁻³ mL/m²·24 h atm or less as determined in accordance with JIS K 7126-1987 and a water vapor transmission rate of 1×10⁻⁵ g/m²·24 h or less.

The barrier film may be formed from any material capable of preventing intrusion of a substance which impairs the organic EL element, such as moisture or oxygen. Examples of the material include silicon oxide, silicon dioxide, and silicon nitride. In view of enhancement of the strength, the barrier film preferably has a layered structure composed of an inorganic layer and an organic material layer. The inorganic layer and the organic layer may be disposed in any order. Preferably, a plurality of inorganic layers and organic layers are alternately disposed.

The barrier film may be formed by any known process. Examples of the process include vacuum deposition, sputtering, reactive sputtering, molecular beam epitaxy, the ionized-cluster beam method, ion plating, plasma polymerization, atmospheric pressure plasma polymerization, plasma CVD, laser CVD, thermal CVD, and coating. In particular, the barrier film is preferably formed through atmospheric pressure plasma polymerization as described in Japanese Patent Application Laid-Open Publication No. 2004-68143.

Examples of the opaque supporting substrate include metal plates, such as aluminum plates and stainless steel plates, films, opaque resin substrates, and ceramic substrates.

In the organic EL element of the present invention, the external extraction efficiency of light at room temperature (25° C.) is preferably 1% or more, more preferably 5% or more.

The external extraction efficiency of light (%) is determined by the following expression:

external extraction efficiency of light (%)=(the number of photons emitted to the outside of the organic EL element/the number of electrons flowing through the organic EL element)×100.

A hue improving filter (e.g., a color filter) may be used in combination. Alternatively, a color conversion filter may be used in combination which converts the color of light emitted from the organic EL element into multiple colors with a fluorescent material.

### [Sealing]

Examples of the means for sealing of the organic EL element of the present invention include a process of bonding a sealing member to the electrode and the supporting substrate with an adhesive. The sealing member only needs to be disposed to cover a display area of the organic EL element. The sealing member may be in the form of concave plate or flat plate. The sealing member may have transparency or electrical insulating property.

Specific examples of the sealing member include a glass plate, a composite of polymer plate and film, and a composite of metal plate and film. Examples of the glass plate include plates of soda-lime grass, glass containing barium and strontium, lead glass, aluminosilicate glass, borosilicate glass, barium borosilicate glass, and quartz. Examples of the polymer plate include plates of polycarbonate, acrylic resin, poly(ethylene terephthalate), polyethersulfide, and polysulfone. Examples of the metal plate include plates composed of one or more metals selected from stainless steel, iron, copper, aluminum, magnesium, nickel, zinc, chromium, titanium, molybdenum, silicon, germanium, and tantalum, and plates composed of alloys of these metals.

In the present invention, a polymer film or a metal film is preferably used for reducing the thickness of the organic EL element. The polymer film preferably has an oxygen transmission rate of 1×10⁻³ mL/m²·24 h or less as determined in accordance with JIS K 7126-1987 and a water vapor transmission rate (25±0.5° C., relative humidity of 90±2%) of 1×10⁻³ g/m²·24 h or less as determined in accordance with JIS K 7129-1992.

The sealing member may be formed into a concave plate by sandblasting or chemical etching.

Specific examples of the adhesive include photocurable and thermosetting adhesives containing reactive vinyl groups of acrylic acid oligomers and methacrylic acid oligomers, moisture-curable adhesives, such as 2-cyanoacrylate esters, and thermosetting and chemical-curable adhesives (two-component adhesives), such as epoxy adhesives. Other examples include hot-melt polyamides, polyesters, and polyolefins, and cationic UV-curable epoxy resin adhesives.

In consideration that the organic EL element may be degraded through thermal treatment, an adhesive is preferably used which can be cured at a temperature of room temperature to 80° C. The adhesive may contain a desiccant dispersed therein. The adhesive may be applied to a sealing portion with a commercially available dispenser or by screen printing.

An inorganic or organic layer, serving as a sealing film, is preferably formed on the electrode which sandwiches the organic layer with the supporting substrate so as to cover the electrode and the organic layer and to come into contact with the supporting substrate. The sealing film may be formed from any material capable of preventing intrusion of a substance which impairs the organic EL element, such as moisture or oxygen. Examples of the material include silicon oxide, silicon dioxide, and silicon nitride.

In view of enhancement of the strength, the sealing film preferably has a layered structure composed of an inorganic layer and an organic material layer. The sealing film may be formed by any known process. Examples of the process include vacuum deposition, sputtering, reactive sputtering, molecular beam epitaxy, the ionized-cluster beam method, ion plating, plasma polymerization, atmospheric pressure plasma polymerization, plasma CVD, laser CVD, thermal CVD, and coating.

The gap between the sealing member and the display area of the organic EL element is preferably filled with an inert gas (e.g., nitrogen or argon) or an inert liquid (e.g., fluorohydrocarbon or silicone oil). The gap between the sealing member and the display area may be vacuum. Alternatively, the gap may be filled with a hygroscopic compound.

Examples of the hygroscopic compound include metal oxides (e.g., sodium oxide, potassium oxide, calcium oxide, barium oxide, magnesium oxide, and aluminum oxide), sulfates (e.g., sodium sulfate, calcium sulfate, magnesium sulfate, and cobalt sulfate), metal halides (e.g., calcium chloride, magnesium chloride, cesium fluoride, tantalum fluoride, cerium bromide, magnesium bromide, barium iodide, and magnesium iodide), and perchlorates (e.g., barium perchlorate and magnesium perchlorate). Preferred are anhydrous salts of sulfates, metal halides, and perchlorates.

### [Protective Film, Protective Plate]

In order to increase the mechanical strength of the organic EL element, a protective film or plate may be provided on the surface of the sealing film which faces the supporting substrate with the organic layer being disposed therebetween. If the sealing film is used for sealing of the organic EL element, such a protective film or plate is preferably provided, because the mechanical strength of the element is not necessarily high. Examples of the material for the protective film or plate include those used for the aforementioned sealing member, such as a glass plate, a composite of polymer plate and film, and a composite of metal plate and film. Of these, a polymer film is preferably used in view of a reduction in weight and thickness.

### [Technique for Improvement of Light Extraction]

In general, in an organic EL element, light is emitted in a layer having a refractive index higher than that of air (i.e., a refractive index of about 1.6 to 2.1), and only about 15 to 20% of the light emitted from the light-emitting layer is extracted. The reason for this is attributed to the fact that light incident on an interface (interface between a transparent substrate and air) at an angle θ equal to or larger than the critical angle is totally reflected and cannot be extracted from the element, and that light is totally reflected at the interface between the transparent substrate and the transparent electrode or the light-emitting layer and is guided to the transparent electrode or the light-emitting layer, whereby the light is released along the side face of the element.

Examples of the technique for improving the efficiency of light extraction include a technique for preventing total reflection at the interface between the transparent substrate and air by providing irregularities on the surface of the transparent substrate (see, for example, U.S. Pat. No. 4,774,435); a technique for improving the efficiency of light extraction by imparting light collecting property to the substrate (see, for example, Japanese Patent Application Laid-Open Publication No. S63-314795); a technique for forming a reflection surface on the side faces of the element (see, for example, Japanese Patent Application Laid-Open Publication No. H1-220394); a technique for providing an anti-reflection film by disposing a flat layer between the substrate and the light-emitting layer, the flat layer having a refractive index which is intermediate between those of the substrate and the light-emitting layer (see, for example, Japanese Patent Application Laid-Open Publication No. S62-172691); a technique for disposing a flat layer between the substrate and the light-emitting layer, the flat layer having a refractive index lower than that of the substrate (see, for example, Japanese Patent Application Laid-Open Publication No. 2001-202827); and a technique for providing a diffraction grating between any layers of the substrate, the transparent electrode layer, and the light-emitting layer (including on the substrate surface exposed to the outside) (Japanese Patent Application Laid-Open Publication No. H11-283751).

In the present invention, any of these techniques can be used for the organic electroluminescent element of the present invention. In particular, preferred is a technique for disposing a flat layer between the substrate and the light-emitting layer, the flat layer having a refractive index lower than that of the substrate, or a technique for forming a diffraction grating between any layers of the substrate, the transparent electrode layer, and the light-emitting layer (including on the substrate surface exposed to the outside).

The present invention can provide an element exhibiting higher luminance or excellent durability by combining the aforementioned techniques.

If a medium having a low refractive index and having a thickness larger than a light wavelength is provided between a transparent electrode and a transparent substrate, the efficiency of extraction of light from the transparent electrode to the outside increases with a decrease in refractive index of the medium.

The layer of low refractive index may be composed of, for example, aero gel, porous silica, magnesium fluoride, or a fluorine-containing polymer. The refractive index of the layer of low refractive index is preferably about 1.5 or less, because the transparent substrate generally has a refractive index of about 1.5 to 1.7. The refractive index of the layer of low refractive index is more preferably 1.35 or less.

The medium of low refractive index preferably has a thickness twice or more a light wavelength in the medium. This is because, if the medium of low refractive index has a thickness nearly equal to the light wavelength, the electromagnetic wave exuded as an evanescent wave enters the substrate, leading to a reduction in the effect of the layer of low refractive index.

The technique for providing a diffraction grating at any interface where total reflection occurs or in any medium can highly improve the efficiency of light extraction. A diffraction grating turns light to a specific direction other than the refraction direction by Bragg diffraction (e.g., a primary diffraction or a secondary diffraction). This technique uses the diffraction grating provided at any interface or in any medium (e.g., in a transparent substrate or a transparent electrode), and achieves extraction of a light component emitted from the light-emitting layer, which would otherwise fail to be extracted to the outside due to the total reflection, to the outside by diffraction with the diffraction grating.

The diffraction grating used preferably has a two-dimensional periodic refractive index profile, for the following reasons. Because light is emitted in any directions randomly in the light-emitting layer, a common one-dimensional diffraction grating having a periodic refractive index profile in a specific direction diffracts light only in the specific direction, resulting in a low effect of improving the efficiency of light extraction.

In contrast, the diffraction grating having a two-dimensional diffractive index profile can diffract light in any directions and thus highly improve the efficiency of light extraction.

The diffraction grating may be provided at any interface or any medium (e.g., in a transparent substrate or a transparent electrode). Preferably, the diffraction grating is provided around the organic light-emitting layer, from which light is emitted. The pitch of the diffraction grating is preferably about a half to three times of the wavelength of light in the medium. The diffraction grating preferably has in a two-dimensionally repeated pattern, such as a square lattice, triangular lattice, or honeycomb lattice pattern.

### [Light Condensing Sheet]

In the organic EL element of the present invention, the supporting substrate (substrate) may be provided, on its side for light extraction, with a microlens array structure or a light condensing sheet, to collect light in a specific direction (e.g., in a front direction of a light emitting face of the element), thereby increasing luminance in the specific direction.

For example, the microlens array includes two-dimensionally arranged quadrangular pyramids each having a 30-μm side and a vertex angle of 90°, on the light-extraction side of the substrate. Each side of the quadrangular pyramid has a length of preferably 10 to 100 μm. A side having a length below this range leads to coloring caused by diffraction, whereas an excessively long side leads to an undesirable increase in thickness of the element.

The light condensing sheet may be, for example, a commercially available sheet used in an LED backlight of a liquid crystal display device. Examples of such a sheet include Brightness Enhancement Film (BEF) manufactured by Sumitomo 3M Ltd. The prism sheet may be composed of a base with triangular protrudent stripes having a vertex angle of 90° C. which are arranged at pitches of 50 μm. The vertexes of the triangular protrudent stripes may be rounded, or the pitches may be randomly varied. The sheet may have any other structure.

In order to control the radiation angle of light from the organic EL element, the light condensing sheet may be used in combination with a light diffusing plate or film; for example, a diffusing film (LIGHT-UP, manufactured by KIMOTO Co., Ltd.).

### [Application]

The organic EL element of the present invention may be used for electronic device, such as display devices, displays, and various light emitting devices.

Examples of light emitting devices include, but are not limited to, lighting devices (e.g., household and in-vehicle lighting devices), backlight units of watches and liquid crystal displays, billboards, traffic signals, light sources for optical storage media, light sources for electrophotocopiers, light sources for optical communication processors, and light sources for optical sensors. In particular, the organic EL element can be effectively used for a backlight unit of a liquid crystal display device and a light source for illumination.

In the organic EL element of the present invention, the layers may optionally be patterned with a metal mask or by inkjet printing during formation of the layers. The patterning process may be performed on only the electrodes, both the electrodes and the light-emitting layer, or all the layers of the element. Any known process may be used for preparation of the element.

The color of light emitted from the organic EL element or compound according to the present invention is determined by applying values obtained with a spectroradiometer CS-1000 (manufactured by Konica Minolta Optics, Inc.) to the CIE chromaticity coordinate shown in FIG. 4.16 on page 108 of “Shinpen Shikisai Kagaku Handobukku (Handbook of Color Science, New Edition)” (edited by the Color Science Association of Japan, published from University of Tokyo Press, 1985).

The organic EL element of the present invention can be used as a white light-emitting element. In such a case, the term “white” refers to that when 2-degree viewing angle front luminance is determined by the aforementioned process, the chromaticity in the CIE 1931 Color Specification System at 1,000 cd/m² falls within a region of X=0.33±0.07 and Y=0.33±0.1.

### <Display Device>

The display device including the organic EL element of the present invention may be a monochromatic or multicolor display device. Now will be described a multicolor display device.

In the case of a multicolor display device, a shadow mask is provided only during formation of the light-emitting layer, and each of the layers may be formed over the entire surface by, for example, vacuum deposition, casting, spin coating, ink jetting, or printing.

Any process can be used for patterning of only the light-emitting layer. The patterning is preferably performed by vacuum deposition, ink jetting, spin coating, or printing.

The configuration of the organic EL element of the display device is optionally selected from the above-exemplified configurations.

The process of producing the organic EL element of the present invention is as described above in one embodiment.

If a DC voltage of about 2 to 40V is applied to the resultant multicolor display device (anode: positive electrode, cathode: negative electrode), light emission can be observed. In contrast, if a voltage is applied with reverse polarity, no current flows through the device, and light is not emitted at all. If an AC voltage is applied to the device, light is emitted only in the state where the anode is positive and the cathode is negative. The AC voltage to be applied may have any waveform.

The multicolor display device can be used for various display devices, displays or light sources. In the display device or display, full-color display is achieved with three types of organic EL elements; i.e., blue, red, and green-emitting elements.

Examples of the display device or display include television sets, personal computers, mobile devices, AV devices, teletext displays, and information displays in automobiles. In particular, the display device may be used for reproducing still images or moving images. The driving system used in the display device for reproducing moving images may be a simple matrix (passive matrix) type or an active matrix type.

Examples of the light emitting device include, but are not limited to, household lighting devices, in-vehicle lighting devices, backlight units of watches and liquid crystal displays, billboards, traffic signals, light sources for optical storage media, light sources for electrophotocopiers, light sources for optical communication processors, and light sources for optical sensors.

Now will be described an example of the display device including the organic EL element of the present invention with reference to the drawings.

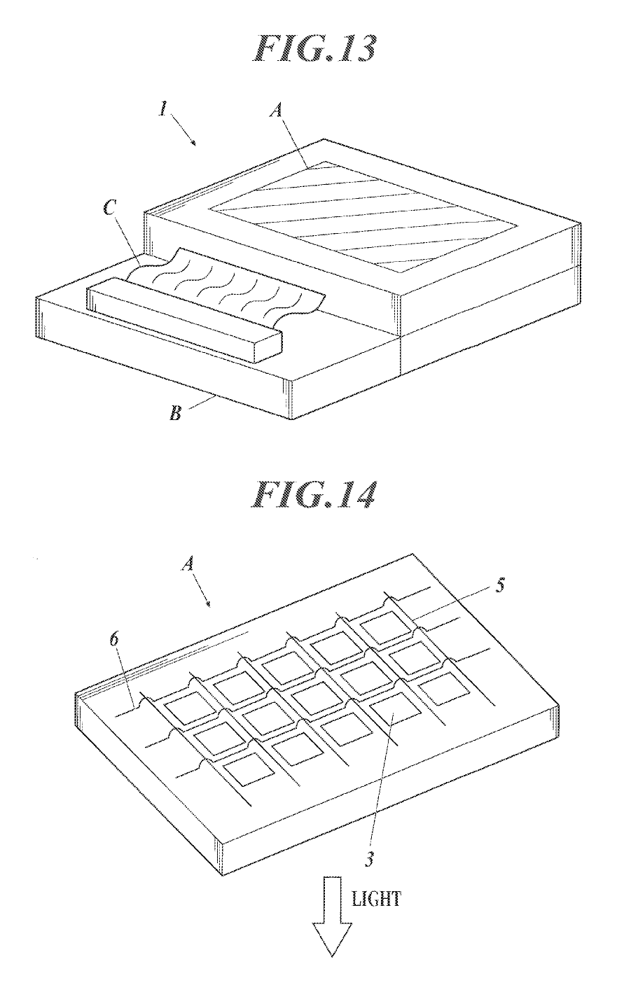

FIG. 13 is a schematic view of an exemplary display device including the organic EL element. FIG. 5 schematically illustrates a display for, for example, a mobile phone to display image information through light emission by the organic EL element.

The display 1 includes a display unit A having a plurality of pixels, a control unit B for image scanning on the display unit A on the basis of image information, and a wiring unit C which electrically connects the display unit A and the control unit B.

The control unit B, which is electrically connected to the display unit A via the wiring unit C, transmits scanning signals and image data signals to the respective pixels on the basis of external image information. The pixels in each scanning line sequentially emit light in response to the scanning signal on the basis of the image data signal to perform image scanning so that the image information is displayed on the display unit A.

FIG. 14 is a schematic view of an active matrix display device.

The display unit A has, on a substrate, a wiring unit C including a plurality of scanning lines 5 and data lines 6, and a plurality of pixels 3. The main components of the display unit A will be described below.

With reference to FIG. 14, light emitted from the pixels 3 is extracted to the direction shown by the white arrow (downward direction).

The scanning lines 5 and the data lines 6 of the wiring unit are composed of a conductive material and are orthogonal to each other to form a grid pattern. The scanning lines 5 and the data lines 6 are connected to the pixels 3 at orthogonal intersections (details are not illustrated).

If a scanning signal is applied to the scanning lines 5, the pixels 3 receive an image data signal from the data lines 6 and emit light in response to the received image data.

Full-color display is achieved by appropriately arranging red light-emitting, green light-emitting, and blue light-emitting pixels on a single substrate.

Now will be described the emission process of a pixel. FIG. 15 is a schematic view of a pixel circuit.

The pixel includes an organic EL element 10, a switching transistor 11, a driving transistor 12, and a capacitor 13. Full color display is achieved by using a plurality of pixels arranged on a single substrate, each of the pixels including red, green, and blue light-emitting organic EL elements 10.

With reference to FIG. 15, an image data signal from the control unit B is applied to the drain of the switching transistor 11 via the data line 6. If a scanning signal from the control unit B is applied to the gate of the switching transistor 11 via the scanning line 5, the switching transistor 11 is turned on, and the image data signal applied to the drain is transmitted to the gates of the capacitor 13 and the driving transistor 12.

The capacitor 13 is charged through transmission of the image data signal depending on the potential of the image data signal, and the driving transistor 12 is turned on. The drain and source of the driving transistor 12 are connected to a power source line 7 and the electrode of the organic EL element 10, respectively. Depending on the potential of the image data signal applied to the gate, a current is supplied from the power source line 7 to the organic EL element 10.

If the scanning signal is transmitted to the next scanning line 5 through sequential scanning by the control unit B, the switching transistor 11 is turned off. Because the capacitor 13 maintains the charged potential corresponding to the image data signal even after turning off of the switching transistor 11, the driving transistor 12 is maintained in an ON state, and the organic EL element continues to emit light until application of the next scanning signal. Through application of the next scanning signal by sequential scanning, the driving transistor 12 is driven depending on the potential of the subsequent image data signal in synchronization with the scanning signal, and the organic EL element 10 emits light.

To each of the organic EL elements 10 corresponding to the respective pixels 3, the switching transistor 11 and the driving transistor 12 serving as active elements are provided so that each of the organic EL elements 10 emits light. This light-emitting system is called “active matrix type.”

Multi-tone light may be emitted from the organic EL element 10 in response to multi-valued image data signals having different gradient potentials. Alternatively, light with a specific intensity from the organic EL element 10 may be turned on or off in response to a binary image data signal. The potential of the capacitor 13 may be maintained until application of the subsequent scanning signal, or the capacitor 13 may be discharged immediately before application of the subsequent scanning signal.

In the present invention, the display device may be not only of the aforementioned active matrix type, but also of a passive matrix type, in which light is emitted from the organic EL element in response to the data signal only during application of the scanning signals.

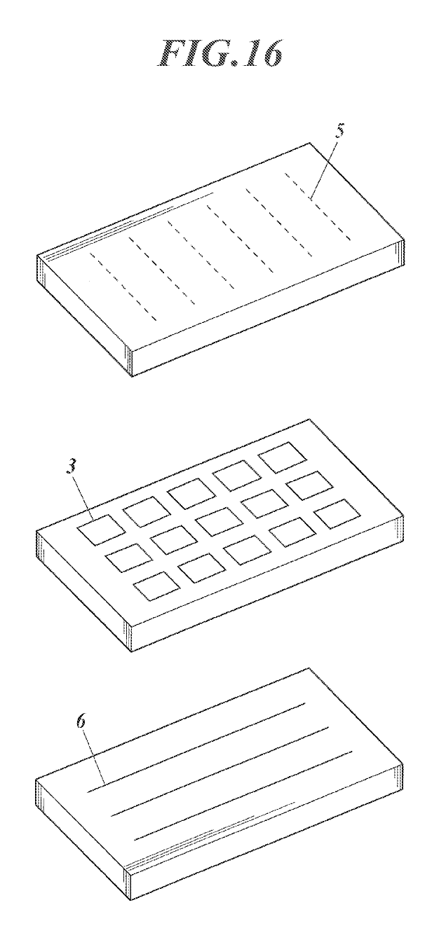

FIG. 16 is a schematic view of a passive matrix display device. With reference to FIG. 16, a plurality of scanning lines 5 and a plurality of image data lines 6 are provided with the pixels 3 disposed theirbetween to form a grid pattern.

If a scanning signal is applied to a scanning line 5 through sequential scanning, the pixel 3 connected to the scanning line 5 emits light in response to the image data signal.

The passive matrix display device can reduce production cost, because no pixel 3 includes an active element.

The use of the organic EL element of the present invention realized a display device exhibiting improved light emission efficiency.

### <Lighting Device>

The organic EL element of the present invention can be included in a lighting device.

The organic EL element of the present invention may have a resonator structure. Examples of the application of the organic EL element having a resonator structure include, but are not limited to, light sources for optical storage media, light sources for electrophotocopiers, light sources for optical communication processors, and light sources for optical sensors. Alternatively, the organic EL element of the present invention may be used for the aforementioned purposes by laser oscillation.

The organic EL element of the present invention may be used in a lamp, such as a lighting source or an exposure light source, or may be used in a projector for projecting images or a display device (display) for directly viewing still or moving images.

If the organic EL element is used in a display device for playback of moving images, the display device may be of a passive matrix type or an active matrix type. A full-color display device can be produced from two or more organic EL elements of the present invention which emits light of different colors.

The light-emitting compound used in the present invention can be applied to an organic EL element which emits substantially white light as a lighting device. For example, white light is produced by mixing light of different colors simultaneously emitted from a plurality of light-emitting materials. The combination of emission of different colors may include light of three primary colors (red, green, and blue) with three maximum emission wavelengths, or light of complementary colors (e.g., blue and yellow or blue-green and orange) with two maximum emission wavelengths.

For preparation of the organic EL element of the present invention, a mask is disposed only during formation of the light-emitting layer, the hole transporting layer, or the electron transporting layer such that a patterning process is performed simply through the mask. The other layers, which are common to one another, do not require any patterning process with a mask. Thus, an electrode film can be formed on the entire surface of such a layer through, for example, vacuum deposition, casting, spin coating, ink jetting, or printing, resulting in improved productivity.

The element produced by this process emits white light, unlike a white light-emitting organic EL device including arrayed light-emitting elements that emit light of a plurality of colors.

### [Embodiment of Lighting Device of the Present Invention]

Now will be described an embodiment of the lighting device including the organic EL element of the present invention.

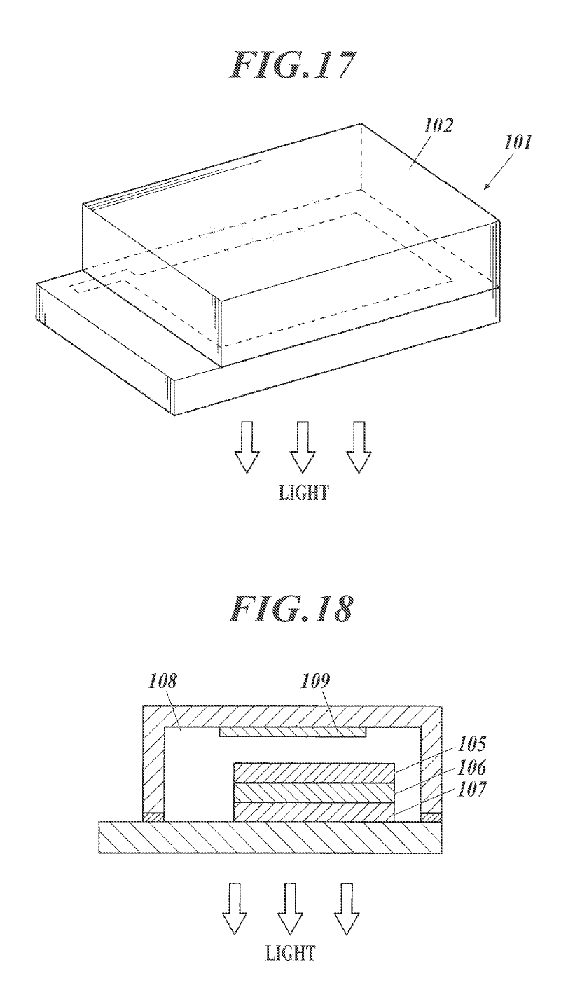

The non-light-emitting surface of the organic EL element of the present invention is covered with a glass casing, and a glass substrate having a thickness of 300 μm is used as a sealing substrate. An epoxy photocurable adhesive (LUXTRACK LC0629B, manufactured by Toagosei Co., Ltd.), serving as a sealing material, is applied to the periphery of the substrate, and the glass casing is placed from above the cathode and is attached to the transparent supporting substrate, followed by curing of the adhesive by irradiation of the glass substrate with UV rays and sealing the glass casing. A lighting device shown in FIG. 17 or 18 is thereby produced.

FIG. 17 is a schematic view of the lighting device. The organic EL element of the present invention (organic EL element 101 in the lighting device) is covered with a glass cover 102 (sealing with the glass casing is performed in a glove box under a nitrogen atmosphere (an atmosphere of nitrogen gas having a purity of 99.999% or more) for preventing the organic EL element 101 in the lighting device from being exposed to air).

FIG. 18 is a cross-sectional view of the lighting device. With reference to FIG. 18, reference numeral 105 denotes a cathode, 106 denotes an organic EL layer, and 107 denotes a glass substrate having a transparent electrode. The interior of the glass cover 102 is filled with nitrogen gas 108 and is provided with a water-collecting agent 109.

The use of the organic EL element of the present invention realized a lighting device exhibiting improved light emission efficiency.

### EXAMPLES

The present invention will now be described in detail by way of Examples, which should not be construed as limiting the invention thereto. Unless otherwise specified, the terms “part(s)” and “%” in the following description indicate “part(s) by mass” and “mass %,” respectively.

In the Examples, the vol % of a compound is determined on the basis of the thickness of a layer composed of the compound measured by a quartz crystal microbalance technique, the calculated mass of the layer, and the specific weight of the compound.

### Example 1

### Preparation of Organic El Element 29

An indium tin oxide (ITO) film having a thickness of 100 nm was deposited on a glass substrate with dimensions of 100 mm by 100 mm by 1.1 mm (NA 45 manufactured by NH Technoglass Corporation) and was patterned into an anode. The transparent support substrate provided with the transparent ITO electrode was ultrasonically cleaned in isopropyl alcohol, was dried in a dry nitrogen stream, and then was cleaned in a UV ozone environment for five minutes.

A solution of 70% poly(3,4-ethylene dioxythiophene)-poly(styrene sulfonate) (PEDOT/PSS; Baytron P Al 4083 manufactured by Bayer) in pure water was applied by spin coating on the transparent support substrate at 3,000 rpm for 30 seconds. The coating film was dried at 200° C. for one hour, to form a first hole transporting layer having a thickness of 20 nm.

The transparent support substrate was fixed to a substrate holder in a commercially available vacuum vapor deposition apparatus. α-NPD (4,4′-bis[N-(1-naphthyl)-N-phenylamino]biphenyl) (200 mg) was placed in a molybdenum resistive heating boat, SH-11 (200 mg) was placed in another molybdenum resistive heating boat, comparative compound 1 (200 mg) was placed in another molybdenum resistive heating boat, and BCP (2,9-dimethyl-4,7-diphenyl-1,10-phenanthroline) (200 mg) was placed in another molybdenum resistive heating boat. The molybdenum resistive heating boats were then placed in the vacuum vapor deposition apparatus.

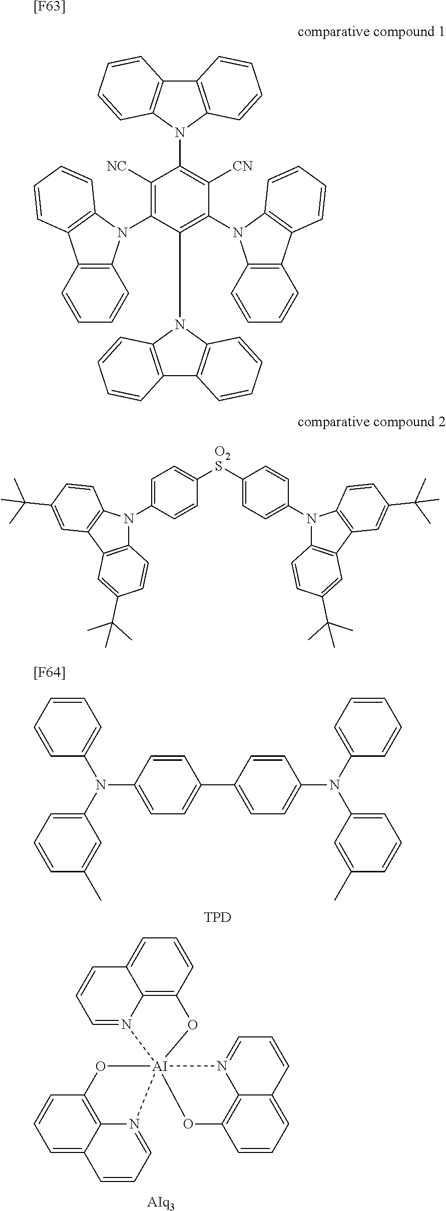

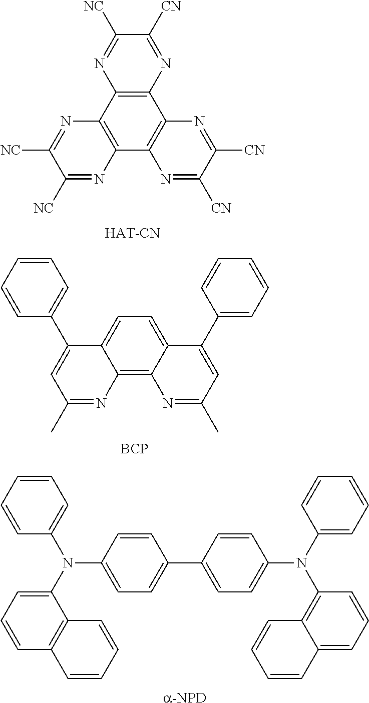

After evacuation of the vacuum vessel to 4×10⁻⁴ Pa, the heating boat containing α-NPD was electrically heated to deposit α-NPD onto the hole injecting layer at a deposition rate of 0.1 nm/second, to form a second hole transporting layer having a thickness of 30 nm.

The heating boats containing SH-11 and comparative compound 1 were electrically heated to co-deposit SH-11 and comparative compound 1 onto the hole transporting layer at deposition rates of 0.1 nm/second and 0.010 nm/second, respectively, to form a light-emitting layer having a thickness of 30 nm.

The heating boat containing BCP was then electrically heated to deposit BCP onto the hole blocking layer at a deposition rate of 0.1 nm/second, to form an electron transporting layer having a thickness of 30 nm.

Subsequently, lithium fluoride was deposited into a thickness of 0.5 nm to form a cathode buffer layer, and then aluminum was deposited into a thickness of 110 nm to form a cathode, to prepare an organic EL element 29.

### <<Preparation of Organic EL Elements 1 to 28 and 30>>

Organic EL elements 1 to 28 and 30 were prepared as in the organic EL element 29, except that SH-11 and comparative compound 1 were replaced with compounds described in Table 3.

### Example 2

Organic EL elements 31 to 60 were prepared as in the organic EL element 29 of Example 1, except that the host compound and the light-emitting compound used in the light-emitting layer were replaced with those shown in Table 4, and BCP used in the electron transporting layer was replaced with Alg₃.

### Example 3

Organic EL elements 61 to 90 were prepared as in the organic EL element 29 of Example 1, except that the host compound and the light-emitting compound used in the light-emitting layer were replaced with those shown in Table 5, and α-NPD used in the second hole transporting layer was replaced with TPD.

### Example 4

Organic EL elements 91 to 113 were prepared as in the organic EL element 29 of Example 1, except that the host compound and the light-emitting compound used in the light-emitting layer were replaced with those shown in Table 6, α-NPD used in the second hole transporting layer was replaced with TPD, and BCP used in the electron transporting layer was replaced with Alq₃.

### Example 5

### Preparation of Organic El Element 134

An indium tin oxide (ITO) film having a thickness of 100 nm was deposited on a glass substrate with dimensions of 100 mm by 100 mm by 1.1 mm (NA 45 manufactured by NH Technoglass Corporation) and was patterned into an anode. The transparent support substrate provided with the transparent ITO electrode was ultrasonically cleaned in isopropyl alcohol, was dried in a dry nitrogen stream, and then was cleaned in a UV ozone environment for five minutes.

The transparent support substrate was fixed to a substrate holder in a commercially available vacuum vapor deposition apparatus. Subsequently, molybdenum resistive heating boats respectively containing HAT-CN (200 mg), α-NPD (4,4′-bis[N-(1-naphthyl)-N-phenylamino]biphenyl) (200 mg), SH-9 (200 mg), D-15 (200 mg), and BCP (2,9-dimethyl-4,7-diphenyl-1,10-phenanthroline) (200 mg) were placed in the vacuum vapor deposition apparatus.

After evacuation of the vacuum vessel to 4×10⁻⁴ Pa, the heating boat containing HAT-CN was electrically heated to deposit HAT-CN onto the transparent support substrate provided with the transparent ITO electrode at a deposition rate of 0.1 nm/second, to form a first hole transporting layer having a thickness of 20 nm.

The heating boat containing α-NPD was electrically heated to deposit α-NPD onto the hole injecting layer at a deposition rate of 0.1 nm/second, to form a second hole transporting layer having a thickness of 30 nm.

The heating boats containing SH-9 and D-15 were electrically heated to co-deposit SH-9 and D-15 onto the second hole transporting layer at deposition rates of 0.1 nm/second and 0.010 nm/second, respectively, to form a light-emitting layer having a thickness of 30 nm.

The heating boat containing BCP was then electrically heated to deposit BCP onto the hole blocking layer at a deposition rate of 0.1 nm/second, to form an electron transporting layer having a thickness of 30 nm.

Subsequently, lithium fluoride was deposited into a thickness of 1.0 nm to form a cathode buffer layer, and then aluminum was deposited into a thickness of 110 nm to form a cathode, to prepare an organic EL element 134.

### <<Preparation of Organic EL Elements 114 to 133, 135, and 136>>

Organic EL elements 114 to 133, 135, and 136 were prepared as in the organic EL element 134, except that SH-9 and D-15 were replaced with compounds described in Table 7.

### Example 6

Organic EL elements 137 to 159 were prepared as in the organic EL element 134, except that SH-9 and D-15 were replaced with compounds described in Table 8, and BCP used in the electron transporting layer was replaced with Alq₃.

### Example 7

Organic EL elements 160 to 182 were prepared as in the organic EL element 134, except that SH-9 and D-15 were replaced with compounds described in Table 9, and α-NPD used in the second hole transporting layer was replaced with TPD.

### <<Evaluation of Light-Emitting Compounds and Organic EL Elements 1 to 182>>

### (1) Determination of Lowest Excited Singlet Energy Level S₁ of Light-Emitting Compound

The emission spectrum of a solution of a light-emitting compound (solvent: dichloromethane) was measured at room temperature (25° C.) with a fluorescent spectrometer (F-4500 fluorescent spectrometer manufactured by Hitachi, Ltd.), and the energy level corresponding to the maximum emission wavelength was determined as the lowest excited singlet energy level S₁ of the compound.

### (2) Determination of Stokes Shift of Light-Emitting Compound

The excitation (absorption) spectrum and emission spectrum of a solution of a light-emitting compound (solvent: dichloromethane) were measured at room temperature (25° C.) with a fluorescent spectrometer (F-4500 fluorescent spectrometer manufactured by Hitachi, Ltd.), and the energy corresponding to the difference between the maximum fluorescence wavelength and the maximum excitation (absorption) wavelength was determined as the “Stokes shift.”

TABLE 2

| Light-emitting compound | Singlet energy level (eV) | Stokes shift (eV) |
|---|---|---|
| D-1 | 2.67 | 0.21 |
| D-2 | 3.37 | 0.24 |
| D-3 | 3.54 | 0.09 |
| D-4 | 3.88 | 0.11 |
| D-5 | 3.51 | 0.10 |
| D-6 | 3.14 | 0.24 |
| D-7 | 2.88 | 0.23 |
| D-8 | 2.92 | 0.24 |
| D-9 | 3.01 | 0.15 |
| D-10 | 2.89 | 0.18 |
| D-11 | 2.71 | 0.24 |
| D-12 | 3.41 | 0.09 |
| D-13 | 3.44 | 0.08 |
| D-14 | 3.25 | 0.12 |
| D-15 | 3.24 | 0.11 |
| D-16 | 3.50 | 0.12 |
| D-17 | 3.37 | 0.11 |
| D-18 | 3.47 | 0.09 |
| D-19 | 3.46 | 0.12 |
| D-20 | 3.60 | 0.12 |
| D-21 | 3.80 | 0.11 |
| D-22 | 3.43 | 0.08 |
| D-23 | 3.40 | 0.11 |
| D-24 | 3.44 | 0.12 |
| D-25 | 3.22 | 0.12 |
| D-26 | 3.30 | 0.09 |
| D-27 | 3.60 | 0.11 |
| D-28 | 3.45 | 0.12 |
| Comparative compound 1 | 2.89 | 0.46 |
| Comparative compound 2 | 3.30 | 0.54 |

The results shown in Table 2 demonstrate that light-emitting compounds D-1 to D-28 according to the present invention have a singlet energy level of 2.64 eV or more and a Stokes shift of 0.24 eV or less.

### (3) Variation in Resistance and Percent Retention of Light Emission Efficiency.

For evaluation of the resultant organic EL elements, lighting devices shown in FIGS. 17 and 18 were produced with the organic EL elements, and the light-emitting layers were analyzed for a variation in resistance and light emission efficiency with an impedance spectrometer.

FIG. 17 is a schematic view of a lighting device. The organic EL element of the present invention (the organic EL element 101 in the lighting device) is covered with a glass casing 102 (sealing with the glass casing 102 was performed under a high-purity (99.999% or higher) nitrogen gas atmosphere in a glovebox to avoid exposure of the organic EL element 101 to the air). Specifically, an epoxy photocurable adhesive (LUXTRACK LC0629B, manufactured by Toagosei Co., LTD.) as a sealant was applied onto the position where the glass casing is in contact with the glass substrate provided with the organic EL element, i.e. the periphery of the glass casing. The glass casing was attached on the transparent support substrate to cover the cathode. The adhesive was then cured by irradiation with UV light incident on the glass substrate (except for the organic EL device) to seal the periphery.

FIG. 18 is a cross-sectional view of the lighting device. With reference to FIG. 18, the lighting device includes a cathode 105, an organic EL layer 106, and a glass substrate 107 provided with a transparent electrode. The interior of the glass casing 102 is filled with nitrogen gas 108 and is provided with a water-collecting agent 109.

(3-1) Variation in Resistance after Driving of Organic EL Element

Each of the organic EL elements prepared as described above was subjected to measurement of the resistance of the light-emitting layer at a bias voltage of 1 V with Solartron Impedance Analyzer 1260 and Solartron 1296 dielectric interface (manufactured by Solartron) in accordance with the method described in “Hakumaku no Hyoka Handobukku (Handbook of Thin Film Characterization Technology)” (published by Technosystem Co., Ltd., pp. 423 to 425).

Specifically, each of the organic EL elements was driven for 1,000 hours under a constant current density of 2.5 mA/cm² at room temperature (25° C.), and was subjected to measurement of the resistance of the light-emitting layer before and after the driving of the element. On the basis of the results of measurement, a variation in resistance was calculated for the organic EL element by the expression described below. Tables show the variation in resistance of the organic EL element as a relative value to that (taken as 100) of the comparative organic EL element.

Variation in resistance between before and after the driving=|(resistance after the driving)/(resistance before the driving)−1|×100

A value near to zero indicates a small variation in resistance between before and after the driving

A smaller value indicates a smaller variation in resistivity of the thin film over time.

(3-2) Percent Retention of Light Emission Efficiency after Driving of Organic EL Element

For evaluation of the light emission efficiency of an organic EL element, the organic EL element was driven at room temperature (25° C.) under a constant current density of 2.5 mA/cm², and the external quantum efficiency (%) of the element was measured with a spectroradiometer CS-1000 (manufactured by Konica Minolta, Inc.). The external quantum efficiency (%) was used as an index for light emission efficiency. The external quantum efficiency was measured immediately after preparation of the organic EL element and after 1,000-hour driving of the element, to determine the percent retention of light emission efficiency.

The percent retention of light emission efficiency is represented as a relative value to that (taken as 100) of a comparative element determined after driving. Thus, a larger relative value indicates a smaller variation in light emission efficiency over time. For example, if the comparative organic EL element has a percent retention of light emission efficiency of 40% to the initial value, the organic EL element having a percent retention of light emission efficiency of 100% to the initial value is defined as having a relative value of 250.

TABLE 3

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 1 | D-1 | SH-11 | 89 | 125 | Inventive |
| 2 | D-2 | SH-11 | 97 | 109 | Inventive |
| 3 | D-3 | SH-11 | 68 | 169 | Inventive |
| 4 | D-4 | SH-11 | 70 | 159 | Inventive |
| 5 | D-5 | SH-11 | 70 | 169 | Inventive |
| 6 | D-6 | SH-11 | 81 | 144 | Inventive |
| 7 | D-7 | SH-11 | 82 | 134 | Inventive |
| 8 | D-8 | SH-11 | 73 | 159 | Inventive |
| 9 | D-9 | SH-11 | 74 | 163 | Inventive |
| 10 | D-10 | SH-11 | 71 | 163 | Inventive |
| 11 | D-11 | SH-11 | 80 | 144 | Inventive |
| 12 | D-12 | SH-11 | 44 | 222 | Inventive |
| 13 | D-13 | SH-11 | 40 | 225 | Inventive |
| 14 | D-14 | SH-11 | 51 | 203 | Inventive |
| 15 | D-15 | SH-11 | 50 | 206 | Inventive |
| 16 | D-16 | SH-11 | 52 | 200 | Inventive |
| 17 | D-17 | SH-11 | 36 | 241 | Inventive |
| 18 | D-18 | SH-11 | 30 | 253 | Inventive |
| 19 | D-19 | SH-11 | 41 | 231 | Inventive |
| 20 | D-20 | SH-11 | 44 | 222 | Inventive |
| 21 | D-21 | SH-11 | 32 | 250 | Inventive |
| 22 | D-22 | SH-11 | 29 | 259 | Inventive |
| 23 | D-23 | SH-11 | 33 | 247 | Inventive |
| 24 | D-24 | SH-11 | 32 | 250 | Inventive |
| 25 | D-25 | SH-11 | 33 | 253 | Inventive |
| 26 | D-26 | SH-11 | 30 | 263 | Inventive |
| 27 | D-27 | SH-11 | 35 | 250 | Inventive |
| 28 | D-28 | SH-11 | 36 | 247 | Inventive |
| 29 | Comparative | SH-11 | 100 | 100 | Comparative |
| | compound 1 | | | | |
| 30 | Comparative | SH-11 | 240 | 44 | Comparative |
| | compound 2 | | | | |

TABLE 4

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 31 | D-1 | H-233 | 82 | 111 | Inventive |
| 32 | D-2 | H-233 | 89 | 108 | Inventive |
| 33 | D-3 | H-233 | 64 | 159 | Inventive |
| 34 | D-4 | H-233 | 64 | 159 | Inventive |
| 35 | D-5 | H-233 | 61 | 181 | Inventive |
| 36 | D-6 | H-233 | 71 | 141 | Inventive |
| 37 | D-7 | H-233 | 71 | 144 | Inventive |
| 38 | D-8 | H-233 | 64 | 159 | Inventive |
| 39 | D-9 | H-233 | 64 | 156 | Inventive |
| 40 | D-10 | H-233 | 63 | 163 | Inventive |
| 41 | D-11 | H-233 | 74 | 133 | Inventive |
| 42 | D-12 | H-233 | 40 | 233 | Inventive |
| 43 | D-13 | H-233 | 37 | 241 | Inventive |
| 44 | D-14 | H-233 | 44 | 226 | Inventive |
| 45 | D-15 | H-233 | 46 | 219 | Inventive |
| 46 | D-16 | H-233 | 45 | 222 | Inventive |
| 47 | D-17 | H-233 | 30 | 263 | Inventive |
| 48 | D-18 | H-233 | 29 | 267 | Inventive |
| 49 | D-19 | H-233 | 35 | 259 | Inventive |
| 50 | D-20 | H-233 | 44 | 230 | Inventive |
| 51 | D-21 | H-233 | 32 | 256 | Inventive |
| 52 | D-22 | H-233 | 28 | 274 | Inventive |
| 53 | D-23 | H-233 | 32 | 259 | Inventive |
| 54 | D-24 | H-233 | 32 | 256 | Inventive |
| 55 | D-25 | H-233 | 31 | 252 | Inventive |
| 56 | D-26 | H-233 | 29 | 270 | Inventive |
| 57 | D-27 | H-233 | 31 | 256 | Inventive |
| 58 | D-28 | H-233 | 32 | 248 | Inventive |
| 59 | Comparative | H-233 | 100 | 100 | Comparative |
| | compound 1 | | | | |
| 60 | Comparative | H-233 | 245 | 30 | Comparative |
| | compound 2 | | | | |

TABLE 5

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 61 | D-1 | SH-10 | 88 | 109 | Inventive |
| 62 | D-2 | SH-10 | 91 | 105 | Inventive |
| 63 | D-3 | SH-10 | 56 | 135 | Inventive |
| 64 | D-4 | SH-10 | 61 | 137 | Inventive |
| 65 | D-5 | SH-10 | 58 | 135 | Inventive |
| 66 | D-6 | SH-10 | 71 | 121 | Inventive |
| 67 | D-7 | SH-10 | 72 | 125 | Inventive |
| 68 | D-8 | SH-10 | 65 | 130 | Inventive |
| 69 | D-9 | SH-10 | 64 | 133 | Inventive |
| 70 | D-10 | SH-10 | 65 | 132 | Inventive |
| 71 | D-11 | SH-10 | 71 | 125 | Inventive |
| 72 | D-12 | SH-10 | 36 | 146 | Inventive |
| 73 | D-13 | SH-10 | 33 | 151 | Inventive |
| 74 | D-14 | SH-10 | 40 | 140 | Inventive |
| 75 | D-15 | SH-10 | 29 | 158 | Inventive |
| 76 | D-16 | SH-10 | 30 | 146 | Inventive |
| 77 | D-17 | SH-10 | 27 | 149 | Inventive |
| 78 | D-18 | SH-10 | 21 | 160 | Inventive |
| 79 | D-19 | SH-10 | 30 | 153 | Inventive |
| 80 | D-20 | SH-10 | 37 | 142 | Inventive |
| 81 | D-21 | SH-10 | 23 | 156 | Inventive |
| 82 | D-22 | SH-10 | 20 | 165 | Inventive |
| 83 | D-23 | SH-10 | 25 | 154 | Inventive |
| 84 | D-24 | SH-10 | 22 | 161 | Inventive |
| 85 | D-25 | SH-10 | 24 | 156 | Inventive |
| 86 | D-26 | SH-10 | 26 | 161 | Inventive |
| 87 | D-27 | SH-10 | 23 | 158 | Inventive |
| 88 | D-28 | SH-10 | 24 | 154 | Inventive |
| 89 | Comparative | SH-10 | 100 | 100 | Comparative |
| | compound 1 | | | | |
| 90 | Comparative | SH-10 | 322 | 39 | Comparative |
| | compound 2 | | | | |

TABLE 6

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 91 | D-8 | H-4 | 54 | 225 | Inventive |
| 92 | D-8 | H-22 | 60 | 215 | Inventive |
| 93 | D-8 | H-10 | 47 | 239 | Inventive |
| 94 | D-8 | H-13 | 46 | 234 | Inventive |
| 95 | D-8 | H-24 | 45 | 235 | Inventive |
| 96 | D-8 | H-231 | 43 | 242 | Inventive |
| 97 | D-8 | H-26 | 48 | 228 | Inventive |
| 98 | D-8 | H-76 | 40 | 247 | Inventive |
| 99 | D-8 | H-232 | 47 | 233 | Inventive |
| 100 | D-8 | H-18 | 49 | 232 | Inventive |
| 101 | D-8 | H-46 | 40 | 247 | Inventive |
| 102 | D-8 | H-78 | 35 | 257 | Inventive |
| 103 | D-8 | SH-1 | 38 | 240 | Inventive |
| 104 | D-8 | SH-2 | 35 | 256 | Inventive |
| 105 | D-8 | SH-3 | 40 | 250 | Inventive |
| 106 | D-8 | SH-4 | 35 | 251 | Inventive |
| 107 | D-8 | SH-5 | 31 | 259 | Inventive |
| 108 | D-8 | SH-6 | 28 | 261 | Inventive |
| 109 | D-8 | SH-7 | 23 | 271 | Inventive |
| 110 | D-8 | SH-8 | 31 | 260 | Inventive |
| 111 | D-8 | SH-9 | 27 | 260 | Inventive |
| 112 | D-8 | H-1 | 75 | 148 | Inventive |
| 113 | Comparative | H-1 | 100 | 100 | Comparative |
| | compound 1 | | | | |

TABLE 7

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 114 | D-15 | H-4 | 37 | 367 | Inventive |
| 115 | D-15 | H-22 | 38 | 374 | Inventive |
| 116 | D-15 | H-10 | 32 | 374 | Inventive |
| 117 | D-15 | H-13 | 33 | 372 | Inventive |
| 118 | D-15 | H-24 | 37 | 367 | Inventive |
| 119 | D-15 | H-231 | 31 | 371 | Inventive |
| 120 | D-15 | H-26 | 32 | 382 | Inventive |
| 121 | D-15 | H-76 | 24 | 381 | Inventive |
| 122 | D-15 | H-232 | 33 | 376 | Inventive |
| 123 | D-15 | H-18 | 39 | 372 | Inventive |
| 124 | D-15 | H-46 | 25 | 379 | Inventive |
| 125 | D-15 | H-78 | 22 | 393 | Inventive |
| 126 | D-15 | SH-1 | 23 | 395 | Inventive |
| 127 | D-15 | SH-2 | 22 | 384 | Inventive |
| 128 | D-15 | SH-3 | 25 | 388 | Inventive |
| 129 | D-15 | SH-4 | 22 | 397 | Inventive |
| 130 | D-15 | SH-5 | 21 | 386 | Inventive |
| 131 | D-15 | SH-6 | 18 | 398 | Inventive |
| 132 | D-15 | SH-7 | 16 | 405 | Inventive |
| 133 | D-15 | SH-8 | 21 | 390 | Inventive |
| 134 | D-15 | SH-9 | 16 | 397 | Inventive |
| 135 | D-15 | H-233 | 51 | 275 | Inventive |
| 136 | Comparative | H-233 | 100 | 100 | Comparative |
| | compound 2 | | | | |

TABLE 8

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 137 | D-26 | SH-4 | 47 | 313 | Inventive |
| 138 | D-26 | SH-22 | 53 | 312 | Inventive |
| 139 | D-26 | SH-10 | 42 | 324 | Inventive |
| 140 | D-26 | SH-13 | 40 | 322 | Inventive |
| 141 | D-26 | SH-24 | 42 | 313 | Inventive |
| 142 | D-26 | SH-231 | 40 | 322 | Inventive |
| 143 | D-26 | SH-26 | 44 | 315 | Inventive |
| 144 | D-26 | SH-76 | 35 | 326 | Inventive |
| 145 | D-26 | SH-232 | 40 | 315 | Inventive |
| 146 | D-26 | SH-18 | 44 | 312 | Inventive |
| 147 | D-26 | SH-46 | 36 | 331 | Inventive |
| 148 | D-26 | SH-78 | 31 | 318 | Inventive |
| 149 | D-26 | SH-1 | 35 | 319 | Inventive |
| 150 | D-26 | SH-2 | 31 | 328 | Inventive |
| 151 | D-26 | SH-3 | 35 | 329 | Inventive |
| 152 | D-26 | SH-4 | 31 | 328 | Inventive |
| 153 | D-26 | SH-5 | 29 | 326 | Inventive |
| 154 | D-26 | SH-6 | 25 | 339 | Inventive |
| 155 | D-26 | SH-7 | 22 | 335 | Inventive |
| 156 | D-26 | SH-8 | 27 | 328 | Inventive |
| 157 | D-26 | SH-9 | 22 | 332 | Inventive |
| 158 | D-26 | H-1 | 68 | 276 | Inventive |
| 159 | Comparative | H-1 | 100 | 100 | Comparative |
| | compound 2 | | | | |

TABLE 9

| | | | | Percent | |
|---|---|---|---|---|---|
| | | | | retention | |
| Ele- | | | Variation in | of emission | |
| ment | Light- | Host | resistance | efficiency | |
| num- | emitting | com- | (relative | (relative | |
| ber | compound | pound | value) | value) | Note |
| 160 | D-27 | H-4 | 41 | 292 | Inventive |
| 161 | D-27 | H-22 | 44 | 285 | Inventive |
| 162 | D-27 | H-10 | 39 | 292 | Inventive |
| 163 | D-27 | H-13 | 36 | 301 | Inventive |
| 164 | D-27 | H-24 | 37 | 298 | Inventive |
| 165 | D-27 | H-231 | 37 | 301 | Inventive |
| 166 | D-27 | H-26 | 41 | 298 | Inventive |
| 167 | D-27 | H-76 | 34 | 301 | Inventive |
| 168 | D-27 | H-232 | 36 | 298 | Inventive |
| 169 | D-27 | H-18 | 37 | 292 | Inventive |
| 170 | D-27 | H-46 | 31 | 298 | Inventive |
| 171 | D-27 | H-78 | 31 | 292 | Inventive |
| 172 | D-27 | SH-1 | 32 | 298 | Inventive |
| 173 | D-27 | SH-2 | 31 | 305 | Inventive |
| 174 | D-27 | SH-3 | 31 | 301 | Inventive |
| 175 | D-27 | SH-4 | 27 | 301 | Inventive |
| 176 | D-27 | SH-5 | 27 | 305 | Inventive |
| 177 | D-27 | SH-6 | 24 | 311 | Inventive |
| 178 | D-27 | SH-7 | 20 | 311 | Inventive |
| 179 | D-27 | SH-8 | 24 | 308 | Inventive |
| 180 | D-27 | SH-9 | 22 | 305 | Inventive |
| 181 | D-27 | H-233 | 72 | 253 | Inventive |
| 182 | Comparative | H-233 | 100 | 100 | Comparative |
| | compound 1 | | | | |

The results in Table 3 demonstrate that the organic EL element containing each of light-emitting compounds D-1 to D-28 according to the present invention and host compound SH-11 (H-159) having a carbazole structure exhibits a small variation in resistance of the light-emitting layer after application of voltage (i.e., a small variation in properties of the thin light-emitting layer) as compared to that containing comparative compound 1 or 2. The results in Table 3 also demonstrate that the organic EL element containing each of light-emitting compounds D-1 to D-28 according to the present invention and host compound SH-11 having a carbazole structure exhibits a high percent retention of light emission efficiency after application of voltage as compared to that containing comparative compound 1 or 2; i.e., the light-emitting compound of the present invention is effective for an improvement in service life of the organic EL element.

The results in Table 4 demonstrate that the organic EL element containing each of light-emitting compounds D-1 to D-28 according to the present invention and host compound H-233 having no carbazole structure exhibits a small variation in resistance of the light-emitting layer after application of voltage (i.e., a small variation in properties of the thin light-emitting layer) as compared to that containing comparative compound 1 or 2. The results in Table 4 also demonstrate that the organic EL element containing each of light-emitting compounds D-1 to D-28 according to the present invention and host compound H-233 having no carbazole structure exhibits a high percent retention of light emission efficiency after application of voltage as compared to that containing comparative compound 1 or 2; i.e., the light-emitting compound of the present invention is effective for an improvement in service life of the organic EL element.

The results in Table 5 demonstrate that the organic EL element containing each of light-emitting compounds D-1 to D-28 according to the present invention and host compound SH-10 having a carbazole structure exhibits a small variation in resistance of the light-emitting layer after application of voltage (i.e., a small variation in properties of the thin light-emitting layer) as compared to that containing comparative compound 1 or 2. The results in Table 5 also demonstrate that the organic EL element containing each of light-emitting compounds D-1 to D-28 according to the present invention and host compound SH-10 having a carbazole structure exhibits a high percent retention of light emission efficiency after application of voltage as compared to that containing comparative compound 1 or 2; i.e., the light-emitting compound of the present invention is effective for an improvement in service life of the organic EL element.

The results in Table 6 demonstrate that the organic EL element containing light-emitting compound D-8 according to the present invention in combination with each of host compounds SH-1 to SH-9, H-4, H-10, H-13, H-22, H-24, H-26, H-46, H-76, H-78, H-231, and H-232 having a carbazole structure exhibits a small variation in resistance of the light-emitting layer after application of voltage as compared to that containing the light-emitting compound in combination with host compound H-1 having no carbazole structure. The results demonstrate that the organic EL element containing a host compound having a carbazole structure exhibits a small variation in properties of the thin light-emitting layer. The results in Table 6 also demonstrate that the organic EL element containing light-emitting compound D-8 according to the present invention in combination with host compound H-1 having no carbazole structure exhibits a small variation in resistance of the light-emitting layer after application of voltage as compared to that containing comparative compound 1 in combination with host compound H-1. Thus, the light-emitting compound according to the present invention is effective for an improvement in service life of the organic EL element containing a host compound having no carbazole structure.

The results in Table 6 also demonstrate that the organic EL element containing light-emitting compound D-8 according to the present invention in combination with each of host compounds SH-1 to SH-9, H-4, H-10, H-13, H-22, H-24, H-26, H-46, H-76, H-78, H-231, and H-232 having a carbazole structure exhibits a high percent retention of light emission efficiency after application of voltage as compared to that containing the light-emitting compound in combination with host compound H-1 having no carbazole structure. The results demonstrate that the organic EL element containing a host compound having a carbazole structure exhibits a small variation in properties of the thin light-emitting layer. The results in Table 6 also demonstrate that the organic EL element containing light-emitting compound D-8 according to the present invention in combination with host compound H-1 having no carbazole structure exhibits a high percent retention of light emission efficiency after application of voltage as compared to that containing comparative compound 1 in combination with host compound H-1. Thus, the light-emitting compound according to the present invention is effective for an improvement in service life of the organic EL element containing a host compound having no carbazole structure.

The results in Table 7 demonstrate that the organic EL element containing light-emitting compound D-15 according to the present invention in combination with each of host compounds SH-1 to SH-9, H-4, H-10, H-13, H-22, H-24, H-26, H-46, H-76, H-78, H-231, and H-232 having a carbazole structure exhibits a small variation in resistance of the light-emitting layer and a high percent retention of light emission efficiency after application of voltage as compared to that containing the light-emitting compound in combination with host compound H-233 having no carbazole structure. The results demonstrate that the organic EL element containing a host compound having a carbazole structure exhibits a small variation in properties of the thin light-emitting layer. The results in Table 7 also demonstrate that the organic EL element containing light-emitting compound D-15 according to the present invention in combination with host compound H-233 having no carbazole structure exhibits a small variation in resistance of the light-emitting layer and a high percent retention of light emission efficiency after application of voltage as compared to that containing comparative compound 2 in combination with host compound H-233. Thus, the light-emitting compound according to the present invention is effective for an improvement in service life of the organic EL element containing a host compound having no carbazole structure.

The results in Table 8 demonstrate that the organic EL element containing light-emitting compound D-26 according to the present invention in combination with each of host compounds SH-1 to SH-9, H-4, H-10, H-13, H-22, H-24, H-26, H-46, H-76, H-78, H-231, and H-232 having a carbazole structure exhibits a small variation in resistance of the light-emitting layer and a high percent retention of light emission efficiency after application of voltage as compared to that containing the light-emitting compound in combination with host compound H-1 having no carbazole structure. The results demonstrate that the organic EL element containing a host compound having a carbazole structure exhibits a small variation in properties of the thin light-emitting layer. The results in Table 8 also demonstrate that the organic EL element containing light-emitting compound D-26 according to the present invention in combination with host compound H-1 having no carbazole structure exhibits a small variation in resistance of the light-emitting layer and a high percent retention of light emission efficiency after application of voltage as compared to that containing comparative compound 2 in combination with host compound H-1. Thus, the light-emitting compound according to the present invention is effective for an improvement in service life of the organic EL element containing a host compound having no carbazole structure.

The results in Table 9 demonstrate that the organic EL element containing light-emitting compound D-27 according to the present invention in combination with each of host compounds SH-1 to SH-9, H-4, H-10, H-13, H-22, H-24, H-26, H-46, H-76, H-78, H-231, and H-232 having a carbazole structure exhibits a small variation in resistance of the light-emitting layer and a high percent retention of light emission efficiency after application of voltage as compared to that containing the light-emitting compound in combination with host compound H-233 having no carbazole structure. The results demonstrate that the organic EL element containing a host compound having a carbazole structure exhibits a small variation in properties of the thin light-emitting layer. The results in Table 9 also demonstrate that the organic EL element containing light-emitting compound D-27 according to the present invention in combination with host compound H-233 having no carbazole structure exhibits a small variation in resistance of the light-emitting layer and a high percent retention of light emission efficiency after application of voltage as compared to that containing comparative compound 1 in combination with host compound H-233. Thus, the light-emitting compound according to the present invention is effective for an improvement in service life of the organic EL element containing a host compound having no carbazole structure.

As described above, the organic EL elements containing light-emitting compounds D-1 to D-28 according to the present invention exhibited a small variation in properties of the light-emitting layer after long-term application of voltage and maintained high light emission efficiency.

This is probably attributed to the fact that the high rigidity of light-emitting compounds D-1 to D-28 according to the present invention inhibits molecular motion during application of voltage, resulting in an improvement in morphological stability of the thin film. Compounds D-1 to D-28 exhibit reduced intermolecular interaction (e.g., π-stacking) because of non-planar molecular structure. Thus, appropriate dispersion of such a light-emitting compound in the thin film probably leads to prevention of localization of excitons during application of voltage, resulting in an improvement in stability of the thin film.

Furthermore, combination of the light-emitting compound according to the present invention with a host compound having a carbazole structure achieved a small variation in properties of the thin film and a high percent retention of light emission efficiency.

This is probably attributed to the fact that a large π-electron conjugated system of the host compound having a carbazole structure causes appropriate dispersion of the light-emitting compound, which also has a π-electron conjugated system, in the light-emitting layer and appropriate electron hopping, resulting in delocalization of excitons and improved stability of the thin film during application of voltage.

Furthermore, combination of the light-emitting compound according to the present invention with a host compound having a carbazole structure achieved a small variation in properties of the thin film and a high percent retention of light emission efficiency.

This is probably attributed to the fact that a large π-electron conjugated system of the host compound having a carbazole structure causes appropriate dispersion of the light-emitting compound, which also has a π-electron conjugated system, in the light-emitting layer and appropriate electron hopping, resulting in delocalization of excitons and improved stability of the thin film during application of voltage.

In the present invention, a change in state of the thin charge transporting film is analyzed by impedance spectroscopy (i.e., a new non-destructive analytical technique), and the phenomenon occurring in the practical device can be represented as a resistance of the light-emitting layer by the technique. The light-emitting layer of the organic EL element of the present invention, which contains a blue light-emitting compound having a small Stokes shift in combination with a host compound having a specific carbazole structure (i.e., the technique concept of the present invention), exhibits a variation in resistance which is significantly smaller than that of the light-emitting layer of a comparative organic EL element. Thus, the technique is adequate for evaluating the phenomenon occurring in the practical device, although the degree of error in this new technique has not been specified.

A short service life of an organic EL element including a thin charge transporting film is an obstacle for practical use of the element. In an extreme case, a short service life of the element is caused only by a variation in resistance of the thin charge transporting film. A variation in resistance can quantitatively represent all phenomena in the thin film, including decomposition of the compound, a variation in molecular cohesion, a variation in shape or size of crystal grains, and a variation in state of different molecules (interaction between the molecules). Impedance spectroscopy can non-destructively detect a variation in resistance of only a specific film among the films forming an organic EL element. Unlike a conventional technique, this new technique has an advantage in that it can specify a substance or moiety that affects the service life of the element, and is effective in taking specific measures for improving the performance of the element.

The organic EL element of the present invention includes a light-emitting layer containing, as a light-emitting material, a compound having a small Stokes shift and thus a small change in molecular structure during excitation, and also containing an appropriate host compound used in combination with the light-emitting material. Thus, the present invention provides a breakthrough technique that can improve the state of dispersion of the light-emitting material and the carrier hopping properties of the light-emitting layer, and that can provide a thin film with high robustness or resistance against various external factors, such as current, heat, and light. This sophisticated and versatile technique, which is applied to the embodiments described above, can be universally applied to films and bodies through which charges migrate or current flows, and the technique certainly contributes to the future development of organic electronics.

### INDUSTRIAL APPLICABILITY

The present invention can provide an organic electroluminescent element which emits blue light with high chromaticity and which exhibits high light emission efficiency over a long period of time. The organic EL element can be suitably used for display devices, displays, household lighting devices, in-vehicle lighting devices, backlight units of watches and liquid crystal displays, billboards, traffic signals, light sources for optical storage media, light sources for electrophotocopiers, light sources for optical communication processors, light sources for optical sensors, and light sources for, for example, common household electric appliances requiring display devices.

### REFERENCE SIGNS LIST

1: display
3: pixel
5: scanning line
6: data line
7: power source line
10: organic EL element
11: switching transistor
12: driving transistor
13: capacitor
101: organic EL element in lighting device
102: glass casing
105: cathode
106: organic EL layer
107: glass substrate having transparent electrode
108: nitrogen gas
109: water-collecting agent
A: display unit
B: control unit
C: wiring unit

1. An organic electroluminescent element comprising:
an anode;
a cathode; and
at least one organic layer disposed between the anode and the cathode, the organic layer comprising a light-emitting layer,
wherein the light-emitting layer contains a light-emitting compound having a Stokes shift of 0 to 0.24 eV and a lowest excited singlet energy level S₁ of 2.64 eV or more.

2. The organic electroluminescent element according to claim 1, wherein the light-emitting compound has a structure represented by Formula (1): 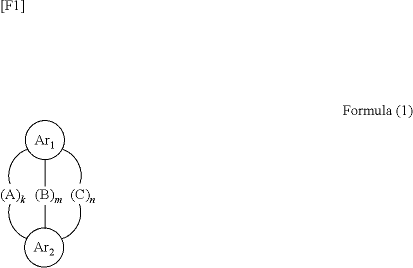
wherein A, B, and C each independently represent a single bond or a linking group containing a carbon, silicon, or oxygen atom; Ar₁ and Ar₂ each independently represent an aromatic hydrocarbon or heterocyclic group optionally having a condensed ring structure; Ar₁ and Ar₂ are optionally identical to each other; k represents a natural number and if k is 2 or more, the groups A are optionally different from one another; m is 0 or a natural number and if m is 2 or more, the groups B are optionally different from one another; n is 0 or a natural number and if n is 2 or more, the groups C are optionally different from one another; and each of A, B, and C independently optionally links Ar₁ and Ar₂ with a single bond or through formation of a condensed ring.

3. The organic electroluminescent element according to claim 1, wherein the light-emitting compound has a non-planar electronic conjugated structure.

4. The organic electroluminescent element according to claim 1, wherein the light-emitting compound has a structure represented by Formula (2): 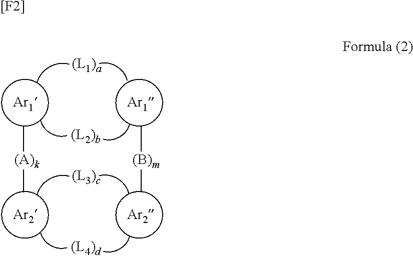
wherein Ar₁′, Ar₁″, Ar₂′, and Ar₂″ are optionally identical to or different from one another and each independently represent an aromatic hydrocarbon or heterocyclic group optionally having a condensed ring structure and a substituent; Ar₁′ and Ar₁″ optionally form a condensed ring, and Ar₂′ and Ar₂″ optionally form a condensed ring; a, b, c, and d each represent 0 or a natural number; a or b represents a natural number; c or d represents a natural number; L₁ and L₂ each represent a single bond or divalent linking group that links Ar₁′ and Ar₁″; Ar₁′ and Ar₁″ optionally form a condensed ring with L₁ and L₂; L₃ and L₄ each represent a single bond or divalent linking group that links Ar₂′ and Ar₂″; Ar₂′ and Ar₂″ optionally form a condensed ring with L₃ and L₄; if a, b, c, or d is 2 or more, the groups L₁, L₂, L₃, or L₄ are optionally identical to or different from one another; k and m each represent 0 or a natural number; k or m represents a natural number; A and B each represent a single bond or a divalent linking group; if k or m is 2 or more, the groups A or B are optionally identical to or different from one another; and Ar₁′, Ar₂′, and A optionally form a condensed ring, and Ar₁″, Ar₂″, and B optionally form a condensed ring.

5. The organic electroluminescent element according to claim 1, wherein the light-emitting compound has a structure represented by Formula (3): 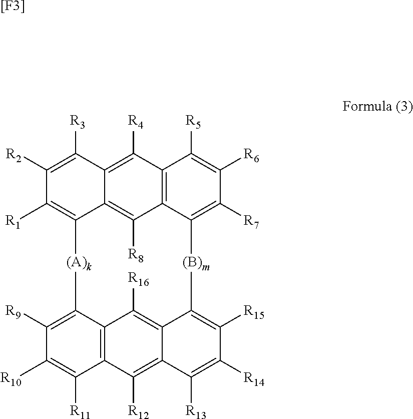
wherein A and B each independently represent a single bond or a linking group containing a carbon or silicon atom; two anthracene rings linked by A and/or B optionally form a condensed ring with R₁, R₉, and A or with R₇, R₁₅, and B; k represents a natural number and if k is 2 or more, the groups A are optionally different from one another; R₁ to R₁₆ each represent a substituted or unsubstituted aliphatic hydrocarbon group or a substituted or unsubstituted aromatic hydrocarbon group, and optionally form a ring; each of R₁ to R₁₆ is optionally a heteroaromatic hydrocarbon group containing a nitrogen, oxygen, or sulfur atom; m represents 0 or a natural number and if m is 2 or more, the groups B are optionally different from one another; and each of the two anthracene rings linked by A and/or B optionally has a non-planar electronic conjugated structure, or the two anthracene rings optionally form a single aromatic ring.

6. The organic electroluminescent element according to claim 1, wherein the light-emitting compound has a structure represented by Formula (4): 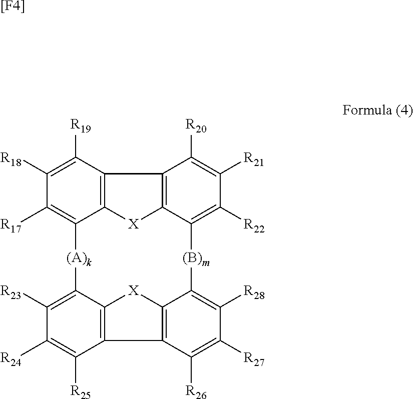
wherein X represents boron, carbon, nitrogen, oxygen, sulfur, or silicon; X optionally has a hydrogen atom or a substituent; R₁₇ to R₂₈ each independently represent a hydrogen atom or a substituent; two aromatic rings linked by A and/or B optionally form a condensed ring structure with any of R₁₇ to R₂₈, A, and B; k and m each represent 0 or a natural number; k or m represents a natural number; A and B each represent a single bond or a divalent linking group; if k or m is 2 or more, the groups A or B are optionally identical to or different from one another; and each of the two aromatic rings linked by A and/or B optionally has a non-planar electronic conjugated structure, or the two aromatic rings optionally form a single aromatic ring.

7. The organic electroluminescent element according to claim 1, wherein the light-emitting compound has a structure represented by Formula (5): 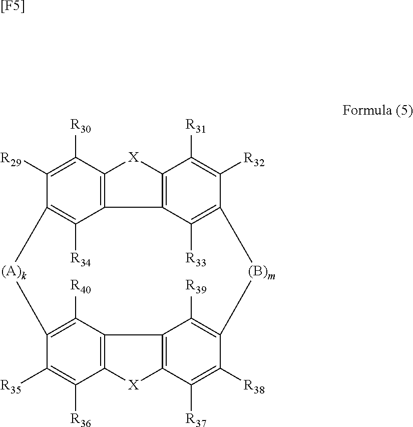
wherein X represents boron, carbon, nitrogen, oxygen, sulfur, or silicon; X optionally has a hydrogen atom or a substituent; R₂₉ to R₄₀ each represent a hydrogen atom or a substituent; two aromatic rings linked by A and/or B optionally form a condensed ring structure with any of R₂₉ to R₄₀, A, and B; k and m each represent 0 or a natural number; k or m represents a natural number; A and B each represent a single bond or a divalent linking group; if k or m is 2 or more, the groups A or B are optionally identical to or different from one another; and each of the two aromatic rings linked by A and/or B optionally has a non-planar electronic conjugated structure, or the two aromatic rings optionally form a single aromatic ring.

8. The organic electroluminescent element according to claim 1, wherein the light-emitting layer contains a carbazole derivative.

9. The organic electroluminescent element according to claim 8, wherein the carbazole derivative is a compound having two or more conjugated structures each having 14 or more π-electrons.

10. The organic electroluminescent element according to claim 8, wherein the carbazole derivative is a compound having a structure represented by Formula (SH): 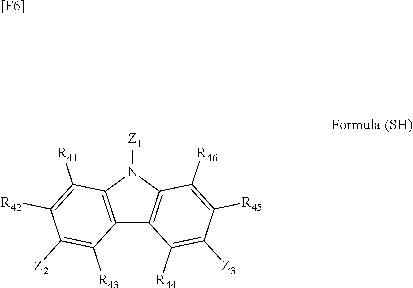
wherein Z₁ to Z₃ and R₄₁ to R₄₆ each independently represent a hydrogen atom or a substituent; at least one of Z₁ to Z₃ and R₄₁ to R₄₆ represents an aromatic cyclic group having 14 or more π-electrons; and adjacent substituents optionally form a ring structure through condensation.

11. The organic electroluminescent element according to claim 10, wherein at least one of Z₁ to Z₃ in Formula (SH) is a substituted or unsubstituted benzofuran ring.

12. A light-emitting device comprising the organic electroluminescent element according to claim 1.

13. A lighting device comprising the organic electroluminescent element according to claim 1.

14. A display device comprising the organic electroluminescent element according to claim 1.

15. An electronic device comprising the organic electroluminescent element according to claim 1.
